(19) United States
(12) Patent Application Publication
(10) Pub. No.: US 2024/0120943 A1
(43) Pub. Date: Apr. 11, 2024

(54) Implicit Transmission of Coded Information

(71) Applicant: Muhammad Ahsan Naim, Irving, TX (US)

(72) Inventor: Muhammad Ahsan Naim, Irving, TX (US)

(21) Appl. No.: 18/473,687

(22) Filed: Sep. 25, 2023

Related U.S. Application Data
(60) Provisional application No. 63/409,598, filed on Sep. 23, 2022.

(51) Int. Cl. H03M 13/11; H04L 1/00

(52) U.S. Cl. CPC H03M 13/1108; H03M 13/1174; H04L 1/005

(57) ABSTRACT

A novel implicit transmission with bit flipping (ITBF) technique is introduced to transmit a coded stream implicitly while transmitting a coded stream explicitly over a channel. ITBF flips a set of chosen parity bits of the explicitly transmitted stream according to an implicit stream. Numerical results show that the ITBF can transmit an implicit stream at the rate from about 5% to 13% of the explicit stream without sacrificing performance, increasing the decoding complexity or the decoding delay. The ITBF is combined with CPCD to form ITCD schemes that can further increase the rate of transmission on the implicit stream. It is demonstrated with the LDPC code in the WiFi standard that ITCD technique is capable of transmitting an implicit stream up to 25% of the rate of the explicit stream.

### CROSS-REFERENCE TO RELATED APPLICATIONS

This application claims priority to U.S. Provisional Patent Application No. 63/409,598, filed Sep. 23, 2022 and entitled “Implicit Transmission of Coded Information,” the contents of which are incorporated herein by reference herein in their entirety.

### BACKGROUND

With rapidly increasing consumer demand, almost all communication systems are seeking ways to increase throughput to meet the consumer demand. For example, 4G LTE (long term evolution) is moving into 5G, OTN (optical transport network) is expanding its speeds into 100G and beyond, computer backbone communication is actively trying to increase speed of communication among chips, memory units, etc. to speedup digital computations, cloud computing is expanding to accommodate more clients and higher speeds. Similar trends exist in almost all types of communications. However, all such communications face many challenges in trying to achieve their desired throughput increase.

Multi-level codes (MLCs) are well documented in the literature. In a traditional MLC that has N levels employs N separately encoded streams. The lowest level employs the most powerful code (usually a low rate code) and the power of the code decreases as the level increase. The highest level can be left uncoded too. During transmission, a symbol is formed by taking one coded bit from every level and mapping N bits onto a 2\hat{ }N-ary signal constellation. Usually, the lowest level corresponds to the least significant bit of every symbol while the highest level corresponds to the most significant bit of every symbol. MLCs are usually decoded by using MSD (multi-stage decoding). In MSD each level is decoded separately starting from the lowest level. All other levels are decoded by using the decisions made by all previously decoded levels. Hard decoding and soft decoding have been separately considered to decode each level. In addition, hard iterative decoding and soft iterative decoding have been considered to improve the performance over MSD. Usually, Gray coding has been considered on the constellation, however, other forms of mapping have also been considered with MLCs in the literature. A systematic way to construct to construct the constellation and the mapping policy has also been presented according to the selected set of component codes.

Implicit transmission of information has been discussed in the literature. A SM (spatial modulation) scheme can transmit additional information from the selection of the antenna used for transmission. For example, a spatial modulation scheme that employs 16 transmitting antennas and uses QPSK for transmission, can transmit 4 bits from the selection of the specific antenna used for transmission and two additional bits from the transmitted symbol. Hence, the four transmitted bits by the selection of the antenna are transmitted implicitly while the transmitted symbol only carries two bits from the selected QPSK symbol.

It would be desirable to have methods, apparatus and systems for increasing the throughput of any existing communication system such as on the uplink or the downlink of the LTE and 5G systems, increase the throughput of multimedia applications, in the transmission over the OTN, and to increase the throughput of any communication system. It would be desirable to increase the throughput without having to significantly modify the existing modulation, demodulation, coding and decoding techniques of the system. It would also be desirable to be able to employ the same technique to improve data storage systems, etc.

Further, a constrained interleaved coded modulation (CICM) technique can be used to best map a coded stream of bits onto a higher order signal. CICM can make a higher order coded modulation scheme to outperform or perform similar to a lower order modulation scheme at high SNR. CICM technique is implemented in two steps: (a) passing a coded stream through a constrained Interleaver (called a CICM Interleaver) that is constructed according to the code used in generating that coded stream, and (b) mapping the coded interleaved bits onto a signal constellation that is mapped according to reverse Gray coding (RGC). CICM is developed with block codes and convolutional codes based on the belief that, as the SNR increases, it is most likely that any errors occur would be limited to just a single codeword in case of a block code or a single error event in case of a convolutional code. CICM is developed by ensuring that all coded bits of every codeword are placed in different symbols and ensure that mapping on the constellation is done in such a way that all single bit differences achieve the highest possible Euclidean distance on the constellation. The CICM Interleaver ensures that all coded bits of every codeword are placed in different transmitted symbols while RGC ensures that all single bit differences achieve the highest Euclidean distance on the constellation. Since almost all systems in practice employ coded information, CICM is applicable to most of the communication systems including 4G, 5G systems, optical transmissions, etc. As a result, CICM can be used to increase the data rate while performing better than the traditional methods. It has been shown that improvements of CICM can be realized over any type of a channel including fading channels. Therefore, CICM has great potential in practice when meeting the increased demand for higher data rates.

However, a CICM technique can only be used with smaller block codes or short convolutional codes. This is because the CICM technique requires consideration of a large number of codewords (in case of a block code) or a long-coded sequence (in case of a convolutional code) in order to properly design its CICM Interleaver. Since short codes are rarely used in practice, it is almost impossible to apply the CICM technique in current communication systems. If the CICM technique is applied to commonly used long codes such as low-density parity check (LDPC) codes or turbo codes, it would require many LDPC codewords or long turbo coded sequences with multiple generations of turbo coded sequences thereby increasing the decoding delay, decoding complexity and required memory. Therefore, the CICM technique is not attractive for current communications systems.

### OVERVIEW

Almost all current communication systems employ some form of error control coding to improve the reliability of transmission. LDPC codes, turbo codes, polar codes, etc. are commonly employed in current systems, such as those described in (i) Ryan, W. E. et al. (2004). An introduction to ldpc codes, (ii) Berrou, C., A. Glavieux, and P. Thitimajshima (1993). Near Shannon limit error correcting coding and decoding: Turbo-codes. 1. In Proceedings of ICC'93-IEEE International Conference on Communications, Volume 2, pp. 1064-1070, (iii) Johnson, S. J. (2010). Iterative error correction: Turbo, low-density parity-check and repeat-accumulate codes. Cambridge university press, and/or (iv) Tal, I. and A. Vardy (2013). How to construct polar codes. IEEE Transactions on Information Theory 59 (10), 6562-6582. The studies so far have focused primarily on searching for good coding techniques and searching for high-rate good codes within those coding techniques, such as described in (i) Berrou, C., A. Glavieux, and P. Thitimajshima (1993). Near Shannon limit error correcting coding and decoding: Turbo-codes. 1. In Proceedings of ICC'93-IEEE International Conference on Communications, Volume 2, pp. 1064-1070 and (ii) Wolf, J. (1978). Efficient maximum likelihood decoding of linear block codes using a trellis. IEEE Transactions on Information Theory 24 (1), 76-80. Studies have also focused on improving the decoding of coded signals to achieve good performance with low decoding complexity and decoding delay, such as described in (i) Fossorier, M. P., M. Mihaljevic, and H. Imai (1999). Reduced complexity iterative decoding of low-density parity check codes based on belief propagation. IEEE Transactions on communications 47 (5), 673-680 and (ii) Sankar, H. and K. R. Narayanan (2004). Memory-efficient sum-product decoding of ldpc codes. IEEE transactions on communications 52 (8), 1225-1230.

Instead of the traditional methods of searching for good codes, it is highly desirable to be able to transmit coded bits implicitly (without transmitting physically over the channel) while transmitting a coded stream explicitly over the channel. It would be highly desirable if such schemes can be developed without increasing the decoding complexity or the decoding delay while maintaining a significant data rate on the implicitly transmitted stream.

Disclosed herein is such a scheme, referred to as implicit transmission with bit flipping (ITBF) to transmit a second coded stream (referred to here as the secondary stream or the implicit stream) implicitly without physically transmitting it over the channel during the transmission of a first coded stream (referred to here as the primary stream or the explicit stream). In this disclosure, we present a simple way to transmit a secondary stream implicitly without sacrificing the performance of the primary stream or increasing the decoding complexity or the decoding delay. In (i) Rezaei, E., J. P. Fonseka, and Y. Bo (2019). Throughput enhancing concatenated codes. lET Communications 13 (9), 1278-1286 (hereinafter “Throughput enhancing concatenated codes” and (ii) Rezaei, E. and J. P. Fonseka (2020). Throughput enhancing concatenated codes with a second uncoded implicit stream. Electronics Letters 56 (1), 32-35 (hereinafter “Throughput enhancing concatenated codes with a second uncoded implicit stream”), implicit transmission has been proposed to transmit a turbo-coded implicit stream while transmitting a turbo-coded stream explicitly. Even though schemes presented in (i) “Throughput enhancing concatenated codes” and (ii) “Throughput enhancing concatenated codes with a second uncoded implicit stream”, can transmit a stream implicitly, the decoding of the two streams need to be done jointly by running iterations between the explicit stream and the implicit stream. As a result, the receiver proposed in “Throughput enhancing concatenated codes” increases the decoding complexity and the decoding delay significantly. Further, the schemes presented in (i) “Throughput enhancing concatenated codes” and (ii) “Throughput enhancing concatenated codes with a second uncoded implicit stream” are dependent on the coding technique; it generates attractive schemes with turbo-coded systems but fails with codes such as LDPC codes. In contrast, the proposed ITBF method here treats the explicit and the implicit streams independently. Therefore, ITBF does not require iterations that involve both the explicit and implicit streams as in (i) “Throughput enhancing concatenated codes” and (ii) “Throughput enhancing concatenated codes with a second uncoded implicit stream”, and therefore, does not increase the decoding delay or decoding complexity while maintaining performance as if no coded stream was transmitted implicitly. Further, since ITBF maintains independence of the explicit and the implicit streams, the two streams can employ any type of coding independently.

In one aspect, disclosed herein is a transmitter apparatus comprising: (i) a first message stream, m_Ex, which is referred to here as the explicit message stream; (ii) an explicit encoder, C_Ex, which can be any type of a code, such as a block code, turbo code, LDPC code, polar code, etc., that encodes the message sequence m_Ex according to the encoding policy adopted by the code C_Ex; (iii) a second message stream, m_Im, which is referred to as the implicit message stream; (iv) an implicit encoder, C_Im, that can be any independent code, such as a block code, turbo code, LDPC code, polar code, etc., that encodes the message sequence m_Im according to the encoding policy adopted by the code C_Im; (v) a set of bit positions of each codeword of the explicit stream, which are referred to here as the chosen bits, that are chosen according to any preferable policy; (vi) an alteration policy that alters the chosen el bits of each codeword of the explicit stream according to el′(<=el) coded bits of the implicit stream to form an altered codewords of the explicit stream; (vii) a modulator that modulates the altered coded bits of the explicit stream according to any chosen linear or non-linear modulation scheme, such as QPSK, 16-QAM, 64-QAM, M-ary CPM, FSK, etc.; and (viii) a transmitting antenna that transmits the modulated signal. This aspect may be referred to herein as “example 1.”

In an example of the transmitter apparatus of example 1, with el′=el, the alteration of the el chosen bits of the explicit stream is done by flipping each chosen bit according to a coded bit of the implicit stream; specifically flip any ith chosen bit if the corresponding ith implicit bit is a ‘1’ (or a ‘0’) and not flip ith chosen bit if the corresponding ith coded implicit bit is a ‘0’ (or a ‘1’).

In another aspect, disclosed herein is a receiver apparatus that decodes the received signal of example 1, the receiver apparatus comprising: (i) an initial decoder that decodes every codeword of the explicit coded stream by treating C_Ex as a punctured code formed by excluding all el chosen bits; (ii) a comparator that compares the decoded chosen bits from the initial decoding and the hard decisions of the received signal to determine whether each chosen bit is more likely or not to have been flipped prior to transmission; (iii) a received signal correction unit that changes the signs of the received signal values of the chosen bits that have been identified as flipped by the comparator; (iv) a final decoder of C_Ex that decodes each codeword of the explicit code C_Ex as a full code by using all coded bits of the codeword including the corrected received signal values of the chosen bits obtained from the received signal correction unit; (v) an artificial channel information creation unit that compares chosen bits of each decoded explicit codeword with the hard decisions of the corresponding received bit and generates channel information of each el′ implicit coded bits used to determine the alterations made in the corresponding el chosen bits of the each explicit codeword; and (vi) an implicit decoder to decode each codeword of the implicit stream according to the decoder of C_Im once artificial channel information of all coded bits of each codeword of the implicit stream is obtained.

In an example, the initial decoding is performed gradually using a gradual initial decoding method.

In another aspect, disclosed herein is a receiver apparatus that decodes the received signal of example 1, the receiver apparatus comprising: (i) an initial decoder that decodes every codeword of the explicit coded stream by treating C_Ex as a punctured code formed by excluding all el chosen bits; (ii) a comparator that compares the decoded chosen bits from the initial decoding and the hard decisions of the received signal to determine whether each chosen bit is more likely or not to have been flipped prior to transmission; (iii) a received signal correction unit that changes the signs of the received signal values of the chosen bits that have been identified as flipped by the comparator; (iv) a final decoder of C_Ex that decodes each codeword of the explicit code C_Ex by considering two component codes of C_Ex: (a) a first component code being the punctured code used in the initial decoding, and (b) a second component code that comprises the message bits and the corrected chosen bits of C_Ex, and exchanging information between those two component codes; (v) an artificial channel information creation unit that compares chosen bits of each decoded explicit codeword with the hard decisions of the corresponding received bit and generates channel information of each e1′ implicit coded bits used to determine the alterations made in the corresponding e1 chosen bits of the each explicit codeword; and (vi) an implicit decoder to decode each codeword of the implicit stream according to the decoder of C_Im once artificial channel information of all coded bits of each codeword of the implicit stream is obtained.

In an example, the initial decoding is performed gradually using a gradual initial decoding method.

It should be appreciated that many other features, applications, embodiments, and variations of the disclosed technology will be apparent from the accompanying drawings and from the following detailed description. Additional and alternative implementations of the structures, systems, non-transitory computer readable media, and methods described herein can be employed without departing from the principles of the disclosed technology.

### BRIEF DESCRIPTION OF THE DRAWINGS

A further understanding of the nature and advantages the present disclosure may be realized by reference to the following drawings.

FIG. 1 shows designs illustrating exemplary methods in accordance with various aspects of the present disclosure;

FIG. 2 shows designs illustrating exemplary methods in accordance with various aspects of the present disclosure;

FIG. 3 shows designs illustrating exemplary methods in accordance with various aspects of the present disclosure;

FIG. 4 shows designs illustrating exemplary methods in accordance with various aspects of the present disclosure;

FIG. 5 shows designs illustrating exemplary methods in accordance with various aspects of the present disclosure;

FIG. 6 shows designs illustrating exemplary methods in accordance with various aspects of the present disclosure;

FIG. 7 shows designs illustrating exemplary methods in accordance with various aspects of the present disclosure;

FIG. 8 shows designs illustrating exemplary methods in accordance with various aspects of the present disclosure;

FIG. 9 shows designs illustrating exemplary methods in accordance with various aspects of the present disclosure;

FIG. 10 shows designs illustrating exemplary methods in accordance with various aspects of the present disclosure;

FIG. 11 shows designs illustrating exemplary methods in accordance with various aspects of the present disclosure;

FIG. 12 shows designs illustrating exemplary methods in accordance with various aspects of the present disclosure;

FIG. 13 shows designs illustrating exemplary methods in accordance with various aspects of the present disclosure;

FIG. 14 shows designs illustrating exemplary methods in accordance with various aspects of the present disclosure;

FIG. 15 shows designs illustrating exemplary methods in accordance with various aspects of the present disclosure;

FIG. 16 shows designs illustrating exemplary methods in accordance with various aspects of the present disclosure;

FIG. 17 shows designs illustrating exemplary methods in accordance with various aspects of the present disclosure;

FIG. 18 shows designs illustrating exemplary methods in accordance with various aspects of the present disclosure;

FIG. 19 shows designs illustrating exemplary methods in accordance with various aspects of the present disclosure;

FIG. 20 shows designs illustrating exemplary methods in accordance with various aspects of the present disclosure;

FIG. 21 shows designs illustrating exemplary methods in accordance with various aspects of the present disclosure;

FIG. 22 shows designs illustrating exemplary methods in accordance with various aspects of the present disclosure;

FIG. 23 shows designs illustrating exemplary methods in accordance with various aspects of the present disclosure;

FIG. 24 shows designs illustrating exemplary methods in accordance with various aspects of the present disclosure;

FIG. 25 shows designs illustrating exemplary methods in accordance with various aspects of the present disclosure;

FIG. 26 shows designs illustrating exemplary methods in accordance with various aspects of the present disclosure;

FIG. 27 shows designs illustrating exemplary methods in accordance with various aspects of the present disclosure;

FIG. 28 shows designs illustrating exemplary methods in accordance with various aspects of the present disclosure;

FIG. 29 shows designs illustrating exemplary methods in accordance with various aspects of the present disclosure;

FIG. 30 shows designs illustrating exemplary methods in accordance with various aspects of the present disclosure;

FIG. 31 shows designs illustrating exemplary methods in accordance with various aspects of the present disclosure;

FIG. 32 shows designs illustrating exemplary methods in accordance with various aspects of the present disclosure;

FIG. 33 shows designs illustrating exemplary methods in accordance with various aspects of the present disclosure;

FIG. 34 shows designs illustrating exemplary methods in accordance with various aspects of the present disclosure; and

FIG. 35 shows designs illustrating exemplary methods in accordance with various aspects of the present disclosure.

FIG. 36 depicts a general structure of an example implicit transmission with bit flipping (ITBF) transmitter.

FIG. 37 is an illustration of example actions taken by an example bit flipping unit (BFU) when l=6.

FIG. 38 depicts a general structure of an example ITBF decoder.

FIG. 39 depicts an example structure of a parity check matrix H of 5G NR.

FIG. 40 illustrates a comparison of B-CPCD, U-CPCD, S-CPCD and US-CPCD schemes constructed from rate ½ code with 16-QAM transmission.

FIG. 41 depicts illustrates a comparison of B-CPCD, U-CPCD, S-CPCD and US-CPCD schemes constructed from rate ⅔ code with 16-QAM transmission.

FIG. 42 illustrates bit error rate (BER) variations of the explicit and the implicit streams of the ITBF schemes constructed from the rate code that transmit 13.19% rate 0.2083 on the implicit stream compared to the rate in the explicit stream.

FIG. 43 illustrates BER variations of the explicit and the implicit streams of the ITBF schemes constructed from the rate code that transmit 18.75% rate 1 4 on the implicit stream compared to the rate in the explicit stream.

FIG. 44 illustrates BER variations of the explicit and the implicit streams of the ITCD schemes constructed from the rate 1½ code that transmit 12.5% and 25% rate on the implicit stream compared to the rate in the explicit stream.

FIG. 45 illustrates BER variations of the explicit and the implicit streams of the ITCD schemes constructed from the rate ⅔ code that transmit 8.3% and 16.6% rate on the implicit stream compared to the rate in the explicit stream.

FIG. 46 depicts an example application of ITBF and ITCD to create an added layer of encryption.

### DETAILED DESCRIPTION

### I. Simultaneous Packet Transmission

In one aspect, the present application discloses SPT (simultaneous packet transmission) for increasing the throughput of a communication system. SPT employs different streams for transmission. The data packets on different streams of a SPT can be inherently present in the communication system. For example, the different types of signals, such as voice and data, or video and audio, already available in a multimedia application can form different streams of packets (one for videos, one for voice, etc.) of a SPT scheme. If not, the present application also teaches how to systematically generate different data streams from a single data stream that carries the same type of packets. Therefore, the SPT technique disclosed herein is applicable for the current LTE system, the upcoming 5G systems and multimedia applications, and the like. The throughput enhancement using SPT is feasible because SPT allows packets transmitted on some streams to employ significantly higher code rates.

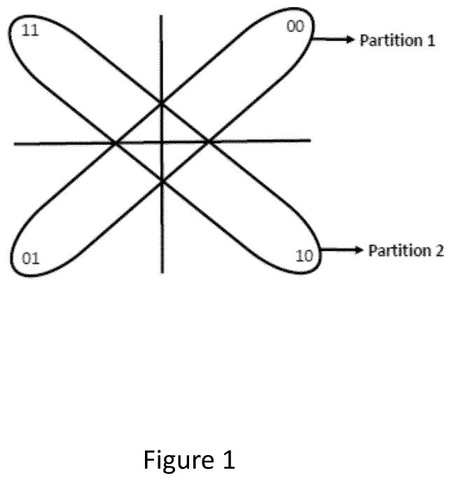

In order to explain the SPT technique disclosed herein, let us consider a SPT scheme that employs a M=2^{(m}^{₁}^{+m}^{₂}⁾-ary overall signal constellation for transmission, where m₁ and m₂ are two positive integers. Let M₁=2^{m}^{₁} and M₂=2^{m}^{₂}. In the SPT technique disclosed herein, the overall M=M₁M₂-ary constellation is partitioned into M₁ number of distinct M₂-ary partitioned constellations so that no two different M₂-ary partitioned constellations share any common constellation points on the overall constellation. Further, partitioned constellations are chosen so that every constellation point on the overall M₁M₂-ary constellation belongs one and only one M₂-ary partitioned constellation. In addition, the partitioned constellations are selected to maintain a high MSED (minimum squared Euclidean distance) as possible within their respective partitioned constellations. As a result, the MSED of any partitioned constellation can be significantly higher than the MSED of the overall constellation. Therefore, m₁ number of bits (out of (m₁+m₂) number of total bits) of a symbol transmitted during every interval can be used to identify the specific M₂-ary partitioned constellation among all M₁ number of such partitioned constellations, while the remaining m₂ number of bits can be used to identify the specific constellation point of that specific partitioned M₂-ary constellation. Therefore, a SPT scheme can be developed to transmit symbols that carry m=(m₁+m₂) number of bits every interval, where the first m₁ bits of a symbol can be dedicated to selecting the particular M₂-ary partitioned constellation, whereas the last m₂ bits of a symbol can be dedicated to selecting the specific constellation point of that M₂ -ary partitioned constellation. For example, FIG. 1 illustrates an overall 4-ary SPT constellation that corresponds to the case m₁=m₂=1. The overall 4-ary constellation in FIG. 1 consists of two distinct 2-ary partitioned constellations as highlighted in FIG. 1. The partitioned constellation 1 is identified by a “0” first bit of a symbol while the partitioned constellation 2 is identified by a “1” first bit of a symbol. Throughout this document, the first m₁ bits of a symbol that select the specific partitioned constellation are referred to as the “primary m₁ bits” while the last m₂ bits of a symbol that determine the specific constellation point of that specific partitioned constellation are referred to as the “secondary m₂ bits” of a symbol. Clearly, the primary m₁ bits that select the partitioned constellation can be placed anywhere within m=(m₁+m₂) bits of the symbol while the remaining secondary m₂ bits can select the specific constellation point on that partitioned constellation. Note that each ith partitioned M₂ -ary constellation corresponds to a unique combination of primary m₁ bits, pⱼ=(pⱼ₁, pⱼ₂, . . . , pⱼₘ₁), j=1, 2, . . . , M₁.

With the above observations, the disclosed SPT proposes to assign each of the M₁ number of M₂ -ary partitioned constellations to a specific stream of packets. As a result, a SPT has M₁ number of streams in addition to the stream that carries the primary m₁ bits of every symbol. Specifically, a SPT has the following transmission structure:

1. Employ (M₁+1) number of different streams for transmission

2. Use usually a powerful code on stream 1, which is also called the primary stream, and select the primary m₁ bits of every symbol from that primary stream

3. Assign each of the remaining streams, streams 2 through (M₁+1), a specific partitioned constellation among all M₁ partitioned constellations. Without loss of generality, assign the partitioned constellation j to stream (j+1) j=1, 2, . . . , M₁. Note that each jth partitioned M₂-ary constellation, which is assigned to the (j+1) th stream, corresponds to a unique combination of primary m₁ bits, pⱼ=(pⱼ₁, pⱼ₂. . . , pⱼₘ_{₁}), where, j=1,2, . . . , M₁.

4. In every symbol, once the specific kth partitioned constellation is selected by the primary m₁ bits on stream 1, identify the specific constellation point on the kth partitioned constellation corresponding to the secondary m₂ bits taken from stream (k+1).

During transmission, the first primary m₁ bits of a symbol are taken from stream 1. These primary m₁ bits uniquely identify the specific kth partitioned constellation corresponding to that symbol. Since the kth partitioned constellation is assigned to stream (k+1), select the corresponding constellation point on the selected kth partitioned constellation based on the next m₂ bits from stream (k+1). As a result, every symbol carries m₁ primary bits from stream 1 and m₂ secondary bits from one stream from streams 2 through (M₁+1), which is selected based on the m₁ primary bits of that symbol. For example, a SPT scheme with m₁=m₂=1 can employ the constellation shown in FIG. 1 and use one primary stream (stream 1) and two secondary streams (streams 2 and 3).

In order achieve the best performance and to maintain the highest throughput, the mapping on the constellation in SPT can be preferably done as follows:

1. Since every combination of m₁ primary bits corresponds to a specific partitioned constellation, assign the same m₁ primary bits as the most significant m₁ bits of every constellation point of that specific partitioned constellation. Assign different primary m₁ bit combinations different M₁ partitioned constellations to maintain Gary coding or any other preferable mapping policy among the primary m₁ bit combinations of those M₁ partitioned constellations.

2. Maintain Gray coding or any other different mapping policy among m₂ secondary bit combinations within any given partitioned constellation for all M₁ partitioned constellations.

Therefore, even though the constellation points on the overall constellation would not maintain Gary coding among all m=(m₁+m₂) bit combinations, they can maintain Gray coding among the first m₁ primary bits among different partitioned constellations and among the last m₂ secondary bits within partitioned constellations separately. However, depending on the application, SPT can use other mapping policies such as anti-Gray coding, RGC (reverse Gray coding). For example, if the SPT scheme is developed to use iterative decoding including the demodulator as in CICM (constrained interleaved coded modulation) or BICM (bit-interleaved coded modulation), RGC or other mapping policies can be used to improve performance at the expense of complexity.

As stated before, SPT schemes of the present disclosure maintain a higher minimum squared Euclidean distance (MSED) than that of the overall constellation. For example, the two partitioned constellations in FIG. 1 have a MSED which is twice the MSED of the overall 4-ary constellation. Therefore, if the receiver can correctly identify the specific partitioned constellation at the receiver by correctly decoding all m₁ primary bits of every symbol, the secondary m₂ bits of every symbol that decide the specific constellation point on the respective partitioned constellation can have more immunity for handling channel noise. For example, the two partitioned constellations in FIG. 1 have a 3 dB advantage over the overall constellation. Therefore, all streams 2 through (M₁+1) can employ codes that have significantly higher code rate than the code used on stream 1 thereby increasing the overall throughput of the SPT scheme. Specifically, when stream 1 employs a code that has rate R₁ and all streams 2 through (M₁+1) employ the same code that has rate R₂>R₁, the overall rate employed by the SPT scheme is R=(m₁R₁+m₂R₂)/(m₁+m₂), which is higher than R₁ when R₂>R₁. Therefore, compared with a conventional transmission that employs a rate R₁ code for all packets, the SPT technology disclosed herein allows the use of higher rate codes on selected packets increasing the overall throughput.

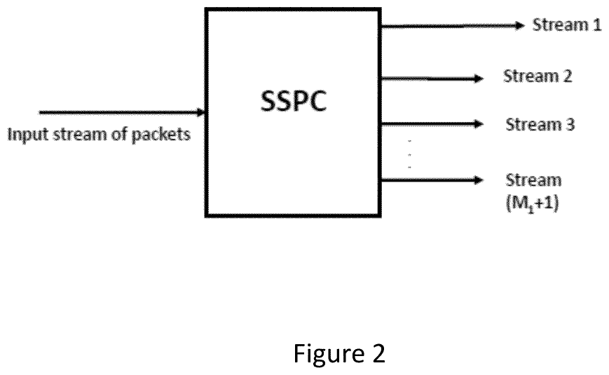

So far, the SPT technology is discussed when (M₁+1) different streams are available for transmission. Such scenarios are common in multimedia type systems that naturally transmit different types of streams simultaneously. The SPT technology disclosed herein can also be used with a scheme that employs only a single stream such as on the down link of the 4G LTE system and 5G systems. In such applications, as illustrated in FIG. 2, the single stream can be first passed through a SSPC (structured serial to parallel converter) in order to systematically generate all (M₁+1) number of streams needed in a SPT scheme. The structured distribution of packets among the streams in SSPC allows the receiver to uniquely identify the specific stream, out of streams 2 through (M₁+1), that feeds the set of m₂ secondary bits of every symbol. The SSPC is discussed here for convenience by assuming that all streams operate on the basis of packets or frames formed by groups of bits. However, the same SSPC technique can be used when the packet sizes vary from one packet to the other. For example, in case of the LTE, these groups can represent packets which can be used by different streams of a SPT. Similarly, when used with individually transmitted bits on different streams, the same SSPC can be used by making the frame length of a packet to one bit. The SSPC can be designed by using the following rule of operation for continuous transmission of packets:

Every stream at the output of the SSPC that is in need of a new packet gets the very next available packet of the stream at the input. A stream that is in need of a new packet is defined here as a stream that has just completed transmitting its current packet and is expected to feed its bits into the current symbol for transmission from a new packet. Since stream 1 transmits its bits in every symbol, stream 1 is in need of a new packet every time it completes its current packet. Any stream from streams 2 through (M₁+1) that has been chosen to transmit the next secondary m₂ bits (based on the primary m₁ bits on stream 1) but has completed transmitting its current packet is also in need of a new packet. In case of a situation where more than one stream is in need of a new packet, the stream with the lowest assigned stream number gets the first priority.

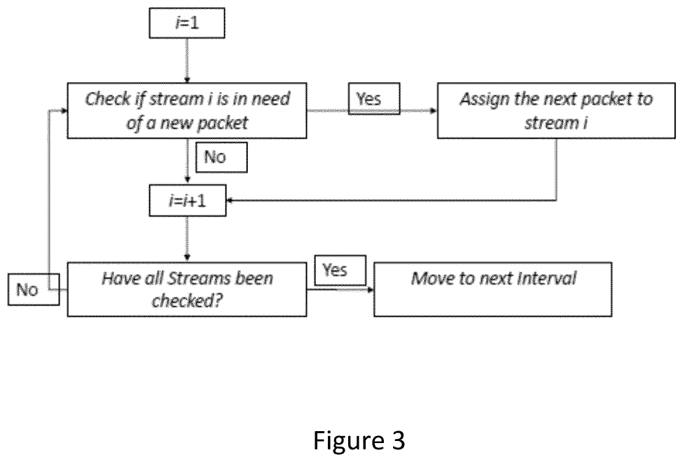

FIG. 3 shows the operating algorithm of the SSPC of the present disclosure according to the above-mentioned rule. Note that at the beginning, stream 1 is in need of packet and hence, steam 1 gets the first packet of the stream of packets to be transmitted at the input of the SSPC. The first m₁ bits on that selected packet on stream 1 decides the selected stream from streams 2 through (M₁+1) and hence, that selected stream gets the second packet at the input of the SSPC. The remaining packets will be assigned to the different streams of the SPT according to the algorithm shown in FIG. 3. Embodiments that employ other similar conventions such as, stream 1 has the lowest priority, etc. that still introduce a structure in the SSPC fall within the scope of the present disclosure.

The above algorithm, however, creates an issue at the end of transmission as it can leave partially completed packets in streams 2 through (M₁+1). In order to overcome this issue in SPT and to maintain the same structure of transmission throughout the entire communication, a final packet, referred as an “artificial terminating packet”, can be introduced on stream 1 to complete any partially completed packets on streams 2 through (M₁+1). This artificial terminating packet on stream 1 carries no information and its purpose is solely to complete any partially completed packets on streams 2 through (M₁+1) and to maintain the same structure of signaling. Depending on the number of remaining bits of the packets on each of the streams 2 through (M₁+1), a binary sequence can be chosen as the artificial terminating packet on stream 1 to complete the remaining bits of packets on streams 2 through (M₁+1) in a pre-selected order. Specifically, if the number of remaining bits of the last packet on stream j is m₂λⱼ, j=2, 3, . . . , (M₁+1), then the artificial terminating packet on stream 1 is formed by placing λⱼ times the sequence pⱼ starting from j=2 and keep increasing j by 1 up to j=(M₁+1). As an example, consider the case when m₁=m₂=1 and M₁=M₂=2. FIG. 1 shows the constellation used for transmission of this SPT scheme with (M₁+1)=3 streams, that has p₁=(0) and p₂=(1). When all packets up to the last packet are assigned to streams 1 through 3 according to the algorithm shown in FIG. 3, let us for example assume that stream 2 still has fifty remaining bits to complete its last packet while stream 3 has forty remaining bits to complete its last packet. In that case a sequence that has 50 zeros followed by 40 ones is chosen as the artificial terminating packet on stream 1. The artificial terminating packet is uncoded and is not decoded at the receiver. However, the received signal during the transmission of the artificial terminating packet can be used to extract information about the remaining bits of the last packets of streams 2 through (M₁+1). Since the artificial terminating packet on stream 1 is not decoded, the artificial terminating packet can optionally employ slightly a modified convention to simply transmit m₁Σⱼ₌₂^{(M}^{₁}⁺¹⁾ λⱼ number of zeros with the understanding that the secondary bits in the last packet come from streams 2 through (M₁+1) in a pre-selected systematic order. Specifically, the last packet can complete streams 2 through (M₁+1), one stream at a time starting from stream 2 and moving up to stream (M₁+1), by transmitting all of their remaining bits as sets of secondary m₂ bits of symbols.

The other terminating methods of SPT can include: (a) transmitting the last several pre-selected number of packets only over stream 1 thereby eliminating the possibility of having partially transmitted packets on streams 2 through (M₁+1), (b) transmitting the remaining bits of streams 2 through (M₁+1) using the standard Gray coded overall constellation, or (c) a hybrid of (a) and (b). However, the above terminating approaches (a), (b) and (c) reduces the MSED that can be achieved by the SPT technique for the terminating portion compared with the use of an artificial terminating packet thereby degrading the performance of the those last packets of the streams 2 through (M₁+1). This degradation is however not experienced in the case of employing the terminating artificial packet as described before.

The decoding of SPT signals begins by decoding of stream 1 correctly. It is important in SPT decoding to correctly decode stream 1 (that carries all primary m₁ bit combinations of all symbols) correctly because without correctly identifying stream 1, the receiver is unable to correctly identify the origin of the remaining secondary m₂ bits of every symbol. Therefore, SPT schemes need verify that all packets on stream 1 are decoded correctly by preferably employing a CRC or employing a different method. In case any packet on stream 1 is incorrectly decoded (i.e., fails the CRC), the decoder needs to request re-transmission of that packet on stream 1. Therefore, SPT schemes are more suitable for hybrid ARQ (hybrid automatic repeat request) schemes, such as those currently employed in the 4G LTE standard. In case of re-transmissions, the incremental redundancy method that is currently used in the 4G LTE can be used to further help to decode the same packets that failed their corresponding CRC and also to help better decode the packets that contain the secondary m₂ bits corresponding to the same set of symbols.

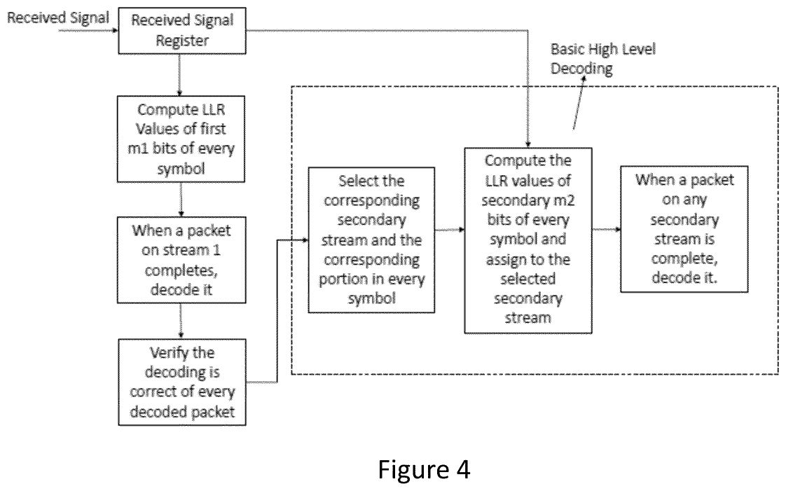

FIG. 4 shows the block diagram of the SPT receiver assuming that the decoding of each packet according to the code (or codes) employed on different streams requires soft decoding similar to the turbo decoding used in the 4G LTE system. The received signal is first fed into the received signal register. Note that each received symbol carries information about m₁ primary bits from stream 1 and m₂ secondary bits from one of streams from 2 through (M₁+1). As shown in FIG. 4, the receiver extracts soft information of only m₁ primary bits of each symbol at the beginning. The soft information which are the log likelihood (LLR) values of each primary bit is obtained in the standard manner known in the literature [Imai] using the M-ary overall constellation. Once the LLR values of a full packet on stream 1 is obtained, decode that packet according to the code used on stream 1. Verify the decoding of that packet on stream 1 is correct decoded by preferably checking a CRC. If the receiver finds that a decoded packet is incorrect, request re-transmission of the set of symbols that are responsible for providing the LLR values of that packet on stream 1. If that decoded packet on stream 1 is correct, the set of primary m₁ bits of every symbol related to that packet has been identified correctly preferably by using a CRC or any other method. Since the set of primary m₁ bits corresponds to a specific jth partitioned M₂-ary constellation which is assigned to stream (j+1) (1≤j≤M₁), the origin of each set of m₂ secondary bits of all the symbols related to that frame can be correctly identified using a stream and constellation finding block as illustrated in FIG. 4. For each symbol of that correctly decoded packet on stream 1, using the correctly identified specific jth M₂-ary partitioned constellation by the correctly decoded set of m₁ primary bits and the corresponding received symbol values, find the LLR values of the set of m₂ secondary bits and assign them to the specific stream (j+1) which is assigned to that jth M 2 -ary partitioned constellation. When LLR values of any packet of any (j+1)th stream completes, start decoding that packet according to the code employed of that (j+1)th stream. Continue this process down to the last packet. When all the previous packets of steam 1 are correctly decoded and verified preferably by using a CRC on stream 1, the receiver can correctly identify the sequence of stream 1 in the last packet. Therefore, in the artificial terminating packet (which is the last packet transmitted on stream 1) is not decoded as the receiver already knows the primary m₁ bits of each symbol in it. The LLR values of the secondary m₂ bits of all symbols corresponding to the artificial terminating packet can therefore be calculated using each respective M₂ -ary partitioned constellation and correctly assign to the respective streams 2 through (M₁+1).

The SPT schemes that have been described so far can be viewed as SPT schemes with two levels. The first level is represented by stream 1 that carries the primary m₁ bits of every symbol. The second level is represented by the set of streams 2 through (M₁+1) that feed the secondary m₂ bits of every symbol. The SPT technology can be easily extended to multiple levels by creating streams at the next level starting from every stream at the current highest level. For example, each of the streams at level 2, which are streams 2 through (M₁+1), can start a new level by sub-partitioning each of its partitioned M₂ -ary constellations thereby creating a new level 3. Using the same terminology, a 3-level SPT can be constructed from a M₁M₂M₃-ary overall constellation by (a) partitioning the overall constellation into M₁ number of M₂M₃-ary partitions, and (b) sub-partitioning each M₂M₃-ary partition into M₂ number of M₃-ary sub-partitions. Sub-partitioning of partitioned constellations is done by following the same rules used to partition the overall constellation. Hence, every symbol of a 3-level SPT constructed using an overall M₁M₂M₃-ary constellation, carries m=(m₁+m₂+m₃) bits, where M₁=2^{m}^{₁}, M₂=2^{m}^{₂} and M₃=2^{m}^{₃}. Further, every transmitted symbol carries m₁ primary bits from stream 1, m₂ secondary bits from streams 2 through (M₁+1), and m₃ tertiary bits from level three which is formed by streams (M₁+2) to (M₁+M₂+2). In general, this process can be continued until the last sub-partitions become 2-ary constellations. Clearly, as the number of levels increases the number of streams of the corresponding SPT scheme also increases. However, due to partitioning and sub-partitioning, the MSED keeps increasing as the level increases. Therefore, the rate of the code employed on all streams of a level can also be increased as the level increases. However, when multiple levels are used in a SPT, all streams that belong to all levels except for those on the highest level need to be correctly decoded. Hence, all streams, except for those at the highest level need to verify that their packets are decoded correctly by employing a CRC or any other method on each of those streams. In case any packet on any of those streams fails to correctly decode (i.e., CRC check fails), the set of symbols that include that packet needs to be retransmitted. As stated before during re-transmissions, incremental redundancy technique can be preferably used, as in the 4G LTE, to better decode the re-transmitted frames.

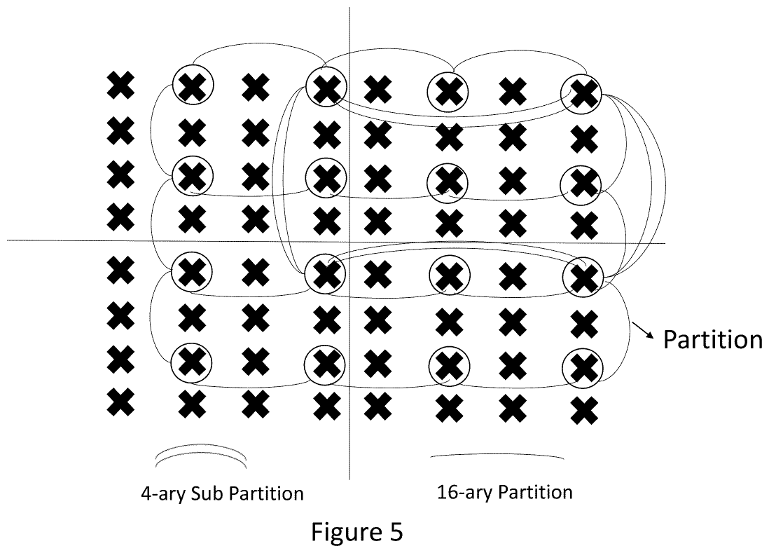

For example, consider an embodiment with a 3-level SPT that uses a 64-QAM overall constellation with m₁=m₂=m₃=2, and M₁=M₂=M₃=4. First, the overall constellation is partitioned into four partitioned 16-ary constellations to form the second level. Each partitioned 16-ary partitioned constellations at the second level is further sub-partitioned into four 4-ary constellations to form the third level. FIG. 5 illustrates one 16-ary partition and one 4-ary sub-partition within that partition. Each symbol can be formed starting from two bits from the first level, followed by two bits from the second level and finally two bits from the third level. Note that in every symbol (a) the first two bits from the first level uniquely identify the 16-ary partitioned constellation and the corresponding second level stream that feeds the two middle bits (3rd and 4th) of every symbol, (b) the 3rd and 4th bits from the selected second level stream uniquely identify the specific 4-ary sub-partition (from the selected 16-ary partition in (a)) and the corresponding third level stream that feeds the last two bits, and (c) the last two bits from the selected third level stream determines the specific constellation point from the selected sub-partition. This 3-level SPT has one first level stream (stream 1), four second level streams (streams 2 through 5), four third level streams under each second level streams. Therefore, the 3-level SPT has one first level stream, four second level streams (that can be labeled streams 2 through 5) and 16 third level streams (that can be labeled streams 6 through 21) with a total of 21 streams. Note that the MSED of the second level streams is 4 times that of stream 1 at the first level, and the MSED of the third level streams is 4 times that of the second level streams. Therefore, all streams at the second level (streams 2 through 5) have a 6 dB advantage over stream 1, while all streams at the third level (6 through 21) have a 12 dB advantage over stream 1. Therefore, the code rate of all streams at the second level (streams 2 through 5) can be higher than that of stream 1 at the first level, and the code rate of all streams at the third level (streams 6 through 21) can be higher than that at the second level.

In general, a SPT with N levels can be constructed with a M=Πᵢ₌₁^{N} Mᵢ-ary overall constellation to transmit mᵢ=log₂M₁ number of bits from each level i, i=1, 2, . . . , N, in every symbol that carries a total of m=Σᵢ₌₁^{N} mᵢ=log₂M bits, where m and mᵢ, i=1, 2 . . . , N are positive integers and N is also a positive integer. The first level of a SPT scheme has one stream and bits on the first level stream are referred to as primary bits or level-1 bits in this document. Following the description of 2-level SPT schemes, a N-level SPT scheme has M₁ secondary streams, which are also referred to as level-2 streams in this document. The bits of level-2 streams are referred to as secondary bits or level-2 bits in this document. As described before with 2-level SPT schemes, each of the level-2 streams is assigned a particular Πᵢ₌₂^{N} Mᵢ-ary partitioned constellation out of a total of M₁ number of Πᵢ₌₂^{N} Mᵢ-ary partitioned constellations. In order to simplify the terminology, these M₁ number of partitioned constellations in a general N-level SPT scheme are also referred to as level-2 partitioned constellations or simply level-2 partitions. The specific level-2 partition corresponding to a symbol is selected based on m₁ level-1 bits in that symbol. At any general level j, for 1<j<N, every level-j partition is further partitioned into Mⱼ number of Πᵢ₌₍ⱼ₊₁₎^{N} Mᵢ-ary partitioned constellations, which are referred to as level-(j+1) partitioned constellations or level-(j+1) partitions. Each of the Mⱼ number of level-(j+1) partitioned constellations is assigned a separate level-(j+1) stream. In every symbol, m₁ number of bits from the selected level-j stream selects the specific level-(j+1) partition and the corresponding level-(j+1) stream. Therefore, noticing that every level-j stream initiates Mⱼ number of level-(j+1) streams, the total number of streams, N_{T}, used by a N-level SPT scheme can be written as N_{T}=[1+Σᵢ₌₁^{N}(Πⱼ₌₁ⁱ Mⱼ)].

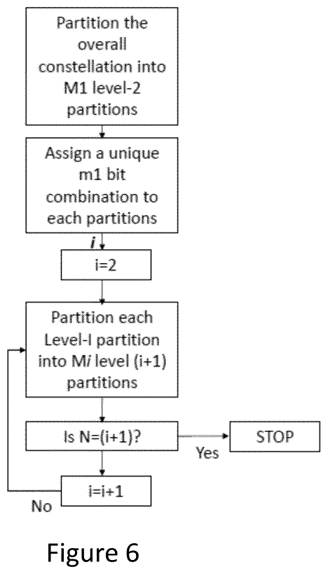

FIG. 6 shows the algorithm used to construct a N-level SPT signaling scheme starting from an overall M=Πᵢ₌₁^{N} Mᵢ-ary constellation. The algorithm starts by partitioning the overall M-ary constellation into M₁ level-2 partitions. Each level-2 partition is partitioned M₂ times to create level-3 partitions. This process is continued until level-N partitions are created. Note that the first m₁ bits of every symbol are taken from the level-1 stream, which is stream 1. These m₁ bits uniquely identify the level-2 partition and the corresponding level-2 stream selected for that symbol. The next m₂ bits of that symbol are selected from that level-2 stream. These m₂ bits uniquely indentify the level-3 partition and the corresponding level-3 stream. This process is continued until m_{N-1} bits from level (N−1) uniquely identity the level-N partition and the corresponding level-N stream. The last m_{N} bits of that symbol are taken from that selected level-N stream and those m N bits determine the specific constellation point on the selected level-N partition.

Note that every symbol is formed by taking mⱼ bits from level j, j=1,2, . . . , N. These mⱼ bits can be preferably arranged starting from level 1 and gradually increasing the level until level N. As a result, every symbol can be preferably formed by placing the m₁ bits taken from level-1 stream corresponding to that symbol at the beginning of the symbol, followed by the m₂ bits taken from the selected level-2 stream corresponding to that symbol, and so on up to the last m_{N} bits taken from the selected level-N stream corresponding to that symbol. The mapping on the overall constellation is done by observing that at every level j, 1≤j≤N, that every constellation point on the overall constellation belongs to one and only one level-j partition. With that observation, the mapping on the overall constellation is done to ensure that (a) the same combination of mⱼ bits of a symbol is assigned to all constellation points of any given level-(j+1) partition, and (b) Gray coding or any other preferable mapping policy is maintained by all mⱼ bit combinations of symbols among all level (j+1) partitions, by all levels j, 1≤j≤(N−1). In addition, the mapping on the overall constellation points should preferably ensure that the last m_{N} bits of every symbol that are taken from the selected level-N stream are assigned to different constellation points of each level-N partition to maintain Gray coding or any other preferable mapping policy in m_{N} bits within all constellation points of that level-N partition. Note that, all level-N partitioned constellations are 2^{m}^{_{N}}-ary partitioned constellations.

Partitioning of constellations has been in the literature. For example, Ungerboeck codes use set partitioning. Specifically, in set partitioning, a 2^{m}-ary constellation is partitioned into two sets every time until all partitions are down to 2-ary constellations. At that point one bit each of a coded stream is assigned to identify the division into the two partitions. As a result, a m-bit combination is determined for each constellation point. The SPT technique defers Ungerboeck's set partitioning in many ways as pointed out below:

1. Ungercoeck codes use one coded stream where as SPT technique uses multiple streams. In fact, each partition in SPT is assigned to a separate coded stream.

2. If an Ungerboeck code uses a 2^{m}-ary constellation, it needs to use m levels of partitioning until the partitioned constellations are finally 2-ary constellations. In SPT, the number of levels and the size of the partitions can be decided as desired.

3. Ungerboeck's set partitioning allows the resulting codes to achieve higher MSED values from a single coded stream. In SPT, due to the use of multiple coded streams, much higher MSED values than those achieved by set partitioning in Ungerboeck codes can be achieved. Further, SPT schemes can maintain different MSED values for different streams with some streams with much higher than the others.

4. Comparing with SPT coded schemes disclosed herein, Ungerboeck codes can be considered as 1-level SPT schemes. The SPT technology disclosed herein is focused on N-level SPT schemes with N≥2.

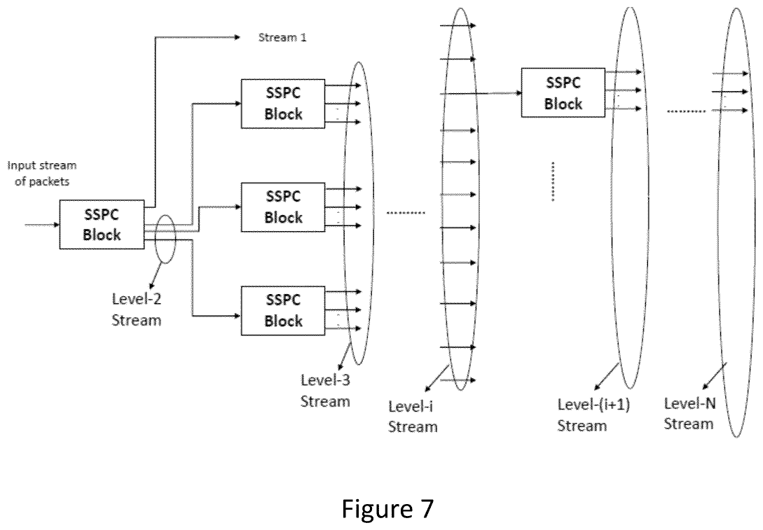

Note that the SSPC block shown in FIG. 2, which is referred to here as a basic SSPC block, describes how a single stream of packets can feed its packets in a structured manner onto all (M₁+1) streams of a 2-level SPT. The same basic SSPC block in FIG. 2 can be used repeatedly in a N-level SPT with N>2 to transmit a single stream of packets using a N-level SPT scheme and feed packets on that single stream in a structured manner onto N_{T} number of different streams of that N-level SPT scheme. FIG. 7 shows the construction of a super SSPC (S-SSPC) block, constructed using a number of the basic SSPC blocks shown in FIG. 2 and changing their M₁ value appropriately, to feed a single stream of packets into a N-level SPT when N>2. Note that a basic SSPC block in FIG. 2 is used in every partition. Since the constellation corresponding to all streams at levels 1 through (N−1) are partitioned, all streams at levels 1 through (N−1) of a N-level SPT require a separate basic SSPC as shown in FIG. 7. Hence, a N-level SPT scheme requires N_{S}=[1+Σᵢ₌₁^{(N-1)} (Πⱼ₌₁ⁱMⱼ)] number of basic SSPC blocks on streams at levels 1 through (N−1) to construct a S-SSPC block when a single stream of packets is used with a N-level SPT scheme to feed the packets in a structured manner into N_{T} streams of that N-level SPT.

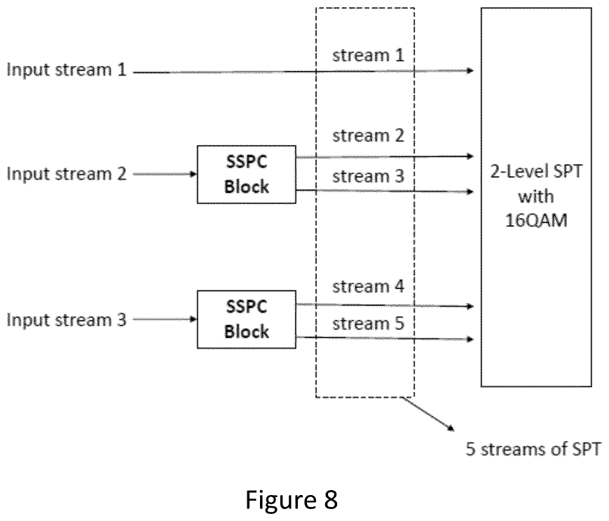

In some embodiments in multimedia type applications may require to transmit a number of streams, N_{P}, which is smaller than the number of streams of the SPT, N_{T}, i.e., N_{P}<N_{T}. In such embodiments, a modified S-SSPC block can be constructed using the same basic SSPC block in FIG. 2. In such applications, the construction of the S-SSPC shown in FIG. 7 can be modified to be used with a N-level SPT depending on the values of N_{P} and N_{T}. For example, consider an embodiment in a multimedia application that has three separate streams of packets in the application (N_{P}=3). For example, these three streams could be video, audio and data. Let us consider that the application uses a 2-level SPT with m₁=m₂=2 that employs a 16-QAM constellation. As described before, that 2-level SPT has one level-1 stream and four level-2 streams with a total of N_{T}=5 streams. In order to use this 2-level SPT for the application that has three streams, two separate basic SSPC blocks can be used as shown in FIG. 8 to construct a S-SSPC. As shown in FIG. 8, the first stream of the application is assigned to the level-1 stream of the SPT, the first two level-2 streams are generated by the second multimedia data stream using a basic SSPC block, and similarly the last two level-2 streams are generated by the third multimedia data stream using a second basic SSPC block.

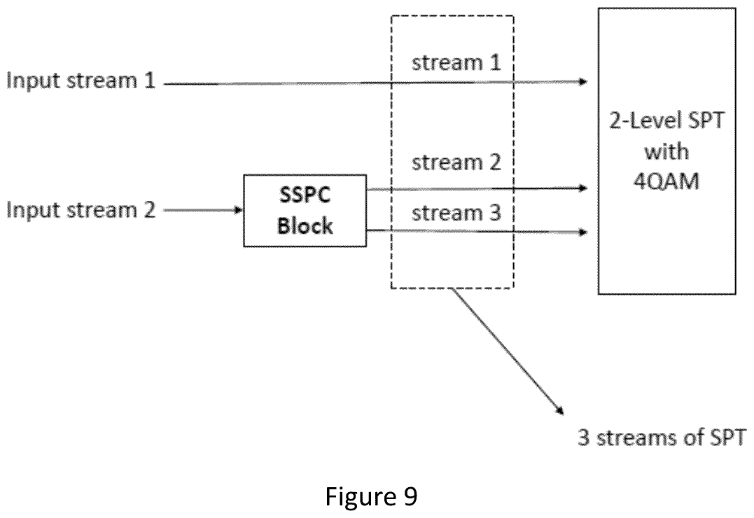

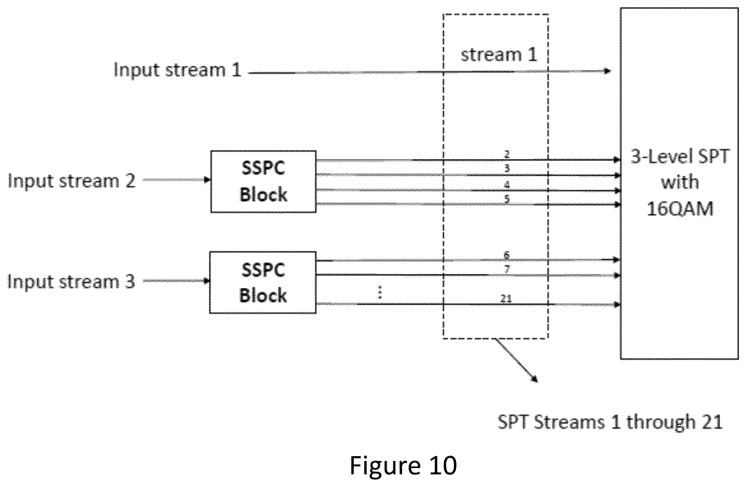

Another preferable way to transmit information in a multimedia application is to assign each level to a different signal type. As a second example, consider a multimedia application that transmits voice and data. Such an application can use a 2-level SPT that employs the 4-ary overall constellation shown in FIG. 1 to transmit data over stream 1 and to transmit voice over streams 2 and 3 at level 2 as shown in FIG. 9 by using a basic SSPC block at level 2 to feed voice packets into streams 2 and 3 in a structured manner. As a third example, consider a 3-level SPT constructed with a 16-QAM overall constellation. Assume that the 3-level SPT is constructed by partitioning according to M₁=4, M₂=M₃=2, m₁=2 and m₂=m₃=1. This 3-level SPT has one level-1 stream, four level-2 streams and eight level-3 streams. Consider the use of the above 3-level SPT for the transmission of three separate signals in a multimedia application. This can be done by feeding the three different multimedia data signals to streams at levels 1,2 and 3 with the help of two basic SSPC blocks as shown in FIG. 10.

Therefore, a S-SSPC block can be constructed using the basic SSPC block shown in FIG. 2 to generate all N_{T} different streams of a STP scheme using a single stream of packets or any number of Nₚ (<N_{T}) streams of packets. It is noticed that the S-SSPC block in FIG. 7 and the basic SSPC block in FIG. 2 can be used in other applications different from SPT encoding to combine different streams of operations. Specifically, a SSPC block can be used in any embodiment that needs to feed portions of one or few onto different parallel streams regardless of the specific operation (or operations) on the different parallel streams.

The SPT signaling technique disclosed herein can also be applied to constellations constructed using multiple orthogonal or nearly orthogonal dimensions. These dimensions can be formed in time domain, frequency domain, spatial domain, polarization domain, etc. For example, let us consider two frequencies in OFDM (orthogonal frequency division multiplexing) scheme where each frequency employs a 16-QAM constellation. As a result, the two tones jointly employ a 256-ary constellation. Therefore, the SPT technology disclosed herein can be applied to the joint 256-ary constellation by considering that joint 256-ary constellation as the overall constellation and partitioning it as described before to create different levels of the SPT. Similarly, the overall constellation in SPT can be constructed by considering multiple time intervals (separated in time domain) and multiple antennas (separated in spatial domain). Therefore, the SPT technology disclosed herein can be applied to overall constellations used in isolation or to overall constellations formed by combining constellations used in isolation that are separated in different orthogonal or almost orthogonal domains. These separations can be in time domain, frequency domain, spatial domain, polarization domain, etc.

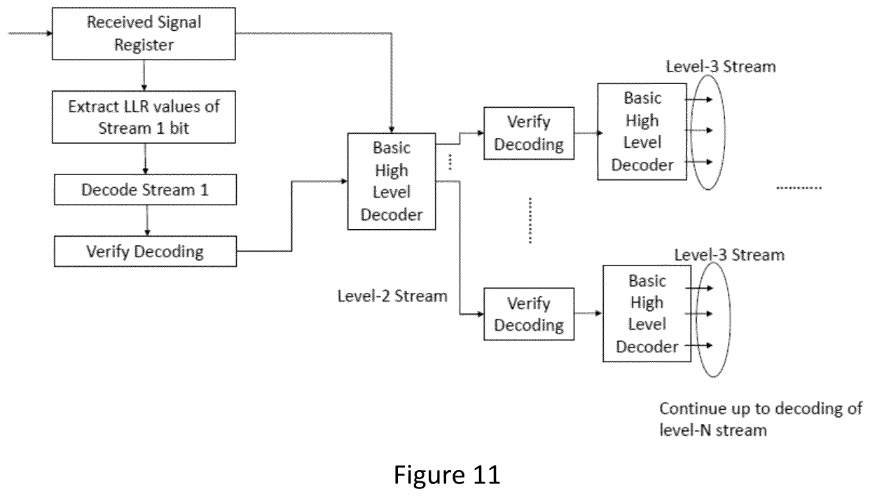

FIG. 11 shows the decoding of a N-level SPT by extending the decoding of 2-level SPT shown in FIG. 4. The decoding of level-2 streams in FIG. 4, highlighted in FIG. 4, is referred to as a basic higher level decoding. Basic higher level decoding is used multiple times for the decoding of a N-level SPT as shown in FIG. 11. The decoding starts by extracting the LLR values (bit metrics) of the bits on the stream at level-1 (stream 1). Once a packet of stream 1 is complete, decode that packet and verify that the decoding is correct. Preferably, a CRC can be used to verify that the decoding has correctly decoded each of its packets. In case stream 1 decoding fails to correctly decode, request re-transmission of that packet. Once a packet of the stream at level-1 has been decoded correctly, based on that decoded bits in blocks of m 1 bits, identify the level-2 partition and the corresponding level-2 stream that fed the level-2 bits (m₂ of them) of each symbol. Then calculate the LLR values of level-2 bits using the received signal on the identified level-2 partition. Once any packet at level-2 is complete, decode that level-2 packet and verify that the decoding was correct by preferably using a CRC. Using blocks of m₂ bits on the correctly decoded level-2 stream, identify the level-3 partition within the previously identified level-2 partition and the corresponding level-3 stream. Calculate the LLR values of m₃ level-3 bits of the respective symbols using the received signal on that identified level-3 partition. Continue this process up to level-N packets until all packets are decoded. Note that packets of a N-level SPT are decoded as they are completed and not in any particular order. Specifically, anytime all bit metrics of a packet become available, that packet is decoded. When a packet at levels 1 through (N−1) is decoded, verify that packet is decoded correctly by preferably using a CRC. All packets at level-N can optionally use a CRC but they are not required to do so as there are no higher levels that dependent on the decisions of those packets. As described before with a 2-level SPT, an artificial terminating packet can be used at the end on stream 1 to transmit the remaining bits of all packets at levels 2 through N. The received signal corresponding to the artificial terminating packet is used to extract the LLR values of all the remaining bits of partially transmitted packets on streams at levels 2 through N.

When a SSPC is used at the transmitter, the receiver can automatically identify the order of the packets fed into the SSPC at the transmitter by decoding all streams of the SPT. The decoder adopts a policy similar to that the SSPC adopted at the transmitter. Specifically, the SPT can recover the order of the packets, that was fed to the SSPC at the transmitter, correctly by assigning the decoded packets a packet number starting from according to the following rules: (a) assign the lowest possible packet number to the packet that is just starting to fill-in on any stream, (b) if more than one stream have packets starting in the same interval, assign the lower packet number to the packet on the stream with the lower stream number. When packets are decoded correctly on all streams at levels 1 through (N−1) of a N-level SPT, the above rules will arrange the packets in the same order that was fed to the SSPC at the transmitter.

So far decoding of any N-level SPT has been described by verifying the decoding of all packets on streams at levels 1 through (N−1). As described before, they can be verified preferably by using a CRC on each of the streams at levels 1 through (N−1). Optionally, SPT decoding can be done without verifying any decisions at levels 1 through (N−1). One option is to assume that the decoding of packets on stream 1 is always correct. This assumption can be mostly correct if the code used on stream 1 is a very powerful low rate code. However, any errors on stream 1 would distribute the LLR values of bits on streams other than stream 1 incorrectly into different streams at levels 2 through N. This incorrect distribution of LLR values causes decoding errors and misinforms the receiver the times at which the packets on streams at levels 2 through N end. Such a SPT scheme that does not check the decoding of packets on streams 1 through (N−1) can be improved by signaling to the destination anytime a packet on streams at levels 2 through N complete. Similar control signals are commonly transmitted over a separate control channel in practical systems such as in the 4G LTE system. For example, consider a 2-level SPT that employs the 4-ary constellation in FIG. 1 as described before. This 2-level SPT has one level-1 stream (stream 1) and two level-2 streams (streams 2 and 3) and uses m₁=m₂=1. Further, as described before with FIG. 1, stream 2 is assigned to a bit “zero” from stream 1 and stream 3 is assigned to a bit “one” from stream 1. For example, let us assume that each packet is 100 bits long. Suppose that a packet on stream 1 was decoded with errors which were however not checked by a CRC or by using any other method. When the LLR values of streams 2 and 3 are determined based on the decoded stream 1 using the respective partitioned constellations, due to errors on stream 1, it is most likely that the end of packets on streams 2 and 3 will be determined at the receiver incorrectly. However, the additional control signal that informs the receiver when packets on streams 2 and 3 end can be used to adjust the decoding on stream 1 so that the packets on streams 2 and 3 end at the correct times. Specifically, the receiver can make the most likely decision as to how many zeros are decoded in favor of ones, or how many ones are decoded in favor of zeros on stream 1. Then the receiver can go back to the decoding of frames in stream 1 and make the required number of changes in the least reliable positions of that decoded sequence on stream 1. For example, if the receiver is informed that stream 2 has just completed its frame when the receiver has calculated only 98 LLR values of the packet of stream 2 based on the decoded stream 1, it is most likely that two zeros on stream 1 have been incorrectly decoded as ones. At that point go back to the decoded stream 1 and identify the two ones on that decoded stream 1 with the lowest LLR values and flip them to zeroes. Then re-distribute the LLR values of the second bits of the symbols to align with the end of the packet of stream 2.

Even though both MLC schemes and SPT schemes employ multiple levels, SPT schemes differ from MLC schemes by employing multiple streams at all levels above the first level. The use of multiple streams at the second and higher levels allows those levels to employ higher rate codes and achieve the highest possible MSED for each higher level. For example, let us consider the constellation in FIG. 1. If the second bit of every symbol is always selected from a single second level stream as in a regular MLC scheme, the 3 dB advantage for the second levels streams achieved by the SPT scheme is not achieved. Therefore, the SPT schemes, by employing multiple streams at second and higher levels can achieve the highest possible MSED at each of those higher level streams.

It is important to note that the transmission rates on different streams of a SPT can vary from stream to stream. In fact, only the level-1 stream (stream 1) of any N-level SPT scheme has a fixed transmission rate, and the transmission rates on all other streams are random and they can vary from one transmission to the other. However, the average transmission rate on streams at levels 2 through N can be found based on the formation of symbols and the number of streams. For example, consider again the 2-level SPT that employs the 4-ary overall constellation shown in FIG. 1. This 2-level SPT employs one level-1 stream (stream 1) and two level-2 streams (streams 2 and 3). As discussed before, every symbol is formed by one bit from stream 1 and one bit from streams 2 or 3. Therefore, the average transmission rate on streams 2 and 5 is 50% of the transmission rate of stream 1. Therefore, when used for a multimedia application, streams of a SPT scheme can be assigned to different types of signals depending on the required data rates on those signals. Since, the code rate employed on streams 2 through 5 is higher than that on stream 1, the actual message transfer rate on streams 2 and 3 can be significantly higher than 50% of the message transfer rate on stream 1. Further, by appropriately employing SSPC units to combine different streams of a SPT, it is possible to achieve different desired rates on different signals of a multimedia application using a SPT.

Even though the SPT technology has been described using packets of the same size on all streams, the packet size can vary in a SPT. Specifically, the packet size can vary from one stream to the other or it can vary from packet to packet on any given stream. The basic SSPC block or the S-SSPC block described before does not impose any conditions on the packet size of different packets. Therefore, the basic SSPC block or the S-SSPC block described before can be used when the packet sizes vary from stream to stream or from packet to packet on the same stream or when all streams vary the packet size from packet to packet independently.

As stated before a SPT scheme employs N_{T} number of streams. During each interval N(<N_{T}) number of streams are selected to form the symbol transmitted during that interval. In order to select N streams out of N_{T} streams, the SPT schemes discussed so far employ partitions of the overall constellations. However, other strategies can also be adopted in a SPT scheme disclosed herein to select N streams out of N_{T} streams during each interval. For example, different combinations of N streams that can be employed during different intervals can be pre-selected from a bank of allowed selections of N streams. If desired these selections can be varied from interval to interval in a cyclic manner. Therefore, the SPT technique is considered as a technique that chooses N number of streams out of a total of N_{T} streams in the scheme to form the symbol transmitted during each interval.

The present application also discloses an implicit packet transmission (IPT) technique to transmit a stream of packets by transmitting the bits of that stream implicitly along with a stream of packets that is transmitted explicitly over a channel. The IPT technique can be combined with the SPT technique by applying the IPT technique to all or selected streams of a SPT scheme. The IPT technique employs two separate streams (a) an explicit stream, which is the intended transmitted stream and (b) an implicit stream which is transferred to the destination implicitly along with the explicit stream. The IPT technique teaches how an explicit stream can be combined with an implicit stream so that the implicit stream gets transferred to the destination implicitly without increasing the length of the explicit stream.

Let us describe the IPT technique starting with a binary coded explicit stream. In IPT, the coded explicit stream is altered based on the implicit stream prior to transmission. Specifically, the IPT technique disclosed herein inverts (flips) p(<n) bits out every n bits of the explicit stream before transmission, where p and n are positive integers. In other words, in every block of n bits of the explicit stream, p bits are selected and inverted prior to transmission. In the IPT technique disclosed herein, these p bits are selected based on the bits on the implicit stream. For example, when p=1 and n=16, one out of every 16 bits of the explicit stream is selected according to n_{S}=4 bits of the implicit stream and that selected bit is inverted before transmission. Note that the total number of bits transmitted is not changed due to the implicit bit stream. Note also that no bits of the implicit stream are directly transmitted over the channel. However, the information about the implicit bits is conveyed through the location of the bit that is inverted before transmission. Hence, in this example, for every four packets transmitted over the explicit stream, one packet is transferred implicitly to the destination from the implicit stream thereby increasing the overall throughput by 25%. It is also important to note that in IPT, all operations on the physical channel, such as the bandwidth, modulation technique, synchronization technique, demodulation technique, etc., can remain exactly the same as if only the explicit stream is transmitted. In general, if p bits out of every n bits are selected and inverted before transmission,

$${n}_{s} \leq {log}_{2} ( \begin{matrix}n \\ p\end{matrix} )$$

number of bits of the implicit stream can be transferred implicitly to the destination in every block of n bits of the explicit stream using the IPT technique, where,

$$( \begin{matrix}n \\ p\end{matrix} )$$

represents the number of ways p bits can be chosen from n bits.

If necessary both explicit data stream and the implicit data streams of a IPT scheme can be generated from a single data stream. This can be done by generating the two streams using a basic SSPC in FIG. 2 as described before. Unlike in SPT, the transmission rate on the implicit data stream of a IPT is fixed compared with the transmission rate on the explicit data stream. Specifically, when explicit stream transmits n bits, the implicit stream is guaranteed to transmit nₛ bits. Therefore, it is also possible to arrange packets to feed them into the explicit and implicit streams without using a basic SSPC block. For example, consider the IPT scheme with n=16, p=1 and nₛ=4 discussed before. When packets of same length are transmitted on both explicit and implicit data streams, packets can be fed to the IPT encoder 5 packets at a time. Four of those five packets (preferably packets 1 through 4) can be fed to the explicit stream while the other packet (packet 5) can be fed to the implicit code. Instead, if a basic SSPC block is used according to the same operating rules as discussed before, out of the same five packets, packet 2 would be fed to the implicit data stream while the other four packets would be fed to the explicit data stream. Therefore, in an IPT it is possible to use a basic SSPC block to generate both of its explicit data stream and its implicit data stream from a single data stream, or the packets can be fed according to a preselected rule based on the transmission rates on the two streams.

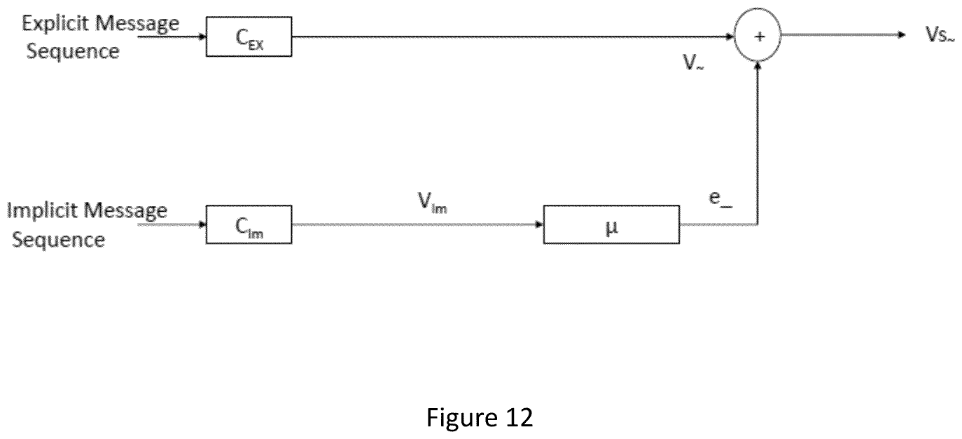

The inversion of p bits in every block of n bits is equivalent to generating an error sequence e of length n with Hamming weight p and adding that error sequence to the n bit long coded sequence of the explicit stream v, where the Hamming weight of a sequence which is also referred to as the weight in this document is the number of ones in the sequence. In other words, in every block of n bits of the explicit stream v, an n-bit long error sequence e with weight p is selected based on nₛ bits of the implicit stream, v_{Im}, and that error sequence e is added to the n-bit long block of the explicit stream v before transmission to obtain the transmitted sequence vₛ=v⊕e, where ⊕ denotes the exclusive OR operation. FIG. 12 shows the encoder of an IPT scheme that employs an explicit code C_{Ex} on the explicit stream and an implicit code C_{Im} on the implicit stream. The mapper M maps each nₛ-bit long sequence v_{Im} onto an error sequence e which is added to the corresponding n-bit coded sequence v of the explicit code to form the n-bit long transmitted sequence vₛ. As a result, for every n-bit sequence transmitted explicitly, the implicit sequence transmits nₛ bits implicitly. The mapper M can be easily implemented when p=1 and n=2ⁿ^{ₛ} which needs to map every nₛ-bit long coded sequence v im onto a unique n-bit long error sequence e with weight one. The position of the single ‘1’ in the error sequence can be easily found as [1-Fdec(v_{Im})], where, dec(v_{Im}) represents the decimal value of the nₛ-bit long implicit sequence v_{Im}. When p>1, the mapper M can be designed to map each sequence of v_{Im} onto an error pattern with weight between 1 and p uniquely in any particular order. As seen from FIG. 12, for every n bits transmitted over the channel carries information of n coded bits of the explicit stream and nₛ coded bits of the implicit stream. If the rate of the explicit code C_{Ex} is R_{Ex} and the rate of the implicit code C_{Im} is R_{Im}, the overall throughput is increased by a factor R_{Im}nₛ/(nR_{Ex}) by using the IPT technique.

In an IPT scheme, it is important to properly select the values of p and n depending on the power of the code C_{Ex} used on the explicit stream. Specifically, values of p and n should be selected to ensure that C_{Ex} can decode the explicit coded stream reasonably well even after adding the error sequence which inverts some of its bits. The easiest way to design an IPT scheme to achieve the highest nₛ/n ratio is to find the smallest value of n (which is a power of 2) so that the explicit code C_{Ex} on the explicit stream can still be able to decode the explicit stream reasonably well with a single bit inversion of the transmitted sequence, and then use that value of n and the corresponding value of nₛ=log₂ n to design the IPT scheme as illustrated in FIG. 12. Since p=1, as described before, the design of the mapper M in that embodiment becomes very easy.

So far the IPT technique is described to alter every n coded bits of C_{Ex} by adding an n-bit long error sequence generated based on the nₛ-bit long coded bits of C_{Im}. However, the alternation of the coded bits of C_{Ex} in an IPT scheme disclosed herein can be also be done in other ways instead of adding an error sequence to it. For example, these alterations can be done according to any linear or non-linear operation that would alter the coded sequence of C_{Ex} based on the coded sequence of C_{Im}. Some of these operations can even slightly increase the length of the coded stream of C_{Ex}. However, the total length of the altered sequence should be less than the sum of the lengths of the twp coded sequences of C_{Ex} and C_{Im}. The alternation in the coded sequence of C_{Ex} is done so that the receiver can use the received version of the transmitted altered coded sequence of C_{Ex} to recover both the coded sequences of C_{Ex} and C_{Im} separately.

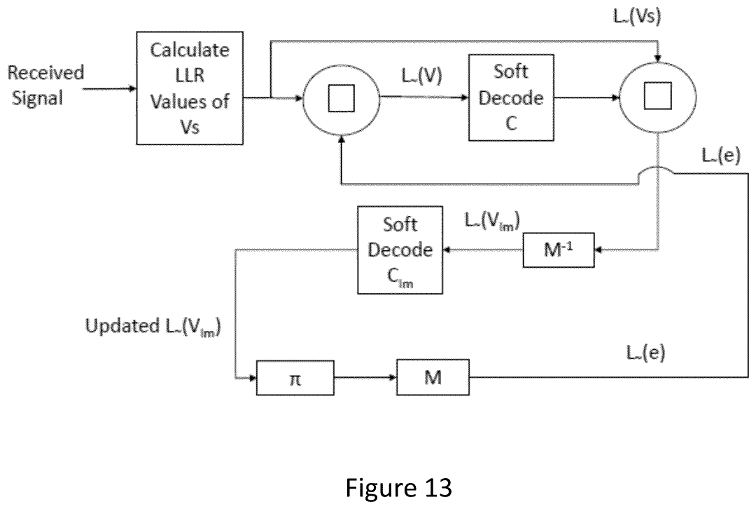

FIG. 13 shows the decoding algorithm of IPT signals to decode both the explicit coded stream and the implicit coded stream using soft iterative decoding. Since the decoding of explicit and/or implicit codes could require iterative decoding, such as the decoding of the turbo code employed in the 4G LTE system, the iterations between the explicit and implicit codes are referred to here as IPT iterations. Throughout the decoder, it is necessary to handle the soft information transfer from the exclusive OR operation (the modulo-2 addition) denoted by ⊕ which was performed during encoding as shown in FIG. 12. Specifically, if z=(x⊕y), the LLR value of z, L(z), can be found using the LLR of x, L(x), and the LLR of y, L(y), as

$$\begin{matrix}L ( z ) = log \frac{P ( z = 1 )}{P ( z = 0 )} = log \frac{P ( x = 1 , y = 0 ) + P ( x = 0 , y = 1 )}{P ( x = 0 , y = 0 ) + P ( x = 1 , y = 1 )} \\ = log \frac{P ( x = 1 ) P ( y = 0 ) + P ( x = 0 ) P ( y = 1 )}{P ( x = 0 ) P ( y = 0 ) + P ( x = 1 ) P ( y = 1 )} \\ = log \frac{exp ( L ( x ) ) P ( x = 0 ) P ( y = 0 ) + exp ( L ( y ) ) P ( x = 0 ) P ( y = 0 )}{P ( x = 0 ) P ( y = 0 ) + exp ( L ( x ) ) exp ( L ( y ) ) P ( x = 0 ) P ( y = 0 )} \\ = log \frac{exp ( L ( x ) ) + exp ( L ( y ) )}{1 + exp ( L ( x ) ) exp ( L ( y ) )}\end{matrix} \qquad ( 1 a )$$

$$\approx - sign ( L ( x ) L ( y ) ) min ( \vert L ( x ) \vert , \vert L ( y ) \vert ) \qquad ( 1 b )$$

Since x, y and z are all binary values, z=(x y) leads to y=(x⊕z) and x=(y⊕z). Hence, equations (1a) or (1b) can be used to calculate the LLR value of any one of the three bits x, y or z when those of the other two are known. The above equations (1a) or (1b) are used with LLR values of any kth coded bit v(k) of the explicit stream, L(v(k)), any kth error bit e(k), L(e(k)), and kth transmitted bit vₛ(k), L(vₛ(k)), throughout IPT iterations. Note that equations (1a) or (1b) operate on a bit by bit basis thereby lowering the decoding complexity. Specifically, since vₛ(k)=v(k)⊕e(k), equations (1a) or (1b) can be used to find the LLR value of either L(v(k)) or L(e(k)) or L(vₛ(k)) when the LLR values of the other two are known.

IPT iterative decoding algorithm consists of the following steps:

1. Using the received signal, extract the LLR values of the transmitted bits, vₛ(k), L(vₛ(k)) , k=1, 2, . . . , N, for all N bits transmitted in a frame. The values L(vₛ(k)), k=1, 2, . . . ,N, are also commonly known as channel information or the received bit metrics. The extraction of bit metrics from the received signal is well documented in the literature (Imai). Note that step 1 in regular IPT decoding is done only once to extract the bit metrics and the same set of L(vₛ(k)), k=1, 2, . . . , N, values are used throughout the IPT iterations. However, if the IPT technique is combined with BICM or CICM to improve performance that require updating the bit metrics on the constellation, step 1 needs to be included in the iterative process as in standard BICM with iterative decoding.

2. Using L(vₛ(k)) values found in step 1, and any soft information available for the error bits, L(e(k)), k=1, 2, . . . , N, calculate the LLR values of the coded bits of the explicit code v, L(v(k)), k=1, 2, . . . , N using either equation (1a) or (1b). Note that in the first iteration all L(e(k)) values are zero, and hence, L(v (k))=L(vₛ(k)), k=1, 2 . . . , N.

3. Using the L(v(k)), k=1, 2 . . . , N, values obtained in step 2, decode the explicit code C_{Ex} to obtain the update the LLR values of the explicit coded sequence L(v(k)), k=1, 2, . . . , N.

Note that in the first iteration decoding of C_{Ex} in step 2 has no useful information about the error bits introduced due to the inverted bits prior to transmission. Therefore, the decoded bits of the explicit code in the first IPT iteration have a lower reliability compared with the case when explicit coded bit stream v is transmitted without inverting any of its bits. However, the values of n and p can be selected in the design of the IPT so that the decoded bits of the explicit code v in the first IPT iteration are still reasonably reliable. In other words, the values of p and n are chosen so that the values of L(v(k)), k=1, 2 . . . , N, in the first iteration reasonably well resemble the actual coded explicit sequence v.

4. Using the LLR values of the transmitted bits, L(vₛ(k)), k=1, 2, . . . , N, found in step 1 and those the of the explicit code, L(v(k)), k=1, 2 . . . , N, found in step 3, obtain LLR values of the error bits e(k), L(e(k)), k=1, 2 . . . , N, on a bit by bit basis using either equation (1a) or (1b).

5. Use the de-mapping policy M⁻¹ that de-maps blocks of n-bit long the error sequences onto blocks of n₂-bit long implicit coded sequences to obtain the LLR values coded bits of v_{Im}. Note that the de-mapper de-maps every valid n-bit long error sequence eₖ=(eₖ(1), eₖ(2), . . . , eₖ(n)) onto a unique nₛ-bit long block of v_{Im}, v_{Im,k}=(v_{Im,k}(1) , v_{Im,k}(2) v_{Im,k}(nₛ)), k=1, 2 . . ., 2ⁿ^{ₛ}. Therefore, the calculation of L(v_{Im,k}(1)), l=1, 2, . . . , nₛ is similar to decoding a linear block code [Shu Lin]. Specifically, in every kth block of nₛ bits of v_{Im,k} and the corresponding n-bit long block of eₖ perform the following two steps: (a) using L(eₖ(j)), j=1, 2 . . . , n, values calculate a metric Λₖ, k=1, 2 . . ., 2ⁿ^{ₛ}, for each valid error sequence eₖ, and (b) from the de-mapping policy M⁻¹, calculate the LLR value of each implicit coded bit. L(v_{Im,k}(l)), l=1, 2, . . . , nₛ, within that kth block of nₛ bits of v_{Im}. Upon completion of step 5 for all blocks of nₛ bits of the implicit stream v_{Im}, all LLR values of v_{Im}, L(v_{Im}(1), L(v_{Im}(2), . . . , L(v_{Im}(N′), where

$${N}^{′} = N ( \frac{{n}_{s}}{n} )$$

is the total number of coded bits transmitted within the frame.

6. Soft decode C im and update the LLR values of each coded bit L(v_{Im}(l), l=1, 2 . . . , N′.

7. Perform the reverse operation of step 4 to obtain the LLR values of the error bits from the LLR values of v_{Im} obtained in step 6 according to the mapping policy M on a block by block basis. Note that the mapper maps every kth nₛ-bit long block of v_{Im}, v_{Im,k}=(v_{Im,k}(1), v_{Im,k}(2), . . . , v_{Im,k}(nₛ)) onto a n-bit long error sequence eₖ=(eₖ(1), eₖ(2), . . . , eₖ(n)), k=1, 2 . . . , 2ⁿ^{ₛ}. Specifically, in every kth block of nₛ bits of v_{Im}, perform the following two steps: (a) using L(v_{Im,k}(l)), l=1, 2, . . . , nₛ, calculate a metric Λₖ, k=1, 2 . . . , 2ⁿ^{ₛ}, for every combination v_{Im,k}, k=1, 2 . . . , 2ⁿ^{ₛ}, and (b) using the mapping policy M calculate an updated LLR of each error bit eₖ(j), L(eₖ(j)), j=1, 2 . . . , n. Upon completion of step 7 for each block of nₛ bits of v_{Im}, the updated LLR values of e, L(e(1)), L(e(2)), . . . , L(e(N)) are available.

8. Go back to step 2 for the next IPT iteration.

Note that after running several IPT iterations according to steps 1 through 8 listed above, the decoding of C_{Im} in step 6 would most likely have a very few or no errors. Therefore, at that point, the above algorithm can be modified to obtain a hard decoded sequence v_{Im} from the LLR values of v_{Im} obtained in step 6. Then use that hard decoded sequence v_{Im} in step 7. As a result, step 7 would simply reduce to selecting the n-bit long error sequence according to the mapper M corresponding to each of the nₛ bit long segments of v_{Im} obtained in step 6. In order to differentiate this modification, above described IPT decoding algorithm is referred to as the “initial IPT decoding algorithm”, and the algorithm with the modification in steps 6 and 7 discussed above is referred to as the “modified IPT decoding algorithm”. Hence, IPT iterative decoding disclosed herein can preferably run a preselected N₁ number of initial IPT decoding iterations followed by a preselected N₂ number of modified IPT decoding iterations. The values of N₁ and N₂ can be chosen depending on the component codes C_{Ex} and C_{Im}, and the frame length to achieve best performance.

Similar to SPT schemes described before, the IPT schemes can also employ different packet sizes and different powers of codes on the explicit and implicit streams. For example, when n=16, k=1 and nₛ=4, by choosing the packet size on the implicit stream to be 25% of the packet size on the explicit stream, when a packet on the explicit stream is complete, the packet on the implicit stream will also complete. Therefore, the IPT scheme can start decoding both the packet on the implicit stream and the packet on the implicit stream as soon as the receiver completes receiving the transmitted packet. Since the IPT decoder described above uses iterative decoding to decode both the packet on the explicit stream and that on the implicit stream jointly, the explicit code C_{Ex} helps the decoding of the implicit code C_{Im} and vice versa. Therefore, the power of the code C_{Im} can be reduced since the power of the code C_{Ex} helps decoding the packet on the implicit stream. Therefore, IPT embodiments can employ R_{Im}>R_{Ex}, or R_{Im}=R_{Ex}, or even R_{Im}<R_{Ex}.

In another aspect, the present application discloses a technique for using CICM with LDPC codes. Since most current communications systems today employ LDPC codes, it is highly desirable to be able to apply the CICM technique to LDPC codes and as a result to be able to transmit LDPC coded bits using higher order modulation while performing better than if they were to be transmitted using a lower order modulation scheme. In addition, it would be highly desirable for such a LDPC coded scheme with CICM to be able to process one LDPC codeword at a time thereby eliminating any increase in decoding delay and memory. If CICM can be applied to a single codeword of a LDPC code, its coded bits could potentially be transmitted using 16-QAM or even 64-QAM modulation while performing better or similar to employing QPSK modulation for transmission. As a result, application of CICM to LDPC codes can potentially more than double the transmission rate. In accordance with this aspect of the present application, a simple method of applying CICM to LDPC codes is presented while decoding one codeword of the LDPC code at a time.

A LDPC code can be viewed as a long code that has a collection of a many single parity check (SPC) codes. Each parity check is formed by a few variable nodes (represented by coded bits) and one check node, where, each check node receives information from several other variable nodes. Effectively, each row of the parity check matrix H of a LDPC code corresponds to a SPC code of that LDPC code. As a result, a LDPC code inherently contains a large number of short SPC codes in it. Since the CICM technique requires consideration of a large number of codewords, these short SPC codes can be used as the required codewords in the application of CICM. As a result, CICM can be applied to a single codeword of the LDPC code without having to consider multiple codewords of it.

In order to describe how the CICM technique can be applied to LDPC codes, let us consider a general LDPC code with n variable nodes (VNs), denoted by v_i, i=1, 2, . . . , n, and L check nodes (CNs), denoted by c_j, j=1, 2, . . . , L. Let us denote the set of ki connections stemming from any general VN vi to its associated CNs, denoted by c_j_1(i), c_j_3(i), . . . , c_j_k_i(i). Similarly, let us denote the set of el_j connections stemming from any general check node c_j to its associated VNs denoted by v_i_1(j), v_i_2(j), . . . , v_i_el_j(j).

As with block codes, it is assumed in the application of CICM to LDPC codes that errors would be limited to only a small number of coded bits as SNR increases. Specifically, it is assumed that the errors are limited to a set of variable nodes formed by starting from any single variable node vi and (a) following all paths that emerge from vi to the check nodes, and (b) then considering each of those check nodes back to a set of variable nodes. This set of variable nodes formed by the above steps (a) and (b) including vi, denoted by S_i, is the set of variable nodes referred to as the associated variable nodes (AVN) of the variable node vi. Therefore, in the application of CICM to LDPC codes, it is assumed that errors that occur are limited to a single Si as SNR increase. Following the above method, it is possible to obtain the corresponding set of AVN for each variable node vi, i=1, 2, . . . , n. The set of AVNs, S_i=1, 2, . . . , n, are used to design the required CICM Interleaver. The goal of the CICM Interleaver is to place each coded bit of every AVN in different transmitted symbols of the 2\hat{ }m-ary constellation used for transmission. First notice that in order to transmit n coded bits using a 2\hat{ }m-ary constellation, it is necessary to use W=n/m symbols. Therefore, the aim of the CICM Interleaver in LDPC codes is to place the coded bits (variable nodes) in a m by W 2-dimensional array, called the symbol array (SA), with m rows and W columns with the aim of forming m-bit long symbols along columns to form W symbols for transmission. The objective of this CICM Interleaver is to satisfy the following condition:
no two coded bits of every Si, i=1, 2 . . . , n, are placed in the same column of the SA.

However, in situations where it is impossible to satisfy the above condition, the Interleaver can be preferably designed to maintain that the coded bits of each Si are placed in as many columns as possible in the SA.

There can be many valid SAs that satisfy the above condition for all Sis, i=1, 2 . . . , n. In the design of the SA, the goal is to find one such valid SA that satisfies the above condition. Many search algorithms can be developed to search for a valid SA starting from the set of Sis of a given LDPC code with n coded bits and a given value of m. One such strategy would be to place coded bits in the SA with the aim of maintaining the number of unplaced coded bits of each Si about the same for all Sis while placing bits in the SA. This strategy allows more flexibility towards the end to fill out the remaining openings of the SA without violating the above condition. Whenever, bits are selected from each Si, they can be selected either randomly or in some systematic manner such as from left to right or from right to left . In failing to find a valid SA, the process can be repeated until a valid SA (or the best possible SA) is found. An alternate strategy would be to place one Si at a time in the SA. This can be preferably done starting with the Si that has the largest number of coded bits and moving down to the Si with the lowest number of coded bits. The hope in this approach is to have all remaining places of SA in the end to fit into all remaining shorter Sis without violating the above stated condition. Again, coded bits of each Si can be either randomly selected or systematically selected, and further, the search can be repeated until a valid SA that satisfies the above stated condition.

Another approach is to design the CICM Interleaver by following the method for block codes. In this approach, Sis are treated as separate codewords. However, an adjustment is necessary since the same coded bit can appear in many Sis whereas in case block codes all coded bits are separate. This can be overcome by removing all remaining (disregarding) appearances of the same coded bit from other Sis once that coded bit is placed in SA.

It is noted here that the Interleaver design is done once prior to transmission and hence time and effort in searching for a valid SA does not contribute to the decoding delay or decoding complexity. The generated symbols from the SA are then transmitted using a signal constellation that employs RGC.

In yet another aspect, the present application discloses a technique for decoding LDPC codes with CICM. In general, CICM decoding requires iterative decoding while involving the constellation during decoding iterations. Since LDPC decoding already uses iterative decoding, the same LDPC iterations can be used to include the constellation. However, the decoder needs to use the same CICM Interleaver used at the transmitter when transferring information from the variable nodes to the constellation and the corresponding de-Interleaver when transferring information from the constellation back to the variable nodes. Checking with the constellation could be done every iteration or every N′th iteration (N′>1) depending on the situation. For example, if N=20 LDPC iterations are used, the constellation could be included after every N′=5 iterations.

It should also be understood that the various different communication techniques disclosed herein, including but not limited to the SPT techniques, the IPT techniques, and the CICM techniques, could be utilized together in any of various manners.

The technology disclosed herein can be used with any communication link that transmits a stream of data from the transmitter to the receiver. The data can be in the form of frames or packets of bits, or in the form of individual bits. These frames or packets of bits, or individual bits can be originated from different types of data signals such as those found in multimedia type applications. For example, these signals in a multimedia application can be video and voice, or voice and data, etc. The technology disclosed herein can also be used when multiple packets or bits that are originated from the same type of data signals, such as voice only or data only, etc. Therefore, the technology disclosed herein is applicable to any communication link that transmits multiple packets or multiple bits originated from the same data signal or different types of data signals. Therefore, the technology disclosed herein is applicable to practically all communication systems. Specifically, the technology disclosed herein can be applied on the uplink and downlink of the 4G LTE and 5G systems, the uplink and downlink of WiFi systems, transmission over the OTN, for the transfer of data between a cloud and a user in cloud computing, in communication links of internet of things, or any other system alike. The technology disclosed herein can also be applied in medical applications, for transferring information collected by a single or a collection of sensors to (a) medical devices using a wired or a wireless channel, or (b) to a smart phone for transmission to a remotely located physician, etc.

In one aspect, the technology disclosed herein includes at least two separate techniques: the SPT technique and the IPT technique. It also includes the SSPC unit. The SPT and IPT techniques enhance the overall throughput of a communication link. Both of these two techniques do not require any hardware modification in the actual transmission system. Instead, they both only require simple software modifications at the transmitter in the encoding of data and at the receiver in the decoding of data. Any communication link can employ either the SPT technique or the IPT technique individually or it can employ both the SPT technique and the IPT technique jointly to further enhance the throughput. The SSPC unit can feed a single stream of data into parallel streams in a structured manner. The parallel streams can process the data at different rates and speeds. Therefore, the SSPC unit can be used with a SPT scheme or an IPT scheme, or it can used with any parallel processing system where the processes can perform any operation. In SPT and IPT techniques, the operations are coding operations. Other operations that can employ SSPC include packaging, routing, scheduling, etc., which include distributing different tasks into different branches, divisions, etc.

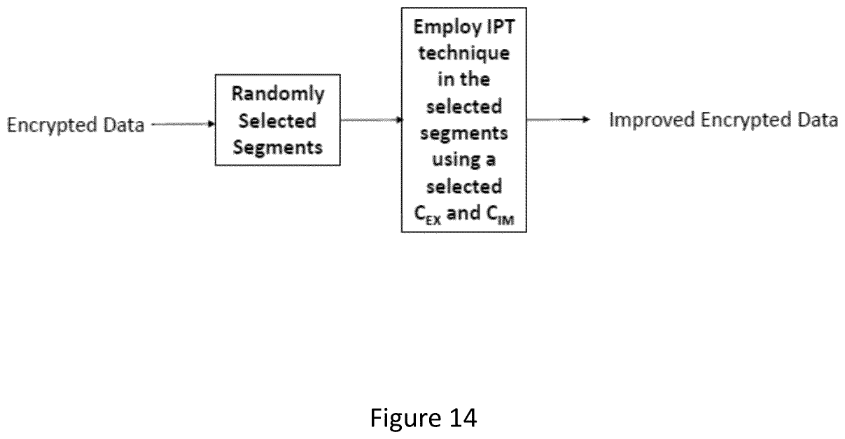

One other important application of the IPT technique is in encryption and security of transmission. The IPT can be effectively employed in a communication link to add an extra layer of encryption by employing the IPT technique in selected portions of the entire data stream. The selected portions can be jointly decided by the transmitter and the receiver. FIG. 14 shows the structure of a communication link where IPT adds an extra layer of encryption to an already encrypted stream of data. The encrypted data using the first layer of encryption is divided into an explicit stream and an implicit stream in selected portions of the data stream. If an intruder is to recover the data stream correctly, the intruder first needs to know the portions of the stream that has employed the IPT technique. In addition, different implicit codes can also be used in the different portions in which the IPT technique is used to further improve security of the transmission. The same method can be used for secure data storage. The data can be stored as an IPT encoded signal which has an explicit and an implicit data stream. In addition, the IPT technique can be inserted in selected portions of the stored data to introduce a second layer of security of the stored data as described before. If an intruder is to recover the actual information from the stored data, the intruder would need to first know the portions where the IPT technique has been used and what explicit and implicit codes have been used in each of those portions to create those IPT signals. The IPT signal can be formed on an already encrypted data thereby making the IPT signaling portion to act as a second layer of security.

Consider a 2-level SPT embodiment that employs three streams, streams 1, 2 and 3, and an overall 4-ary QPSK constellation and the mapping shown in FIG. 1. Such 4-ary constellations are very common in practice. For example, a 4-ary constellation shown in FIG. 1 is commonly used on the downlink of the 4G LTE when the channel between the base station and the user is weak. However, in most common signaling systems, such as in the current 4G LTE standard, Gray coding is commonly used instead of the mapping policy shown in FIG. 1. According to the SPT technique described before, a 2-level SPT embodiment shown in FIG. 6 with the signal constellation shown in FIG. 1 employs one first level stream (stream 1) and two second level streams (streams 2 and 3). The first bit of every symbol is taken from stream 1 while the second bit is taken from stream 2 if the first bit of the symbol is a “zero” and from stream 3 if the first bit of the symbol is a “one”. The 4-ary overall constellation is partitioned into two 2-ary partitions as shown in FIG. 1. The partition 1 in FIG. 1 is assigned to stream 2 and is used when the first bit of every symbol is a “zero”. Similarly, the partition 2 is assigned to stream 3 and is used when the first bit of every symbol is a “one”. If all packets are of the same type, a basic SSPC block shown in FIG. 2 designed as described before can be used to systematically feed the packets into different streams of the SPT scheme. At the end of the transmission, as described before, an artificial terminating packet can be introduced on stream 1 to complete any partially completed packets on streams 2 and 3. If the packets are from different types of signals as in a multimedia application, different streams can represent different types of signals. In some embodiments, all streams at a particular level can be the same type of signals, For example, in a multimedia application that transmits data and voice, stream 1 can be formed by data while streams 2 and 3 can be formed by voice. In such embodiments, as described before, a basic SSPC block can be used as shown in FIGS. 9 and 10 to feed packets into different streams at the same level. As described before, streams 2 and 3 of this 2-level SPT scheme that uses the signal constellation in FIG. 1 have a 3 dB advantage over stream 1. Therefore, this 2-level SPT embodiment can employ a code with a significantly higher rate on streams 2 and 3 than the rate of the code employed on stream 1. As a result, this 2-level SPT embodiment can have a significantly higher overall throughput over a scheme that employs the same constellation with Gray coding to transmit a set of packets a using single stream of packets. Since every symbol carries one bit from stream 1 and one bit from streams 2 or 3, the overall rate of the 2-level embodiment is R=(R₁+R₂)/2, where R₁ is the rate of the code used on stream 1 and R₂ is the rate of the code used on streams 2 and 3. For example, in LTE application, if the R₁=⅓ and R₂= 4/7, then R=0.452, representing a 35.6% increase in the overall throughput over a traditional turbo coded scheme with rate ⅓.

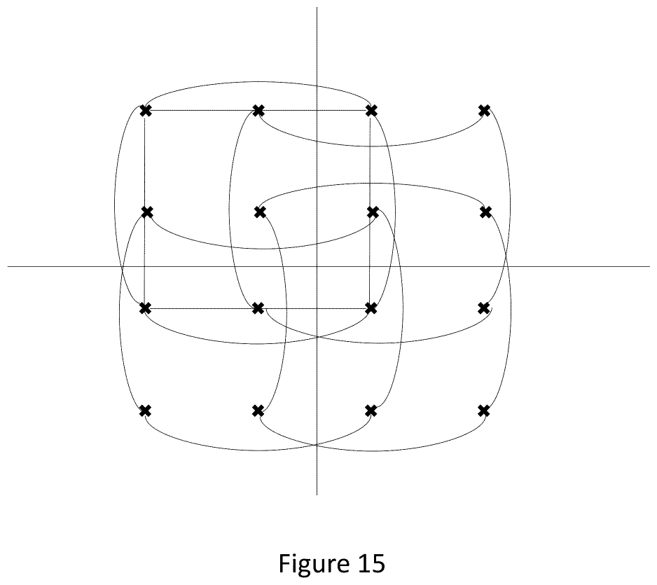

Consider a second 2-level SPT embodiment that employs a 16-QAM overall constellation as shown in FIG. 15. The 16-QAM overall constellation is partitioned into four 4-ary partitioned constellations as highlighted in FIG. 15. Therefore, in this embodiment shown in FIG. 15, M=16, M₁=M₂=4 and m₁=m₂=2. Therefore, the first two bits (primary 2 bits) of every symbol identifies the specific partition as shown in FIG. 15. As a result, this 2-level SPT has one primary stream (stream 1) and four secondary streams (streams 2 through 5). As shown in FIG. 15, Gray coding is maintained for the first two bits of every symbol among the four partitions, and Gary coding is also maintained among the last two bits of constellation points within every 4 -ary partitioned constellation. During transmission, the first two bits of every symbol which are taken from stream 1 identify the specific partitioned constellation and the associated stream which feeds the last two bits of that symbol. Specifically, the embodiment shown in FIG. 15 assigns the first two bit combinations “00”, “01”, “10”, and “11” to streams 2, 3, 4 and 5 respectively and the corresponding respective partitioned constellations are highlighted in FIG. 15. As described before, all partitioned constellations have a 6 dB advantage over the overall signal constellation. Therefore, bits on streams 2 through 5 have a 6 dB advantage over those on stream 1. Therefore, the rate of the code employed by streams 2 through 5, R₂, can be significantly higher than the rate of the code employed on stream 1, R₁. Since every symbol carries two bits from stream 1 and two bits from one of the streams 2 through 5, the overall rate of the SPT scheme is R=(R₁+R₂)/2.

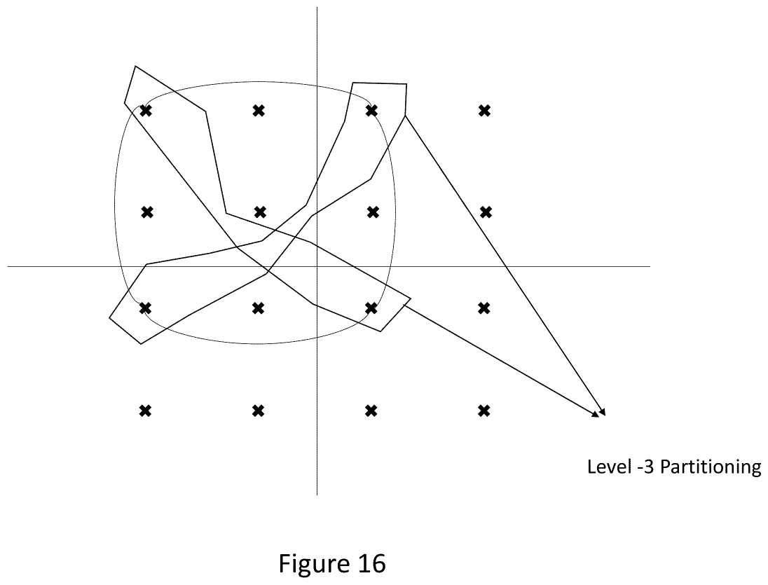

The above embodiment can be modified to form a 3-level SPT embodiment by sub-partitioning each 4-ary partitioned constellation into two 2-ary sub-partitioned constellations. FIG. 16 illustrates one selected level-2 partitioning and the two level-3 partitionings in that level-2 partitioning. Since the overall 16-QAM constellation is partitioned into four level-2 partitioned 4-QAM constellations, there is one primary stream (stream 1), and four level-2 (or secondary) streams (streams 2 through 5). Similarly, since each level-2 partitioned constellation is further partitioned into two level-3 2-ary partitioned constellations, each level-2 stream initiates two level-3 streams (tertiary streams), and therefore, there are eight level-3 streams (streams 6 through 13). Therefore, the 3-level SPT that employs the 16-QAM constellation shown in FIG. 16 employs thirteen streams in total. Every symbol is formed by two bits from the level-1 stream 1, one bit from one of the level-2 streams (streams 2 through 5), and one bit from one of the level-3 streams (streams 6 through 13). This 3-level SPT forms symbols as described below: (a) first two bits of the symbol that are taken from stream 1 decide one of the four level-2 partitioned constellations and the corresponding level-2 stream from streams 2 through 5 as shown in FIG. 16, (b) 3rd bit of the symbol which is taken from the level-2 stream identified in (a) is used to identify the level-3 partition within the selected level-2 partitioned constellation and to select the corresponding level-3 stream (from streams 6 through 13), and (c) the 4th bit of the symbol which is taken from the identified level-3 stream select the specific constellation point from the selected level-3 partitioned constellation. Note that all level-2 bits have a 6 dB advantage over the primary bits, and all level-3 bits have a 9 dB advantage over primary bits. Therefore, if the rates of the codes employed for level-1, level-2 and level-3 bits are R₁, R₂ and R₃ respectively, their values can be chosen according to R₃>R₂>R₁. Since every symbol carries two level-1 bits, one level-2 bit and one level-3 bit, the overall rate of the 3-level SPT shown in FIG. 16 is R=(2R₁+R₂+R₃)/4.

Consider the comparison of a SPT scheme that employs multiple streams with a traditional coded scheme that employs a single stream that uses Gray coding on the constellation. Since the SPT technique alters the mapping from Gray coding, depending on the code employed, the rate of the code on stream 1, R₁, may need to be lowered below the rate of the traditional coded scheme, R′, in order to make the frame error rate of stream 1 about the same as that of the traditional coded scheme, However, since the code rate on the remaining streams of a SPT can be significantly higher than R′, the overall code rate R of the SPT can be significantly higher than R′. Therefore, depending on the application, the code rates on different streams of a SPT can be selected to achieve the highest increase in the overall code rate above the code rate of a traditional coded scheme,

Another preferred 3-level SPT embodiment can be constructed with a 64-QAM constellation. This embodiment is constructed with parameters M=64, M₁=M₂=M₃=4 and m₁=m₂=m₃=2. FIG. 5 shows one level-2 partitioning and one level-3 partitioning within that level-2 partitioning of that 64-QAM constellation. Therefore, the overall 64-QAM constellation is partitioned into four level-2 partitioned 16-QAM constellations. The specific partition and the corresponding level-2 stream (from streams 2 through 5) is selected according to the first two bits of every symbol which are taken from stream 1 (level-1 stream which is also called primary stream). Each partitioned 16-QAM constellation is further partitioned into four level-3 partitioned 4-QAM constellations. The specific level-3 partitioned constellation and the corresponding level-3 stream (streams 6 through 21) from the selected level-2 partitioned constellation is selected according to the 3rd and 4th bits of the symbol which are taken from the selected secondary stream. The 5th and the 6th bits of the symbol taken from the selected level-3 stream select the specific constellation of the selected 4-ary sub-partition.

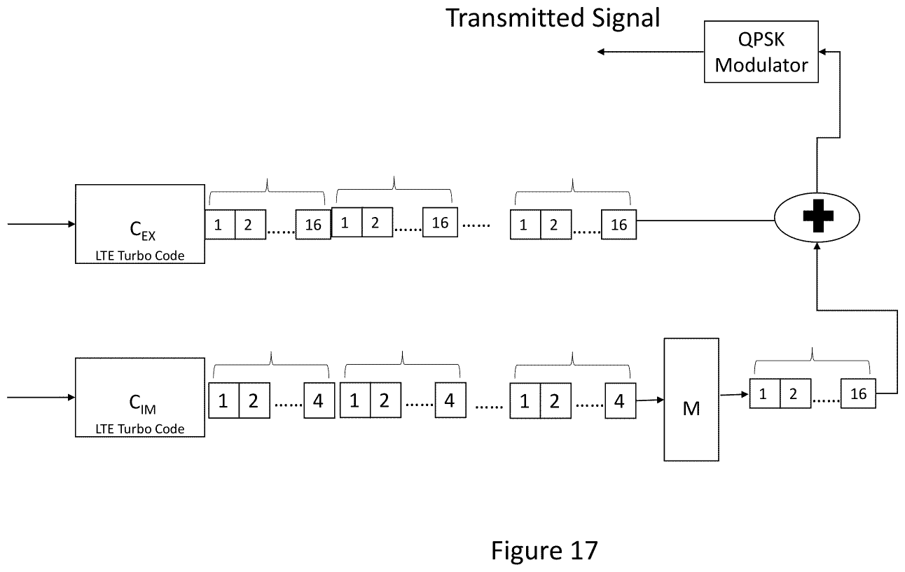

FIG. 17 shows an embodiment that uses the IPT technology described before. The explicit code C_{Ex} and the implicit code C_{Im} can be the 4G LTE turbo code. This embodiment uses of n=16, k=1 and nₛ=4 to increase the throughput by 25% when both C_{Ex} and C_{Im} have the same rate As stated before C_{Im} can be a higher rate code than C_{Ex}. The embodiment in FIG. 17 employs a 4-ary constellation with Gray coding. In general any 2\hat{ }m-ary constellation with Gray coding or any other mapping policy on the constellation can be used with IPT signaling. As described before, if the IPT technique is coupled with BICM or CICM other mapping policy can be preferably used to enhance performance.

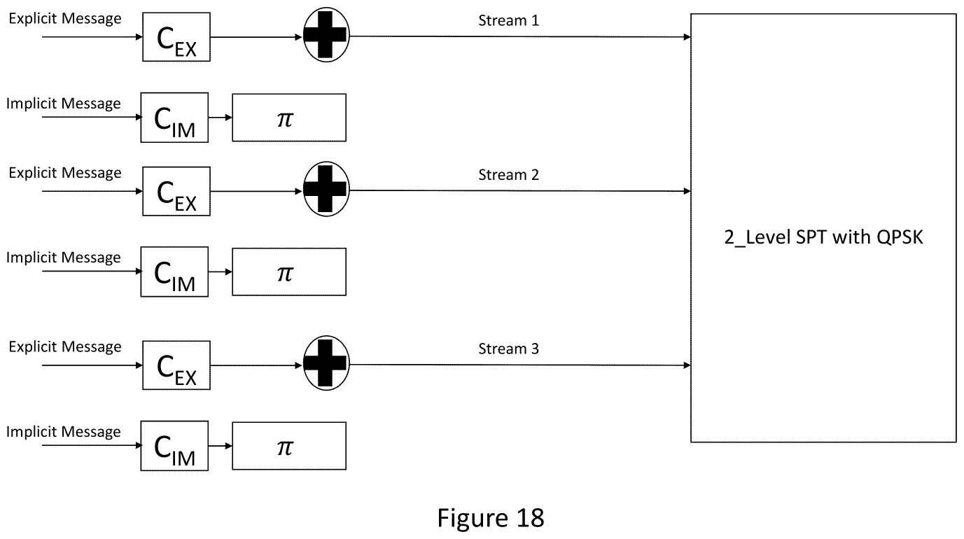

FIG. 18 shows an embodiment that uses both SPT and IPT techniques simultaneously by employing the IPT technique on each stream of a SPT scheme. FIG. 18 shows the use of the IPT technique on each of the three streams of the 2-level SPT scheme described in FIG. 6 that employs a 4-ary constellation shown in FIG. 1. The explicit code C_{Ex} and the implicit code C_{Im} of the three streams can be selected differently from stream to stream. In general, each stream at every level of an SPT scheme can transmit an explicit stream and an implicit stream separately by using the IPT technique. Different embodiments can use the IPT technique at only selected streams of a SPT scheme. Since an N-level SPT needs to correctly decode all streams at levels 1 through (N−1), IPT technique can only be used at the Nth level to reduce complexity.

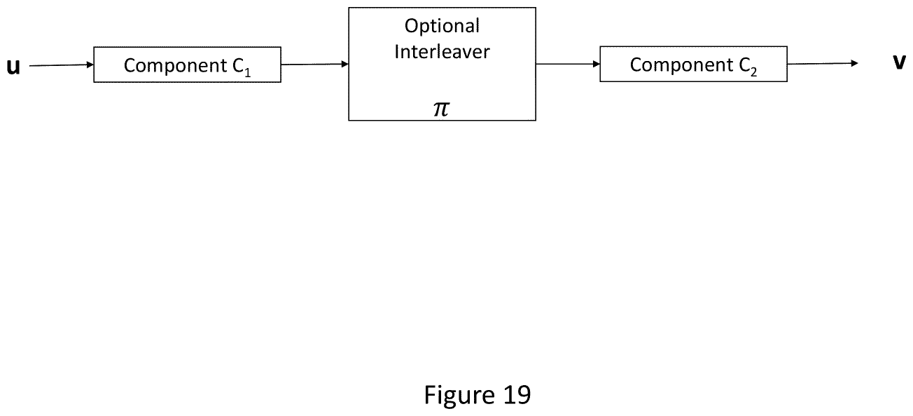

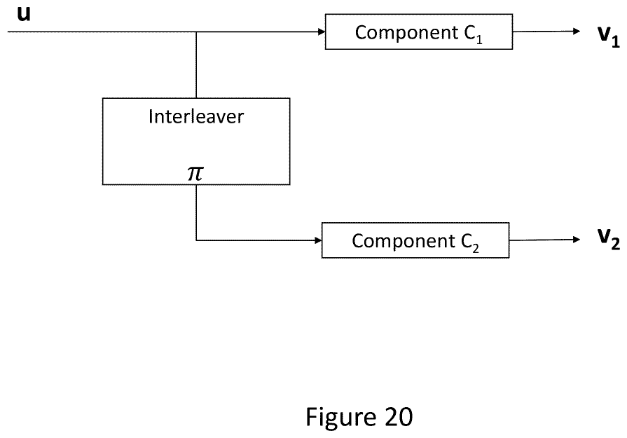

In the following paragraphs, the concept of implicit transmission with bit flipping (ITBF) is explained. Let us consider two components, C₁ and C₂, of a communication system with an incoming sequence u and outgoing sequence v and an optional interleaver π connected as illustrated in FIG. 19. The sequences u and v can be the message sequence and the coded sequence, or they can be two sequence in the middle of processing at the transmitter. Further, C₁ and C₂ can be (a) two component block codes of a turbo product code (TPC), or (b) any two types of component codes of a serial concatenation from the family of block codes or convolutional codes, or (c) a code and a modulator in a coded modulation system that employs any single code such as a block code, and/or a convolutional code, and/or a turbo code and/or a low density parity check (LDPC) code. The technology disclosed herein applies to a coded system or a coded modulation system where the two components C₁ and C₂ carry out some processing like encoding or modulation at the transmitter, and the same two components provide soft information of their input and the output streams of bits at the receiver. Similarly, the technology disclosed herein also applies to configurations of two components C₁ and C₂ with input u and output (v₁, v₂) and an optional interleaver as illustrated in FIG. 20. If necessary, the number of outputs can be more than two. The components C₁ and C₂ of FIG. 20 can be two component codes of a parallel concatenated code with an interleaver which is also well known in the literature as a turbo code. Therefore, FIG. 19 and FIG. 20 are applicable to almost all communication systems in practice including 4G and 5G systems.

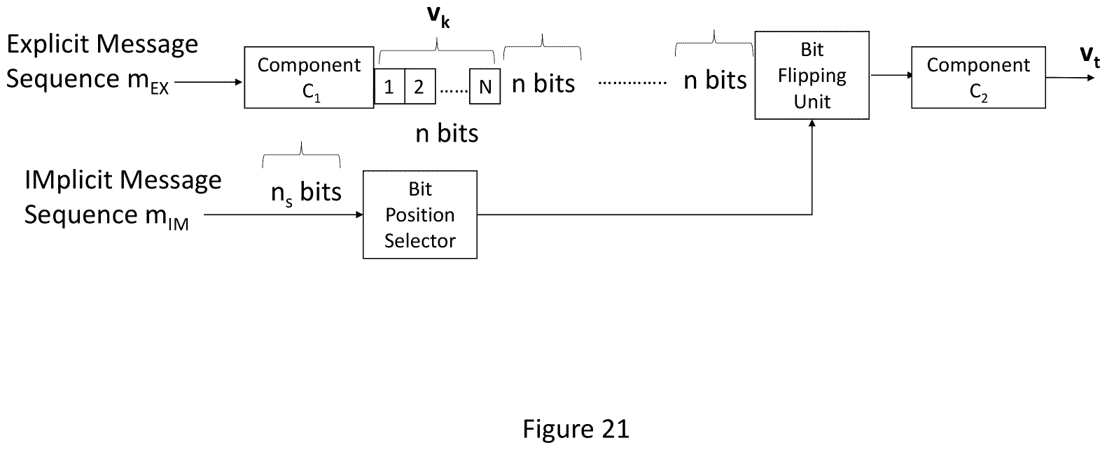

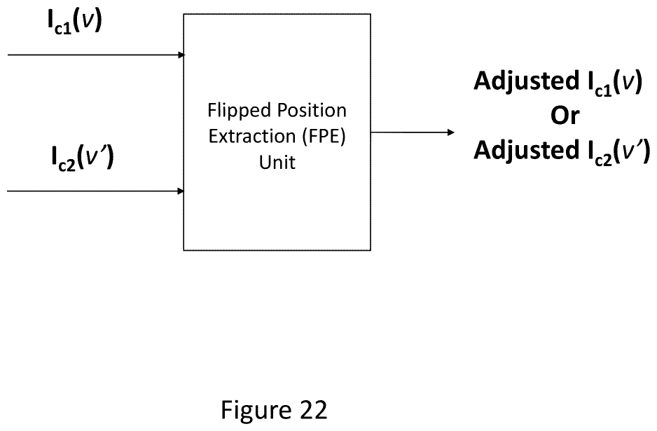

This aspect of the present disclosure, referred to as implicit transmission with bit flipping (ITBF), describes a technique that allows transmission of additional information implicitly in a communication system that includes two components as illustrated in either FIG. 19 or FIG. 20. The ITBF technique is based on the observation that the information about the output of C₁ is provided by C₁ and also by C₂ as its input. FIG. 21 describes the processing that takes place at the transmitter when the ITBF technique is applied to the configuration in FIG. 19. As illustrated in FIG. 21, the transmitter (a) divides the output sequence of C₁, v, into blocks of a pre-selected number of n bits, (b) selects one bit from it in each block of n bits uniquely in a bit position selector based on nₛ=└log₂n┘ number of implicitly transmitted bits from a separate implicit information stream, and (c) flips that selected bit on v in a bit flipping unit to form the sequence v′ before forwarding it to C₂ via an optional interleaver, where, └.┘ denotes the standard floor function. If necessary, the optional interleaver could be placed before the bit flipping unit too. The output of the bit flipping unit, v′, is the sequence processed by the component C₂ to form the transmitted sequence vₜ as shown in FIG. 3. FIG. 3 highlights the flipping operation for any general kth block of n bits of v, vₖ, to form the kth block of v′, v′ₖ. Note that the implicit stream is a pure information stream without any coding. Further, note that C₁ sees every n bit block at its output without the flip (which is v) while C₂ sees the output of C₁, which is at the input of C₂, with the flip (which is v′). Therefore, the information carried by every block of nₛ implicit bits during the transmission of every block of n bits of v (which is delivered by the flipped bit position) can be extracted by comparing the information of v′ provided by C₂, I_{C}_{₂} (v′) and the information of v provided by C₁, I_{C}_{₁} (v). In accordance with the present disclosure, it is proposed that the comparison of I_{C}_{₁} (v) and I_{C}_{₂} (v′) is done by using a flipped position extraction (FPE) unit as illustrated in FIG. 22. However, all other methods that use I_{C}_{₂} (v′) and I_{C}_{₁} (v) to handle the flipped bit are within the scope of the present disclosure.

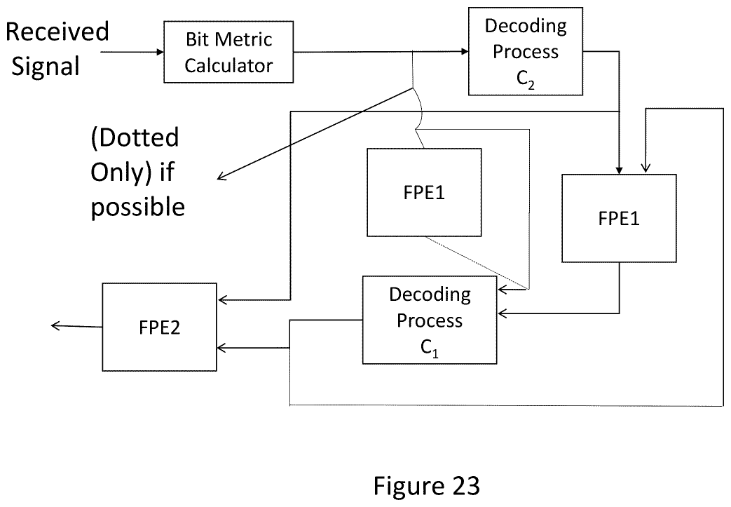

ITBF decoding can be performed iteratively by running soft or hard iterations between components C₁ and C₂ as illustrated in FIG. 23. However, when exchanging information from C₁ to C₂ and from C₂ to C₁, it is necessary to employ a FPE as shown in FIG. 23. In many known applications without any flipping (i,e, v=v′), such as in a turbo product code (TPC), the output of C₁ (v) is also directly transmitted as a part of the transmitted sequence vₜ. In such applications, C₁ carries channel information in addition to the extrinsic information obtained from C₂. When ITBF technique is used in such applications, channel information (also known as bit metrics) of v′, L_{ch}(v′), is carried by the transmitted sequence vₜ. In order to obtain channel information of v, L_{ch} (v), which should be used in the decoding of C₁, pass L_{ch} (v′) through the same FPE going from C₂ back to C₁ as shown in FIG. 5. Therefore, the ITBF iterative decoding can be performed according to the following algorithm:

1. Decode C₂ and extract extrinsic information

2. Pass the extrinsic information obtained in step 1 to a first FPE, FPE1, to modify that extrinsic information by using the most current extrinsic information obtained from C₁. If no extrinsic information of C₁ is available, bypass FPE1 and pass the extrinsic information from C₂ found in step 1 to C₁. If C₁ has channel information, use the same FPE1 to modify the channel information corresponding to C₁. If FPE1 is not available, use the channel information of v′ obtained from the channel as the channel information of C₁.

3. Decode C₁ using the extrinsic information and any available channel information provided to it in step 2 and extract extrinsic information of the output of C₁

4. Pass the extrinsic information obtained in step 3 to a second FPE, FPE2, to modify that extrinsic information by using the most current extrinsic information obtained from C₂ in step 1.

5. Go back to step 1 for the next iteration

However, if C₁ and C₂ are component codes of a strong code such as a serial or a parallel concatenated code or a LDPC code, then it may be necessary to use a two step decoding procedure. In the first step run a pre-selected N₁ number of iterations in the normal way without any FPEs in order to capture the power of the code. Then in the second step, run a pre-selected N₂ number of ITBF decoding iterations described above in five steps. In the second step one or a small pre-selected number of iterations can be used in the decoding of the powerful code.

A FPE can be implemented in many different ways. It can be implemented in a hard sense or in a soft sense. In the hard sense implementation, the FPE compares I_{C}_{₁} (v) and I_{C}_{₂} (v′), and determines the most likely bit position k that has been flipped within every block of n bits. Then the FPE flips the incoming soft information at that position before forwarding it to the next component. Specifically, FPE1 in FIG. 23 takes in I_{C}_{₁} (v) and the most recent I_{C}_{₂} (v′) available and (a) detects the most likely kth position that has been flipped and (b) flips the sign of that kth position in I_{C}_{₁} (v) before forwarding it to C₂. Similarly, FPE2 takes in I_{C}_{₂} (v′) and the most recent I_{C}_{₁} (v) available and (a) detects the most likely kth position that has been flipped and (b) flips the sign of that kth position of I_{C}_{₂} (v′) before forwarding it to C₁. The identification of the flipped position can also be done in one of the following ways:

1. Pick the kth position that maximizes |I_{C}_{₁} (v)−I_{C}_{₂} (v′)|. That means

$$k = {max}_{i} \vert {I}_{{C}_{1}} ( {v}_{i} ) - {I}_{{C}_{2}} ( {{v}_{i}}^{′} ) \vert . \qquad ( 1 )$$

2. Pick k according to (1) but only among the I_{C}_{₁} (v) and I_{C}_{₂} (v′) values that have opposite signs. In situations where no pair of values of I_{C}_{₁} (v) and I_{C}_{₂} (v′) differ in sign, use method 1.

3. Noticing that the values of I_{C}_{₁} (v) and I_{C}_{₂} (v′) are different in magnitudes, use scaling before comparing with each other. This can be done by first calculating a new array of I_{C}_{₂} (v′), I_{C}_{₂}′ (v′), according to

$${I}_{{C}_{{2}^{′}}} ( {ν}^{′} ) = \frac{α}{β} {I}_{{C}_{2}} ( {ν}^{′} ) \qquad ( 2 )$$

where, α=Σᵢ₌₁ⁿ|I_{C}_{₁} (vᵢ)| and β=Σᵢ₌₁ⁿ|I_{C}_{₂} (vᵢ′)|. Then use I_{C}_{₁} (v) and I_{C}_{₂}′ (v′) in determining k either according to method 1 or method 2 described above. Note that I_{C}_{₂}′ (v′) is used only in determining k and not for passing as extrinsic information.

4. Find the flipped position k, using any of the above three methods. Calculate a=|I_{C}_{₁} (vₖ)−I_{C}_{₂} (v′ₖ) and b=Σ_{i=1, i≠k}ⁿ|_{C}_{₁} (vᵢ)−I_{C}_{₂} (v′ᵢ)|. Flip the sign of the extrinsic information of the kth position (i.e., I_{C}_{₁} (vₖ) in FPE1 or I_{C}_{₂} (v′ₖ) when in FPE2) only if a/b is bigger than some pre-selected value γ. Note that γ indicates how reliable the identified flipped position k, higher the value of γ, more reliable the identification of k is. If not, do not flip the sign of any extrinsic value in that block of n values.

A FPE can be designed in a soft sense by calculating the chance, wᵢ, that the position i, i=1, 2, . . . , n, is the flipped position. The value of wᵢ can be calculated using I_{C}_{₁} (vᵢ) and I_{C}_{₂} (v′ᵢ) as

C_{C}_{₂}(v′ᵢ)=(1−2wᵢ)C_{C}_{₁}(vᵢ); i=1, 2, . . . , n (3)

Then adjust the extrinsic values using the wᵢ values given by (3). Specifically, in FPE1, replace I_{C}_{₁} (vᵢ) by (1−2wᵢ) I_{C}_{₁} (vᵢ), and in FPE2, replace I_{C}_{₁} (vᵢ′) by (1−2wᵢ)I_{C}_{₁} (vᵢ′). Note that when w ᵢ is small the extrinsic information is passed without really changing its value while when wᵢ is close to 1, the extrinsic information is almost flipped in sign before passing. Scaling can also be used in the soft FPE by using I_{C}_{₂}′ (v′) discussed in method 3 of hard FPE implementation in place of I_{C}_{₂} (v′) in the calculation of wᵢ in (3).

A hybrid soft/hard FPE can also be designed by combining the hard FPE design approach 4 discussed above with soft FPE. This can be done by using the above described soft FPE when

$$\frac{a}{b} < γ$$

and using the hard FPE when a/b≥γ.

The adjustments made by the FPE can be either assisted or replaced by using an alternate method called progression of likelihood values (PLV). The PLV approach is based on the observation that when the flipped position is correctly identified, that decision should improve the LLR values of the next component whereas if the flipped position is incorrectly identified that should degrade the LLR values of the next component. For example, in FIG. 23, the changes of the extrinsic information made by FPE1 to correct for the flipped bit should improve or degrade the LLR values obtained in C₂ within the corresponding n bit block depending on whether or not the flipped position identified by FPE1 was correct or incorrect respectively. However, in order to determine whether or not the LLR values have improved, it is necessary to determine the LLR values of the next component with and without making any changes in the LLR values obtained from the current component thereby increasing the decoding complexity. If the increase in complexity is disregarded, the PLV method can be used to identify the flipped position and adjust the extrinsic information in place of a FPE. This can be done by calculating the LLR values of the next component (say C₂) without making any adjustment (in FPE1) for the flipped position, and also separately calculating the LLR values of C₂ when the flipped position is varied among each of the n possible positions. Then the flipped position can be identified as the position that improves the LLR of C₂ by the highest amount. However, this approach is not attractive as it requires calculating the LLR values of C₂ separately (n+1) number of times. Therefore, instead of using the PLV method in isolation, it can be combined with the FPE to better estimate the flipped position and update the LLR values before passing it to the next component by using the PLV approach on an as needed basis. Specifically, if the decision made by the FPE appears to be reliable, then accept its decision. However, in situations where the decision made by the FPE does not appear to be reliable, use the PLV method described above either to verify or modify the decision made by the FPE. Therefore, a combined FPE/PLV approach can be developed in the hard sense according to the following rules:

Identify the flipped bit position k in the hard FPE. In addition, calculate the average magnitude of the extrinsic information difference of all remaining positions, L_{avg}(k), and the difference in the extrinsic information of the selected kth position L(k) in the hard FPE. If L(k)≥ρL_{avg}(k), accept the decision made by the FPF and move to the next component of the iterative decoding process, where, ρ is a pre-selected value to maintain good performance. However, if L(k)<ρL_{avg}(k), which suggest that the decision made by the FPE is weak, turn to the PLV method by decoding the next component without adjusting the extrinsic information from the previous component. Then find the average of the absolute value of the extrinsic information of the next component, L_{avg}. Then adjust the extrinsic information of the previous component by assuming the flipped bit is the most likely position k₁ identified by the FPE and calculate the extrinsic information of next component. Then calculate the new average of extrinsic information L_{avg}(k₁). If L_{avg}(k₁)>L_{avg}, assume k₁ was the flipped position and use the corresponding extrinsic information of the next stage. If not, find the extrinsic information of the next component by assuming the next most likely position k₂ is the flipped position and repeat the same process. Continue the same process until L_{avg}(kᵢ)>L_{avg}. At that point, assume the position kᵢ was flipped position and use the corresponding adjusted extrinsic information of the next stage.

The ITBF technique is similar in principle to the IPT technique described before for the transmission of packets implicitly. However, the main difference between ITBF and IPT techniques is that IPT requires that the implicit stream to be coded and as a result it requires updating soft information of the coded bits of the implicit stream during iterative decoding. Therefore, a mapper and a summing unit was used in the IPT technique. In contrast, the ITBF technique mostly uses an uncoded information sequence as the implicit sequence and it can however use a code separately to improve performance of the implicit stream. Further, unlike IPT, ITBF does not require updating soft information of the implicit bits during iterative decoding. Therefore, the mapper used in IPT is referred to in ITBF as a bit position selector and the summing unit in the IPT is referred to in ITBF as a bit flipping unit. The operations in the bit position selector and the bit flipping unit in a ITBF scheme are simpler than the operations in the mapper and the summing unit in an IPT scheme.

Consider an ITBF embodiment of a turbo product code (TPC) constructed with a (n, k) block code with minimum Hamming distance (MHD) dₘᵢₙ (≥3). In such a TPC, the inner code C₁ and the outer code C₂ are both (n, k) linear block codes. FIG. 6 illustrates the encoding of a n by n code array starting from a k by k message array. Note that the top k by n array is the output of C₁ which is checked both by C₁ and C₂. The above described ITBF technique can be applied to this product code by selecting a bit on the first row according to └log₂n┘ implicit message bits at the output of C₁ before feeding it to C₂. In order to improve performance it is desirable not to flip more than one bit along the same column. This can be easily maintained by ignoring the column of the bit that has been flipped on the first row and selecting a bit from the remaining (n−1) bits on the second row according to └log₂ (n−1)┘ and flipping it. This process can be continued down to the kth row to select a bit out of the remaining (n−k+1) columns of the kth row according to └log₂ (n−k30 1)┘ implicit bits and flipping it. In the end at the output of C₁, k bits will be selected (one from each row) before encoding the inner code C₂ along columns. As a result, the TPC with ITBF can additionally transmit

NₛΣᵢ₌₀^{(k-1)}└log₂(n−i)┘ (4)

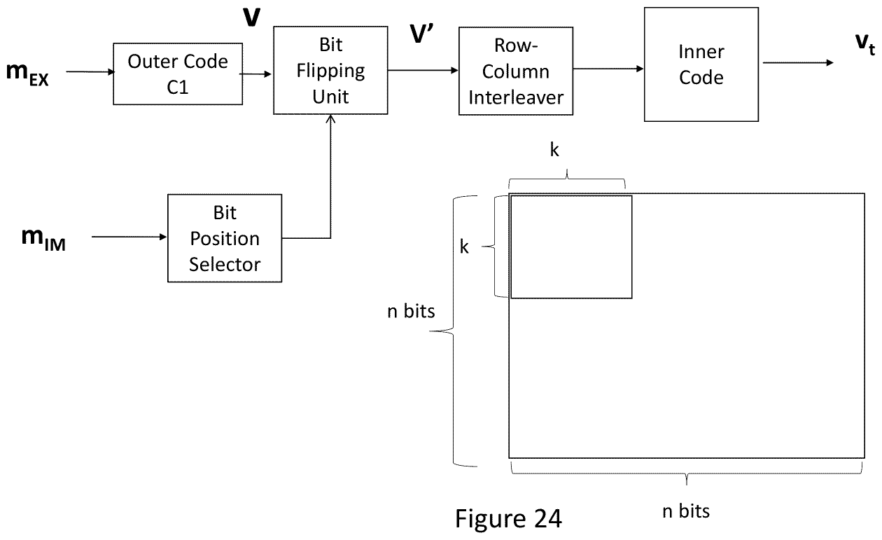

number of message bits implicitly from a separate implicit message sequence. The above TPC with ITBF can be decoded according to the algorithm described before. However, if dₘᵢₙ is significantly higher than 3 and each component code is capable of correcting more than one bit, it is possible to select more than one bit from each row according to implicit bits before feeding the output of C₁ (first k rows of FIG. 24) to C₂ thereby increasing the number of implicitly transmitted bits. Even though selecting bits row by row according to implicit bits is simpler, the number of transmitted implicit bits can be increased by selecting bits jointly by ensuring that only one bit from each of the first k rows are flipped while also maintaining that no column has more than one flipped bit. Specifically, if done jointly, the number of ways to select a combination of k flipped bits while ensuring the above two conditions is N=Πᵢ₌₀^{k-1} (n−i). Therefore, the total number of implicit bits that can be transmitted in a code array is increased from (4) to Nₛ=└log₂N┘.

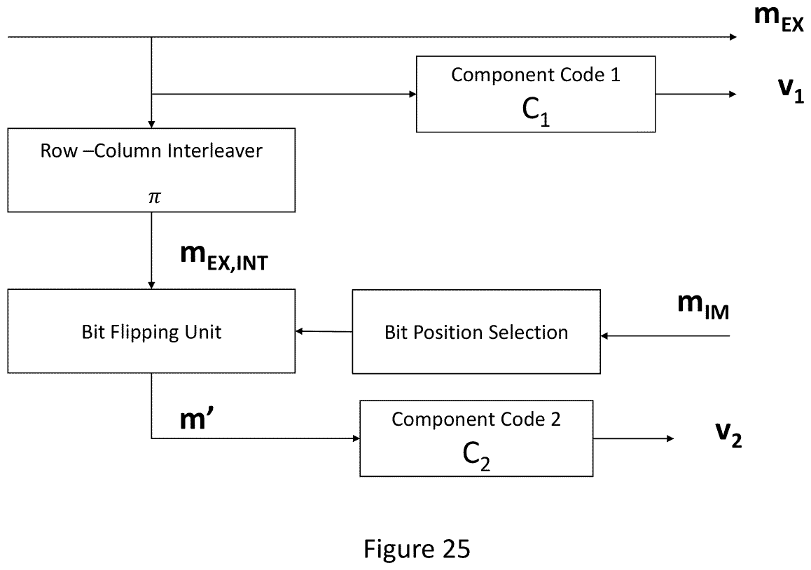

Consider a second embodiment of a turbo code with the ITBF technique as shown in FIG. 25. A turbo code with two component codes transmits the explicit message bits, m_{Ex}, parity bits of the first component code, v₁, and the parity bits of the second component code, v₂. Further, the second component code operates on the interleaved sequence of the explicit message sequence, m_{Ex,Int}. The ITBF technique can be applied to such a turbo code by selecting one bit out of every n bits of the interleaved message bits, m_{Ex,Int}, according to nₛ=└log₂n┘ message bits of a separate implicit message sequence to form the sequence m′ as shown in FIG. 25. Note that the first component code C₁ operates on the actual extrinsic message sequence m_{Ex}, while C₂ operates on the message sequence m′ which contains all the flips. Further, the channel information of the message obtained from the received signal corresponds to m_{Ex}. Therefore, after extracting bit metrics of all bits on m_{Ex}, v₁ and v₂, the above turbo code with ITBF can be decoded a similarly according to the following steps:
1. Decode C₁ using the bit metrics of m_{Ex} and bit metrics of v₁ and extract extrinsic information of the message sequence m_{Ex}
2. Pass the extrinsic information obtained in step 1 to a first FPE, FPE1, to modify that extrinsic information by using the most current extrinsic information obtained from C₂. If no extrinsic information of C₂ is available, bypass the FPE1 and pass the extrinsic information from C₁ found in step 1 to C₂. Use the same FPE1 to modify the bit metrics of the message sequence m_{Ex} to obtain the bit metrics of m′ corresponding to C₂. If no FPE information is available, use the bit metrics of m_{Ex} obtained from the channel as the bit metrics of m′.
3. Decode C₂ using the extrinsic information from C₁ and the bit metrics of m′ found in step 2 along with the bit metrics of its parity bit sequence v₂, and extract extrinsic information of m′
4. Pass the extrinsic information obtained in step 3 to a second FPE, FPE2, to modify that extrinsic information of m′ by using the most current extrinsic information of m_{Ex} obtained from C₁ in step 1 to obtain the extrinsic information of m_{Ex} used by C₁.
5. Go back to step 1 for the next iteration to decode C₁ using the extrinsic information found in step 4. Continue the iterations until the required number of iterations are reached or a terminating condition is satisfied.

Consider the ITBF embodiments previously discussed before with TPC codes and turbo codes. Note that in both of those embodiments, part of the parity bits of the code are generated according to the actual message sequence, which is referred to as the explicit message sequence, while the other parity bits are generated according to a modified version of that explicit message sequence. As described before, ITBF schemes modify the explicit message sequence by selecting bits of that explicit message sequence according to a second implicit message sequence and flipping those selected bits to generate a modified version of the explicit message sequence. Therefore, the ITBF technique can be applied to any code to generate some of its parity bits from the explicit message sequence and the remaining part of the parity bits from the modified version of the explicit sequence. Therefore, the ITBF technique can be applied to generate LDPC codes with ITBF as described below.

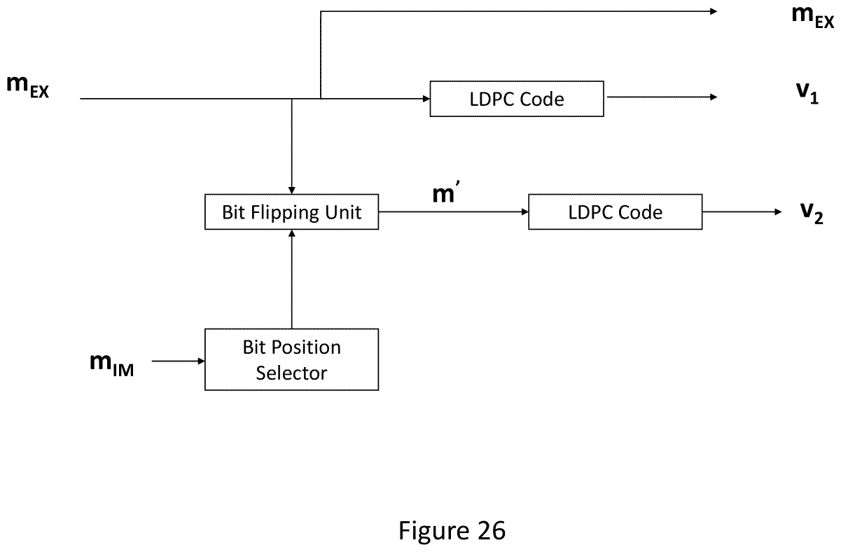

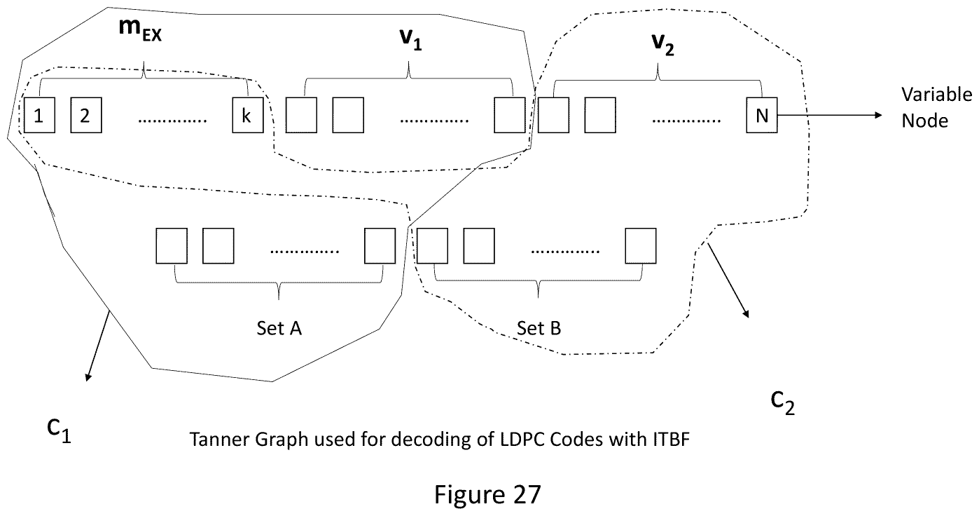

Consider a third ITBF embodiment with a systematic (N, K) LDPC code that uses an explicit message sequence, m_{Ex} for transmission. Then generate part of the parity bits, v₁, using m_{Ex} as shown in FIG. 26. Then modify the sequence m_{Ex} by selecting one bit out of every n bit block of m_{Ex} according to nₛ=└log₂n┘ number of bits of a second implicit message sequence m_{Im} and flipping that selected bit on m_{Ex} in each block of n bits to form a modified message sequence m′. Then use the modified message sequence m′ to generate the remaining portion of the parity bit sequence, v₂, as shown in FIG. 26. In a LDPC code, the sequences v₁ and v₂ can be selected to roughly obtain about the same number of check nodes for v₁ and v₂ on the Tanner graph of that LDPC code. FIG. 27 shows the set of check nodes, set A, corresponding to the explicit message sequence m_{Ex} and v₁, and the set of check nodes, set B, corresponding to the modified message sequence m′ and v₂ as shown in FIG. 27. In order to describe the decoding of LDPC codes with ITBF, let us denote the set of variable nodes and the set A of check nodes, corresponding to the sequences m_{Ex} and v₁, by C₁. Similarly, let us denote the set of variable nodes and the set B of check nodes, corresponding to the sequences m′ and v₂, by C₂ as highlighted in FIG. 27. In fact, C₁ and C₂ can be viewed as two punctured codes generated from the same LDPC code. Further, C₁ and C₂ can be decoded on the same Tanner graph using the same SPA algorithm with the only difference that the corresponding check nodes include only set A for the decoding of C₁ and set B for the decoding of C₂. Note that the bit metrics (channel information) of m_{Ex}, v₁ and v₂ can be obtained from the received signal. By following the decoding of turbo product codes with ITBF and turbo codes with ITBF, LDPC codes with ITBF can be decoded after extracting bit metrics of all bits on m_{Ex}, v₁ and v₂, according to the following steps:

1. Decode C₁ using the bit metrics of m_{Ex} and bit metrics of v₁ and extract extrinsic information of the message sequence m_{Ex}

2. Pass the extrinsic information obtained in step 1 to a first FPE, FPE1, to modify that extrinsic information by using the most current extrinsic information obtained from C₂. If no extrinsic information of C₂ is available, bypass the FPE1 and pass the extrinsic information from C₁ found in step 1 to C₂. Use the same FPE1 to modify the bit metrics of the message sequence m_{Ex} to obtain the bit metrics of m′ corresponding to C₂. If no FPE information is available, use the bit metrics of m_{Ex} obtained from the channel as the bit metrics of m′.

3. Decode C₂ using the extrinsic information from C₁ on step 2 and the bit metrics of m′ found in step 2 along with the bit metrics of its parity bit sequence v₂, and extract extrinsic information of m′

4. Pass the extrinsic information of m′ obtained in step 3 to a second FPE, FPE2, to modify that extrinsic information of m′ by using the most current extrinsic information of m_{Ex} obtained from C₁ in step 1 to obtain the extrinsic information of m_{Ex} used by C₁

5. Go back to step 1 for the next iteration to decode C₁ using the extrinsic information found in step 4. Continue the iterations until the required number of iterations are reached or a terminating condition is satisfied.

Depending on the LDPC code and the desired performance, steps 1 and 3 can employ a single or any desirable pre-selected number of SPA iterations for the decoding of C₁ and C₂ respectively. Further, in order to select the set of parity bits and the corresponding check nodes, a parity bit selection unit can be used in the decoding of LDPC codes with ITBF.

It is also desirable to select each block of n coded bits of the LDPC codes, which is modified by flipping one bit of it, to ensure that flipping of bits will influence as many check nodes as possible. This can be achieved by ensuring, as much as possible, that only one variable node, representing a coded bit, among all variable nodes that feed into each check node is allowed to be flipped. Note that if two variable nodes among those fed into a particular check node are flipped, the check node will not be able to gather any information of the flipped bit. Therefore, it is desirable to select blocks of n coded bits of the explicit stream completely from a set of paths arriving at a complete set of check nodes. In other words, it is desirable to avoid feeding coded bits arriving at a particular check node into different blocks of n bits as much as possible.

Even though the LDPC codes with ITBF has been described with systematic LDPC codes for simplicity, the same technique can be easily applied to non-systematic LDPC codes. Further, even though, the above embodiment has been described with a LDPC code C, the same ITBF technique can be applied to any code C by generating part of its parity bits from the explicit message sequence and the remaining part of its parity bits from a modified version of the explicit message sequence, modified according to a separate implicit message sequence.

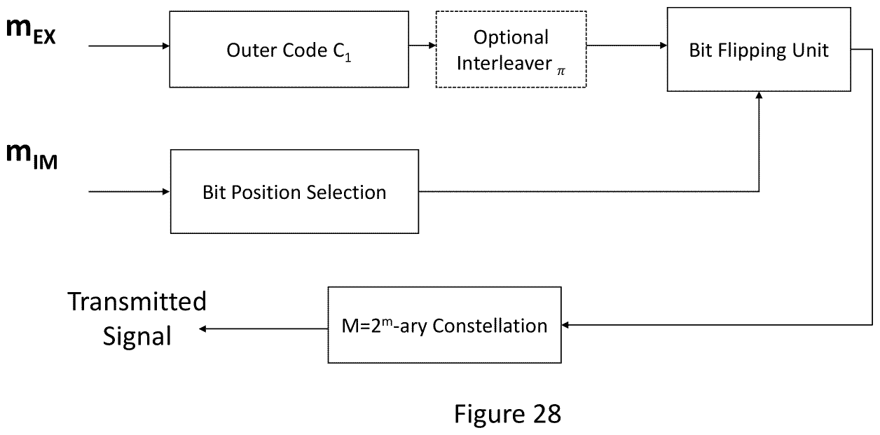

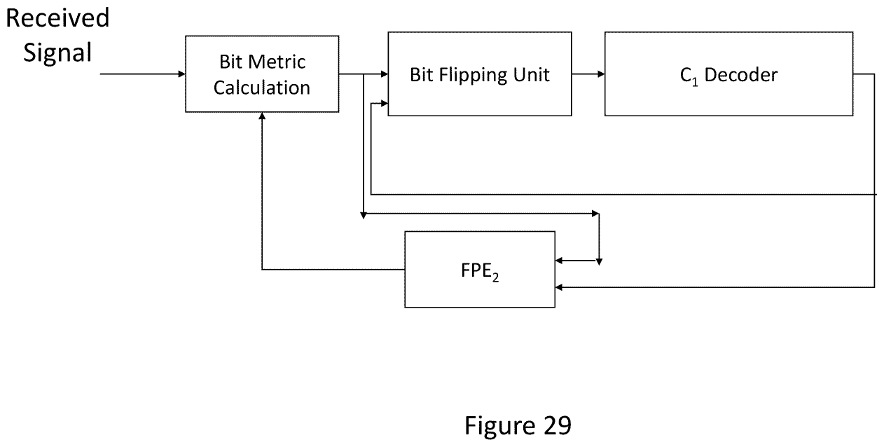

The ITBF technique can be applied to a coded modulation system as illustrated in FIG. 28. In such an application the modulator acts as the second component C₂ while C₁ is the code employed in the system. An optional interleaver π can be used in the system. If such an interleaver is used, the soft information can be transferred using an interleaver (or a de-interleaver) in order to feed the soft information in the proper order to every decoding component at the receiver as it is well known in the literature. Therefore, coded modulation schemes with ITBF are described here without an interleaver, but if an interleaver is used it can be easily incorporated in the decoder described later by using an interleaver (or a de-interleaver) in the exchange of extrinsic information. Therefore, a coded modulation system with ITBF alters the coded sequence (output of C₁) by selecting one bit out of every block of n bits based on nₛ=└log₂ n┘ implicit bits and flipping that selected bit before feeding it to the modulator. These signals are decoded similar to the decoding of a TPC with ITBF or a turbo code with ITBF. First the LLR values (bit metrics) of each coded bit is extracted as in [Imai] from the demodulator according to the signal constellation. Then follow the five ITBF decoding steps to decode both the explicit and the implicit bit sequences. FIG. 29 shows the decoding procedure of coded modulation with ITBF. The decoding procedure can be described in the following steps:

1. Extract LLR values (bit metrics) of each bit using the received signal and any available extrinsic information [Imai]. In the first iteration, since no extrinsic information is available, extract bit metrics using the received signal.

2. Pass the extrinsic information found in step 1 to a first FPE, FPE1, to modify the extrinsic information obtained in step 1 using the most recent extrinsic information available from C₁. If no extrinsic information from C₁ is available bypass the FPE1 and pass the extrinsic information found in step 1 to C₁.

3. Decode C₁ using the extrinsic information provided to it in step 2 and extract extrinsic information of the output of C₁

4. Pass the extrinsic information found in step 3 to a second FPE, FPE2, to modify it using the extrinsic information found in step 1.

5. Pass the extrinsic information found in step 4 to update the bit metrics on the constellation and go back to step 1 for the next iteration.

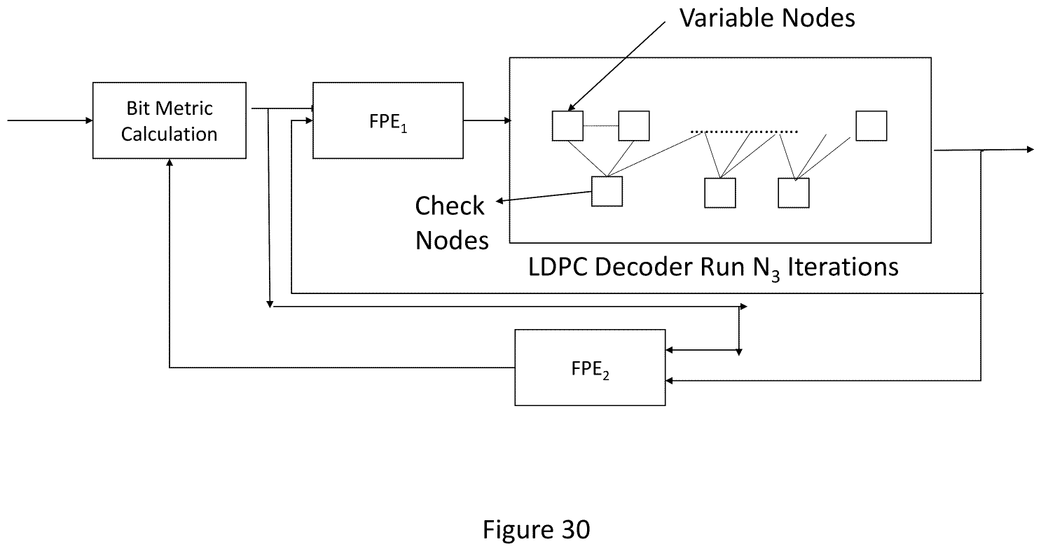

The above 5 step iterative decoding algorithm can be directly applied when the outer code C₁ is a simple code. However, when C₁ is a powerful code, such as a turbo product code or a turbo code or a LDPC code, that requires iterative decoding for the decoding of C₁, the above algorithm can be modified to reduce the increase in decoding complexity. This can be done by inserting steps 1, 2, 4 and 5 listed above within the iterations for the decoding of C₁ in step 3. Consider an ITBF embodiment that transmits LDPC coded bits using a higher order signal constellation. In such an application, the transmitter functions the same way as described before by selecting one bit out of every n coded bits of the LDPC coded stream based on nₛ=└log₂n┘number of implicit bits and flipping it before transmission. At the receiver, usually LDPC codes are decoded by running iterations between the variable nodes and check nodes on the Tanner graph according to the SPA algorithm. Based on the above ITBF decoding algorithm, a LDPC coded modulation scheme with ITBF can be decoded as shown in FIG. 30 according to the following algorithm:

1. Extract bit metrics from the received signal and assign them to the variable nodes disregarding any flipping has taken place. Run the LDPC decoding SPA algorithm for N₁ number iterations, where N₁ is a pre-selected integer.

This allows the LDPC code to provide a good estimate of soft values of the message nodes. However, these soft values are degraded due to the flipping compared with the quality of soft values that would be obtained without any flipping.

2. Following N₁ number of the standard SPA decoding iterations, modify the SPA algorithm to include two FPEs, FPE1 and FPE2, and the bit metric updating unit according to [Imai] as shown in FIG. 13.

Note that the bit metrics calculated from the constellation is a reflection of the flipped version of the coded stream which is also the transmitted sequence. However, the variable nodes during the SPA algorithm reflect the output of the LDPC code without any flips. Therefore, the most recent bit metrics calculated from the constellation and the most recent LLR values of the variable nodes can be compared in FPE1 and FPE2 to best identify the flipped positions. Therefore, the output of FPE1 highlighted in FIG. 28 is a reasonable representation of the un-flipped version of the LDPC coded sequence while the output of FPE2 in FIG. 30 is a reasonable representation of the flipped version of the LDPC coded sequence. Upon completing N₁ number of standard LDPC decoding iterations, run a pre-selected N₂ number of iterations using the algorithm shown in FIG. 6 to complete decoding. The values of N₁ and N₂ can be selected to achieve the desired performance and to limit decoding complexity. Depending on the application, once FPE1 provides extrinsic information to the LDPC decoder, if necessary any pre-selected N₃ number of iterations can be run for the SPA decoding algorithm using the same FPE1 output to reasonably well realize the effects of the provided extrinsic information. The values of N₁, N₂ and N₃ can be selected based on the power of the LDPC code, size of the constellation, mapping policy used on the constellation and the signal to noise ratio. There can be applications for which N₁₌N₃=1. It is mentioned here that any FPE in a ITBF system can be implemented as a hard FPE (according to any of the four ways discussed before), or a soft FPE, or a soft/hard FPE, or according to the PLV algorithm, or combined FPE/PLV algorithm.

It is noticed that the bit error rate performance of the implicit stream relies on how the mapping is done on the constellation. In order to determine which bit has been flipped in a symbol reliably on the constellation, it is important to increase the Euclidean distance between constellation points that differ in one bit differences. Therefore, mapping policies other than traditional Gray coding can be used in a coded modulation scheme with ITBF. For example, anti-Gray coding or reverse Gray coding (RGC) can provide stronger information about the flipped bit from the constellation compared with Gray coding. However, Gray coding can provide stronger information of the remaining un-flipped bits than the other types of mapping. Therefore, depending on the application, Gray coding or any other type of coding can be used to achieve good performance of ITBF coded modulation scheme.

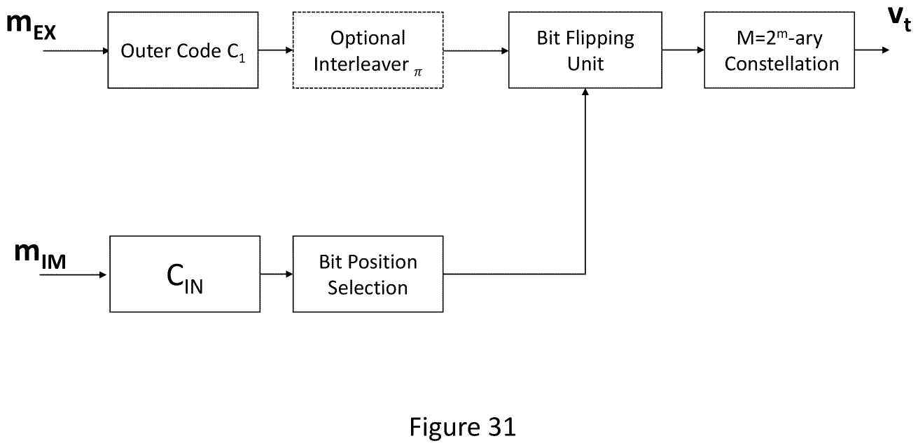

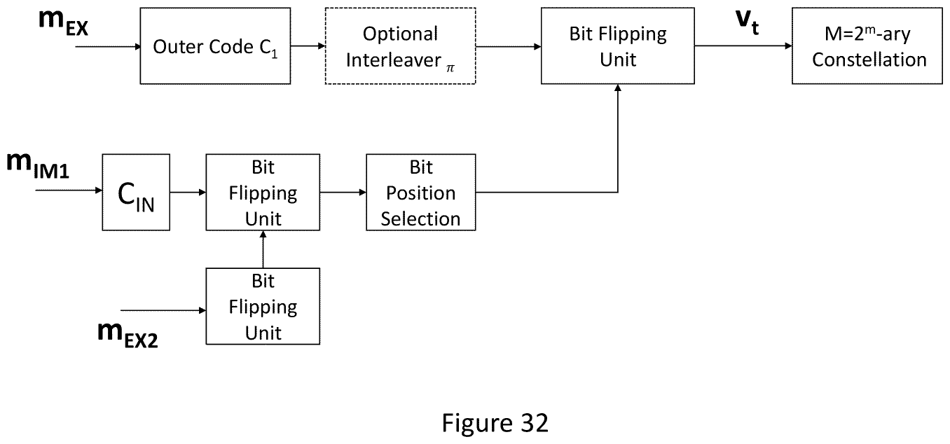

Another approach for improving the performance of the implicit bit sequence is to employ a separate code on the implicit stream as shown in FIG. 31 instead of using an uncoded implicit message data stream as before. In such a coded system, the soft information of coded implicit bits can be first extracted by using the ITBF iterations as described before and after that perform soft or hard decoding of the implicit code to recover the implicit message data stream to achieve the desired error rate performance. Since the ITBF iterations are likely to provide mostly reliable soft information of coded implicit bits, a high rate code C_{Im} can be usually used on the implicit stream. Another way to further increase the transmission rate in the scheme shown in FIG. 31 is to use a second uncoded implicit stream, m_{Im2}, by applying the ITBF technique to the code C_{Im}. FIG. 32 shows such a structure that employs two implicit streams, m_{Im1} and m_{Im2}. The decoding of such a coded scheme follows directly from the iterative decoding of coded modulation schemes with ITBF described before. The only difference is that the same iterative process is needed twice, first to use the ITBF decoding algorithm shown in FIG. 29 to extract soft information of the first coded implicit stream, then to use the ITBF decoding algorithm shown in FIG. 23 to recover the two implicit message streams. If the code C₁ in FIG. 28, or code C₁ and/or C_{Im} in FIGS. 31 and 32, is a LDPC code or any other powerful code that requires iterative decoding, the same decoding method described before and shown in FIG. 30 can be used to recover both the explicit message sequence m_{Ex} and the implicit message sequence m_{Im}.

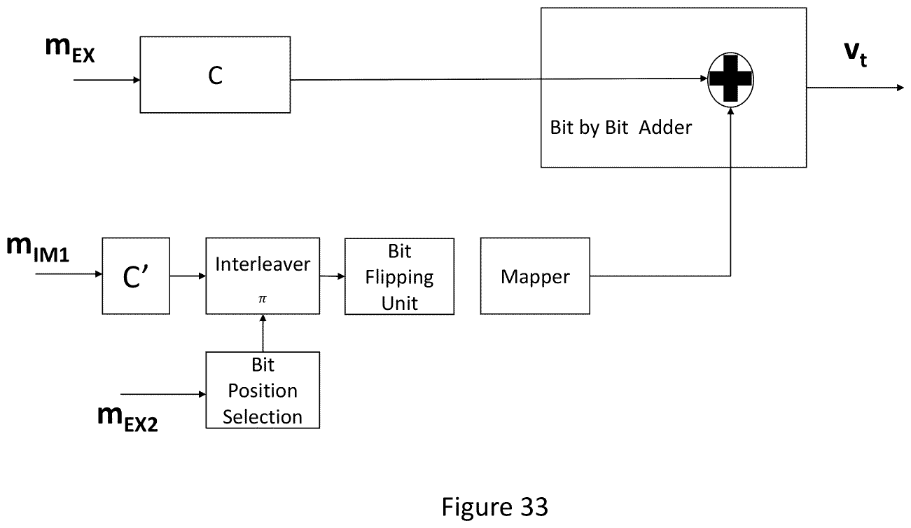

Another method to transmit two implicit message sequences, m_{Im1} and m_{Im2}, is to extend the IPT technique described before with one implicit stream to handle two implicit streams. This is done by applying the ITBF technique described before to the coded implicit stream by adding second implicit stream. FIG. 33 shows the structure of a new class of IPT schemes, referred to here as IPT-2 schemes, that can transmit one stream m_{Ex} explicitly and two streams m_{Im1} and m_{Im2} implicitly. The first implicit stream is coded while the second implicit stream is uncoded. IPT-2 schemes select one bit out of every n′ bits of the first coded implicit stream, v′_{I}, according to n′ₛ=└log₂n′┘ bits of m_{Im2} and flip that selected bit in the a bit flipping unit to form the sequence v_{Im}. Then, as in IPT schemes, one bit out of every n coded bits of the explicit stream, v_{Ex}, is selected according to nₛ=└log₂n┘ bits of v_{Im} and flip that bit before forming the transmitted sequence vₜ. Note that the processing on the first implicit stream m_{Im1} is the same as the structure of an ITBF scheme shown in FIG. 21 with m_{Im2} as its implicit stream. At the receiver, IPT iterative decoding structure shown in FIG. 13 can be modified by replacing the decoding of the implicit code C_{Im} by the ITBF decoding algorithm shown in FIG. 23. After running the modified IPT iterations, all three sequences can be decoded. The explicit message sequence m_{Ex} and the first implicit message sequence m_{Im1} follow directly from the modified IPT iterations, while m_{Im2} can be directly recovered from the information of the FPE as it identifies the flipped bit position which uniquely determine n′ₛ number of bits of m_{Im2} for every n′ number of bits identified on v′_{Im}.

When LDPC codes are used in a IPT shown in FIG. 12 or a IPT-2 scheme as shown in FIG. 33 as the code C_{EX} on the explicit stream and also code C_{Im} on the implicit stream, the decoding can be done by inserting the IPT iterations within LDPC decoding iterations. This can be done by running only a preselected N₁ number of LDPC iterations (SPA iterations) in the decoding of C_{EX} and C_{Im} in the decoder shown in FIG. 13. The value of N₁ is selected to be sufficient for the LDPC decoder to feel the effect of any changes made during the IPT iterations. Similarly, if LDPC codes are used in a IPT-2 scheme shown in FIG. 33 as the code on the explicit stream and also on the first implicit stream, the decoding can again be done by inserting the modified IPT iterations within LDPC decoding iterations as described before. Again, in the decoding of the explicit and implicit codes, only a small pre-selected N₁ number of SPA decoding iterations can be used within the modified IPTC-2 iterations. For some applications N₁ in a IPT or a IPT-2 can be as small as small as 1 or 2. As a result, the increase in decoding complexity is rather small in a IPT or a IPT-2 when the component codes are LDPC codes.

In ITBF or IPT or IPT-2, a portion of a message stream is transmitted implicitly while transmitting the remaining portion explicitly as a coded stream over a channel. It is noticed that when both implicit and explicit streams are formed from a single message stream, there is no restriction on how the two streams are formed. Therefore, the implicit and explicit streams can be formed from the original message stream in any preferable way. That flexibility available in a ITBF scheme or a IPT scheme or a IPT-2 scheme inherently introduces a second layer of encryption. For example, let us consider a IPT scheme that transmits 25% of a coded stream implicitly when transmitting the remaining 75% of the coded stream explicitly. That means on average one out of every five bits of the original message sequence can be transmitted implicitly while transmitting the remaining four bits explicitly. In this scheme, if there are 5λ message bits in the original message stream, then there are

$$( \begin{matrix}5 λ \\ λ\end{matrix} )$$

ways to divide it to form the implicit and explicit streams. For higher values of λ, which is usually the case in practice, this number is a very large number. Therefore, if a third party is to somehow receive the transmitted sequence vₜ, that third party will not be able to decode the two sequences without knowing how the original message sequence is divided to form the implicit and explicit sequences. Therefore, ITBF, IPT and IPT-2 schemes inherently introduce encryption by the division of the original message sequence to form the implicit and explicit streams. It is also noted here that the original sequence can be already encrypted. In that case, how the original encrypted sequence is divided into explicit and implicit streams introduces an additional second layer of encryption.

Another approach for increasing the information transfer rate is to allow interference during transmission. For example, in an OFDM system if the frequencies are brought closer to each other lowering the standard spacing than 1/T, more frequencies can be placed within a given bandwidth, where 1/T is the symbol rate. However, in such a system, the orthorgonality condition is violated causing interference among frequencies.

Similarly, interference can be present in any domain such as, time domain, spatial domain, or it can be present in presence of mismatches such as I/Q mismatch. Traditional method of signaling is to somehow find ways to avoid interference or to combat it at the receiver using interference cancellation or mismatch cancellation.

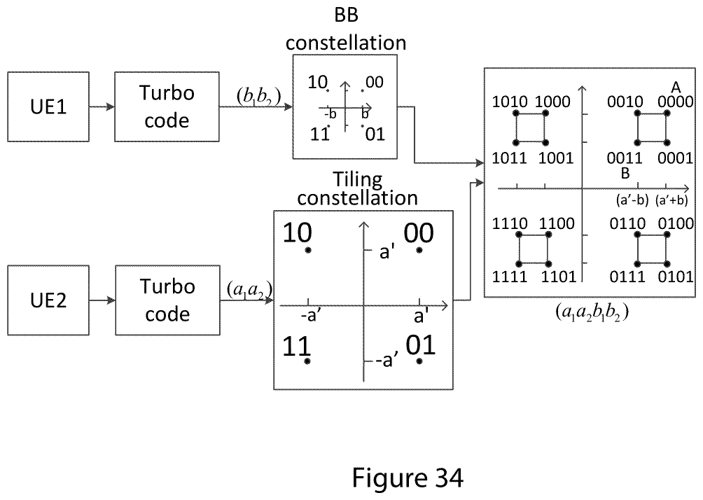

In the literature, the BOMA technique has been proposed to transmit a message sequence from a second user when the message from a first user is transmitted on the downlink of a wireless system. BOMA employs a sparse signal constellation which can be derived using the building block principle that has been used in the design of multilevel codes. For example, FIG. 34 shows a 16-ary sparse constellation that can be used to additionally transmit two bits of user 2 while transmitting two bits of user 1. In that example, user 1 is considered to have a weaker channel while user 2 is considered to have a stronger channel. The constellation shown in FIG. 34 is constructed by following the building block approach by (a) constructing a QPSK constellation for the two bits of user 2 with constellation points (±b, ±b), which is referred to as the building block (BB) constellation, and (b) placing four copies of the building block formed in (a) at the QPSK constellation of the two bits of user 1 with constellation points (±a, ±a), which is referred to as a tiling constellation. As a result, the first two bits of the 16-QAM sparse constellation come from user 1 while the last two bits come from user 2. At the receiver, both users can separately extract the respective LLR values of only their own bits from the received signal.

Note that the primary user, user 1, can view user 2 as interference. As a result, the interference of user 2 expands the original QPSK constellation with points (±a, ±a) of user 1 into a 16-ary sparse constellation with the interference. Therefore, any interference results in an expanded signal constellation. More importantly, the BOMA principle allows the extraction of the LLR values of both the information of the desired signal (which is user 1 in the previous example) and the information of the interfering signal (which is user 2 in the previous example) simultaneously. Therefore, the detection used in the BOMA approach, referred to here as BOMA detection, can be extended to multiple interferences by systematically expanding the constellation according the BB methodology, and extracting the LLR values of the desired bits and each interfering bit separately from the same received signal. As a result, the BOMA approach can be used to combat interference in a communication system. Therefore, signals can be transmitted with interference but the likelihood values of different bits can be extracted using the BOMA detection approach. This is in contrast to traditional thinking which tries to avoid interference and to find ways, such as interference cancelation, equalization, etc., to remove interference before detection. This aspect of the present disclosure, referred to as BOMA detection in presence of interference (BDPI), can be used to transmit signals with interference thereby increasing the information transfer rate.

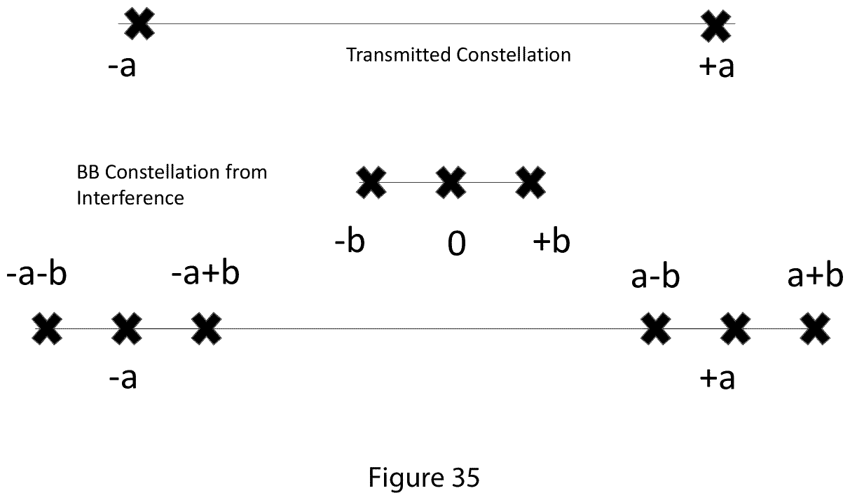

For example, let us consider a transmission scheme that employs BPSK modulation transmitted over a channel that causes inter-symbol interference (ISI) from only the two adjacent symbols. Let us also assume that the channel response is in the form h=(0,0, . . . , h₋₁, h₀, h₁, . . . 0,0) with h₁=h₋₁. Therefore, during every n th interval, the overall constellation with interference from both adjacent symbols can be found by viewing the effect of each interfering signal in the form of a BB. FIG. 35 illustrates how the overall constellation with interference from both adjacent symbols can be found by considering the effect of one symbol at a time. As it can be seen from FIG. 35 the combined BB formed by both adjacent interfering symbols is a 3-ary constellation. Therefore, the overall sparse signal constellation with the interference from both adjacent symbols and the desired signal used by the scheme during every interval is a 6-ary constellation as illustrated in FIG. 35.

The above method can be extended to include ISI from up to N symbols from each side. Noticing that the interference from any ith pair of neighboring symbols on the two sides create a 3-ary BB, BBᵢ, i=1, 2, . . . N, the effective interference BB, BB_{eff,N}, from any N pairs of interfereing symbols can be found by starting from BB₁ (which is also BB_{eff,1}) and placing each BBᵢ at each constellation point of BB_{eff,i-1}, to form BB_{eff,i}, for i=2, 3, . . . N.

During decoding, each received signal yₖ transmitted during any kth interval, carries (2N +1) LLR contributions for bits transmitted during intervals (k−N) , (k−N+1), . . . , (k+N). These contributions, denoted by LLR(k, k−j), j=N, (N−1), . . . , N, can be found by following BOMA decoding approach on the overall signal constellation BB_{eff,N}. Therefore, upon calculating LLR contributions from each received signal, yₖ, −∞<k<∞, each bit will have up to (2N+1) LLR contributions. However, note that when only a finite number of symbols are transmitted, the initial N bits and the final N bits will have fewer LLR contributions. The overall LLR value of each jth bit, L(j) can be calculated by adding all LLR contributions of that bit as

$$L ( j ) = {\sum }_{k} L L R ( k , k - j )$$

Upon calculated the bit metrics for each bit in presence of interference, they can be used to decode the message bits if an error correcting code is employed at the transmitter, or use the bit metrics calculated in any known method as directed by the receiver.

As N increases, calculating all (2N+1) LLR contributions from each yₖ become challenging. Hence, an algorithm can be developed to efficiently calculate the LLR value of each bit by actively searching for the most significant constellation points for which each bit is a 1 and a 0 separately. If the Max-log-MAP based LLR values are calculated, only the most significant (closest to the received signal yₖ) constellation point for 1 and most significant constellation point for 0 are needed. These two constellation points corresponding to each bit can be efficiently searched using the standard search algorithms even though the overall sparse constellation is very large.

As noted above, in another aspect, the present application discloses a technique for using CICM with LDPC codes. Since most current communications systems today employ LDPC codes, it is highly desirable to be able to apply the CICM technique to LDPC codes and as a result to be able to transmit LDPC coded bits using higher order modulation while performing better than if they were to be transmitted using a lower order modulation scheme. In addition, it would be highly desirable for such a LDPC coded scheme with CICM to be able to process one LDPC codeword at a time thereby eliminating any increase in decoding delay and memory. If CICM can be applied to a single codeword of a LDPC code, its coded bits could potentially be transmitted using 16-QAM or even 64-QAM modulation while performing better or similar to employing QPSK modulation for transmission. As a result, application of CICM to LDPC codes can potentially more than double the transmission rate. In accordance with this aspect of the present application, a simple method of applying CICM to LDPC codes is presented while decoding one codeword of the LDPC code at a time.

A LDPC code can be viewed as a long code that has a collection of a many single parity check (SPC) codes. Each parity check is formed by a few variable nodes (represented by coded bits) and one check node, where, each check node receives information from several other variable nodes. Effectively, each row of the parity check matrix H of a LDPC code corresponds to a SPC code of that LDPC code. As a result, a LDPC code inherently contains a large number of short SPC codes in it. Since the CICM technique requires consideration of a large number of codewords, these short SPC codes can be used as the required codewords in the application of CICM. As a result, CICM can be applied to a single codeword of the LDPC code without having to consider multiple codewords of it.

In order to describe how the CICM technique can be applied to LDPC codes, let us consider a general LDPC code with n variable nodes (VNs), denoted by v_i=1, 2,. . . , n, and L check nodes (CNs), denoted by c_j, j=1, 2, . . . , L. Let us denote the set of ki connections stemming from any general VN vi to its associated CNs, denoted by c_j_1(i), c_j_3(i), . . . , c_j_k_i(i). Similarly, let us denote the set of el_j connections stemming from any general check node c_j to its associated VNs denoted by v_i_1(j), v_i_2(j), . . . , v_i_el_j(j).

As with block codes, it is assumed in the application of CICM to LDPC codes that errors would be limited to only a small number of coded bits as SNR increases. Specifically, it is assumed that the errors are limited to a set of variable nodes formed by starting from any single variable node vi and (a) following all paths that emerge from vi to the check nodes, and (b) then considering each of those check nodes back to a set of variable nodes. This set of variable nodes formed by the above steps (a) and (b) including vi, denoted by S_i, is the set of variable nodes referred to as the associated variable nodes (AVN) of the variable node vi. Therefore, in the application of CICM to LDPC codes, it is assumed that errors that occur are limited to a single Si as SNR increase. Following the above method, it is possible to obtain the corresponding set of AVN for each variable node vi, i=1, 2, . . . , n. The set of AVNs, S_i=1, 2, . . . , n, are used to design the required CICM Interleaver. The goal of the CICM Interleaver is to place each coded bit of every AVN in different transmitted symbols of the 2\hat{ }m-ary constellation used for transmission. First notice that in order to transmit n coded bits using a 2\hat{ }m-ary constellation, it is necessary to use W=n/m symbols. Therefore, the aim of the CICM Interleaver in LDPC codes is to place the coded bits (variable nodes) in a m by W 2-dimensional array, called the symbol array (SA), with m rows and W columns with the aim of forming m-bit long symbols along columns to form W symbols for transmission. The objective of this CICM Interleaver is to satisfy the following condition:
no two coded bits of every Si, i=1, 2 . . . , n, are placed in the same column of the SA.

However, in situations where it is impossible to satisfy the above condition, the Interleaver can be preferably designed to maintain that the coded bits of each Si are placed in as many columns as possible in the SA.

There can be many valid SAs that satisfy the above condition for all Sis, i=1, 2 . . . , n. In the design of the SA, the goal is to find one such valid SA that satisfies the above condition. Many search algorithms can be developed to search for a valid SA starting from the set of Sis of a given LDPC code with n coded bits and a given value of m. One such strategy would be to place coded bits in the SA with the aim of maintaining the number of unplaced coded bits of each Si about the same for all Sis while placing bits in the SA. This strategy allows more flexibility towards the end to fill out the remaining openings of the SA without violating the above condition. Whenever, bits are selected from each Si, they can be selected either randomly or in some systematic manner such as from left to right or from right to left . In failing to find a valid SA, the process can be repeated until a valid SA (or the best possible SA) is found. An alternate strategy would be to place one Si at a time in the SA. This can be preferably done starting with the Si that has the largest number of coded bits and moving down to the Si with the lowest number of coded bits. The hope in this approach is to have all remaining places of SA in the end to fit into all remaining shorter Sis without violating the above stated condition. Again, coded bits of each Si can be either randomly selected or systematically selected, and further, the search can be repeated until a valid SA that satisfies the above stated condition.

Another approach is to design the CICM Interleaver by following the method for block codes. In this approach, Sis are treated as separate codewords. However, an adjustment is necessary since the same coded bit can appear in many Sis whereas in case block codes all coded bits are separate. This can be overcome by removing all remaining (disregarding) appearances of the same coded bit from other Sis once that coded bit is placed in SA.

It is noted here that the Interleaver design is done once prior to transmission and hence time and effort in searching for a valid SA does not contribute to the decoding delay or decoding complexity. The generated symbols from the SA are then transmitted using a signal constellation that employs RGC.

As noted above, in yet another aspect, the present application discloses a technique for decoding LDPC codes with CICM. In general, CICM decoding requires iterative decoding while involving the constellation during decoding iterations. Since LDPC decoding already uses iterative decoding, the same LDPC iterations can be used to include the constellation. However, the decoder needs to use the same CICM Interleaver used at the transmitter when transferring information from the variable nodes to the constellation and the corresponding de-Interleaver when transferring information from the constellation back to the variable nodes. Checking with the constellation could be done every iteration or every N′th iteration (N′>1) depending on the situation. For example, if N=20 LDPC iterations are used, the constellation could be included after every N′=5 iterations.

It should also be understood that the various different communication techniques disclosed herein, including but not limited to the SPT techniques, the IPT techniques, and the CICM techniques, could be utilized together in any of various manners.

### II. ITBF Method

Disclosed herein is a general implicit transmission with bit flipping (ITBF) method to transmit a secondary coded stream implicitly during the transmission of a primary coded stream explicitly. Throughout this disclosure, the primary stream is also referred to as the explicit stream while the secondary stream is also referred to as the implicit stream. It is noted that the ITBF method proposed here can employ any error control coding technique on the explicit stream and the implicit stream independently.

In order to describe the ITBF technique, let us consider a code that generates n coded bits corresponding to every k(<n) message bits. Then it is possible to choose el(<(n−k)) bits out of (n−k) parity bits that can be removed from the coded sequence and yet correctly recover the original message sequence of length k. These el bits can preferably be chosen by using a good known punctured code generated from C. For example, let us consider a code C with rate ⅓, i.e., n=3k. Then consider a rate ½ punctured code generated from that rate ⅓ code C. Note that in the construction of the rate ½ punctured code, n/6 coded bits of C are identified and removed. Hence, these n/6 coded bits can be selected as the el=n/6 coded bits of C. Of course, depending on the selected punctured code, the set of el coded bits and its length can change. Throughout this disclosure, these el bits are referred to as the chosen bits. Therefore, a set of chosen bits of a code C can be pre-selected by preferably considering a punctured code generated from the code C or by using any other method.

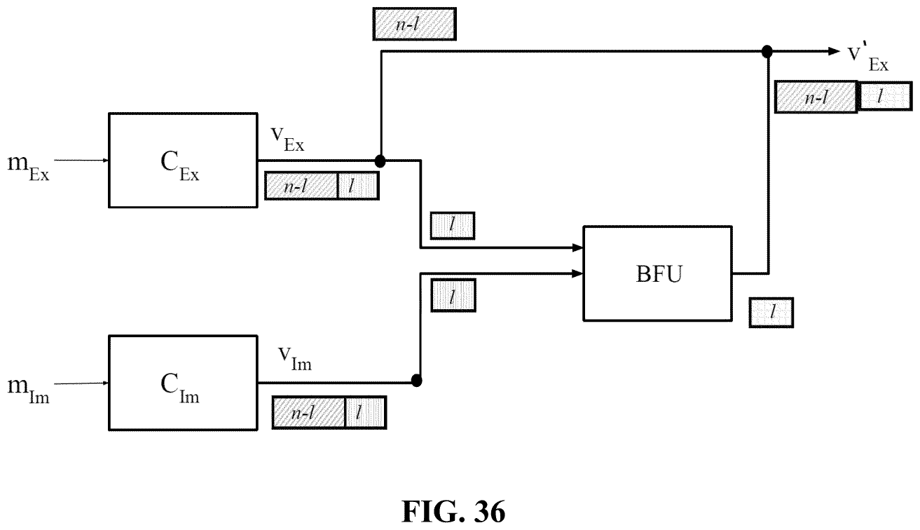

FIG. 36 illustrates the structure of the transmitter in ITBF. In ITBF, an explicit message sequence m_Ex and an implicit message sequence m_Im are separately encoded according to two codes C_Ex and C_Im respectively to generate two coded streams v_Ex and v_Im respectively. Without loss of generality, in this discussion, we consider both C_Ex and C_im to be the same code C, i.e. C_Ex=C_Im=C. However, as stated before, C-Ex and C_Im can be two independent codes. Then identify the el number of pre-selected chosen bit positions of v_Ex. Then, according to el bits of the coded implicit stream v_Im, flip the chosen bits of explicit coded stream v_Ex using a bit flipping unit (BFU) as illustrated in FIG. 36. Specifically, each of these chosen bits of v_Ex is flipped if the corresponding coded bit of the implicit stream is a 1 (or a 0) and not flipped if the corresponding coded implicit bit is a 0 (or a 1).

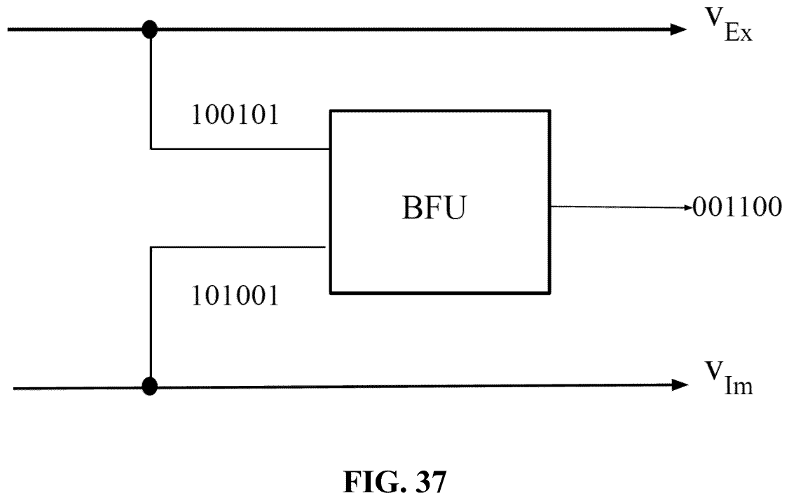

FIG. 37 illustrates an example of the flipping operation when el=6. The resulting sequence v′_Ex on the explicit stream is then transmitted over the channel. Note that none of the coded bits of v_Im is transmitted directly over the channel, however, the information contained in those el bits of v_Im, which were used to decide whether or not to flip the el chosen bits of v_Ex, is conveyed during transmission. Note also that, due to the flipping of the chosen bits, the transmitted sequence v′_Ex may very well not be a valid coded sequence of C_Ex. However, it is noted here that instead of deciding flips on a bit-by-bit basis as described before, it is also possible to decide flips on any other basis such as on a block-by-block basis. For example, a block of a pre-selected el'(<=e1) number of coded bits of the implicit stream can make decisions on the lipping for the entire set of el chosen bits of a codeword of the explicit stream thereby introducing an inherent code in the flipping decision process. In this document, the flipping of bits within the el chosen bits of each explicit codeword is also generally referred to as altering the explicit codewords prior to transmission. This document describes the decoding and other related features according to flipping decisions based on the bit-by-bit flipping basis. However, if other forms of alterations are used, appropriate modifications need to be made at the receiver using the currently known state of art technologies.

### III. Decoding of Explicit and Implicit Streams in ITBF

The proposed ITBF receiver constructed here is based on the following observation:
Even though the transmitted sequence v′_Ex may not be a valid codeword of C_Ex, any existing invalidity is caused only within the el chosen bits due to the flipping of the bits that occurred prior to transmission. Therefore, if the received signal is initially decoded as a punctured code by ignoring those el chosen bits, the explicit message sequence m_Ex and the corresponding explicit coded sequence v_Ex can be correctly decoded. Further, this decoding provides information about the el chosen bits of v_Ex (without any flips) while the received signal provides information of v′_Ex (with the flips).

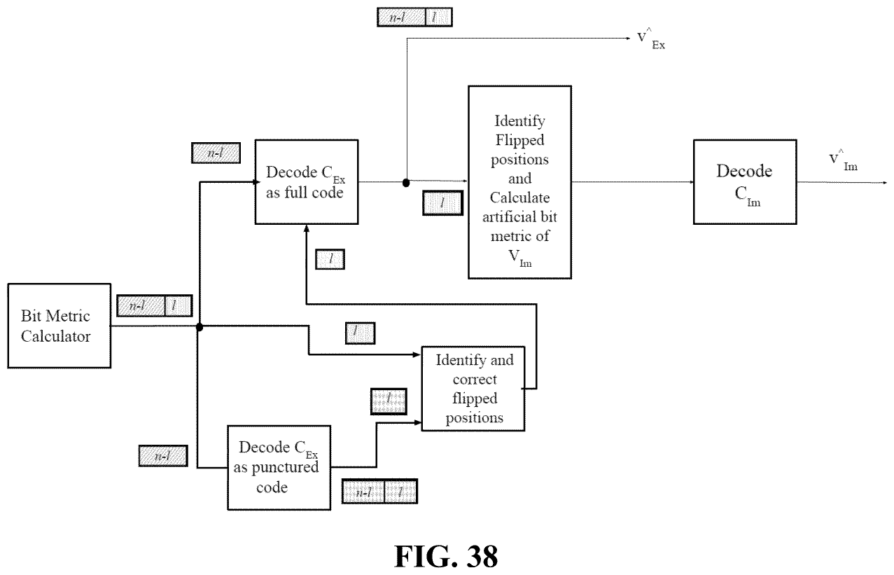

FIG. 38 shows the general structure of the ITBF decoder proposed here based on the above observation to recover both the explicit and the implicit streams. Below we explain the steps involved in ITBF decoding. Throughout this discussion, we focus primarily on the el chosen bits. In order to assist that discussion, we denote the following quantities of the el chosen bits:
(a) received signal values by y1, y2, . . . , y_el,
(b) coded sequence values of v_Ex (prior to flipping) by v′_Ex,1,v′_Ex,2 . . . , v′_Ex,el, and
(c) transmitted sequence v′_Ex (after flipping) by v′_Ex,1,v′_Ex,2, . . . , v′_Ex,el.

The decoding procedure is described using the following four steps.

First, initial decoding: decode C as a punctured code by removing the el chosen bits from the received signal. If iterative decoding is used (such as in the decoding of a LDPC code), run initially a set of iterations of the punctured code. The number of initial iterations used for the punctured code can be pre-selected or adoptively vary as the iterations progress. Note that the initial decoding also provide likelihood values of the el chosen bits, which are denoted here by L_v_Ex(i), i=1, 2, . . . , el, and they represent the likelihood values of the encoded sequence v_Ex prior to flipping at the transmitter.

Second, detecting flips: In order to decide whether or not each of the el chosen bits is flipped, hard decode each of the el chosen bits of v_Ex, which are denoted by b\hat{ }i, i=1, 2, . . . , el, using the likelihood values of those bits found in step 1. Additionally, for each of the el chosen bits, hard decode the corresponding received signal value yi, i=1, 2, . . . , el, to determine the hard decoded received signal value, yh\hat{ }i, i=1, 2, . . . , el that correspond to the flipped sequence v′. Then, using bi\hat{ } and yh\hat{ }i values, determine fi as
fi=0, b\hat{ }=yh\hat{ }i
   1, bi\hat{ }ne yh\hat{ }i
      to indicate whether the ith bit was likely to have been flipped or not prior to transmission. Specifically, if fi=0, the ith chosen bit is not likely to have been flipped while if fi=1, it is likely that the ith bit has been flipped prior to transmission. In essence, the flips are detected using a comparator that compares the hard decision of the chosen bits of the explicit code obtained by the initial decoding with the hard decisions of the received signal of the corresponding received bits to determine whether each transmitted chosen bit is more likely to have been flipped or not prior to transmission.

Third, since fi, i=1, 2, . . . , el, found in step 2, determines whether or not the ith chosen bit has been flipped, it can then be used to modify the received sequence to correspond to v_Ex by reversing the effect of the flips for the decoding of the explicit stream. Specifically, using a received signal correction unit, the received signal yi can be corrected for each of the el chosen bits in the decoding of the explicit stream as (1-2fi)yi, i=1, 2, . . ., el. In case of iterative decoding, upon reversing the effects of the flips, continue decoding of C as a full code (not as a punctured code) by also including the corrected received signals of the chosen bits.

Fourth, recall that the flipping of the el chosen bits were decided at the transmitter was done according to the implicit coded stream. Further, observe that if the ith implicit bit, Im_i, had actually been transmitted over the channel with the same noise experienced by yi, it would have been received as (1-2Im_i)abs(yi). Without loss of generality, it is assumed here that a positive signal value is used for Im_i=0 and a negative signal value is used for Im_i=1. Hence, an artificially created received signal value can be obtained for each implicit coded bit Im_i, i=1,1,2 . . . ,el as (1-2f_i)abs(yi). Note that depending on the value of fi (0 or 1), the artificially created channel value is positive or negative suggesting that the ith coded implicit bit has not been flipped or flipped respectively. Even though fi values are available after the initial decoding, a more reliable set of fi vales in (eqn. no) can be calculated by using the L_v_Ex(i) values at the end of the decoding of the explicit stream in step 3. These more reliable re-calculated fi values can be used to calculate the artificially created received signal values for the corresponding el implicit bits using a unit referred to here as an artificial channel information creation unit.

The first three steps describe the decoding of a single codeword of the explicit stream. It is noticed that if the initial decoding step 1 and the calculation of fis in step 2 are reliable then step 3 would provide a reliable explicit stream that would perform almost as reliably as if no bits were flipped prior to transmission. It is also seen that when every block of the explicit stream (n coded bits) is transmitted over the channel, an artificially created channel information of el coded bits of the implicit stream can be extracted without transmitting them over the channel.

It is noticed that the initial decoding in ITBF and the reliability of fis, that are used to correct the explicit stream and to extract the artificial channel information of the implicit stream, are critical in the decoding of both the explicit and implicit streams. Realizing the importance of extracting reliable fi values, we propose a gradual initial decoding method (GID) as described below to improve step 1.

Gradual Initial Decoding (GID): In order to improve initial decoding in step 1, we propose using Gradual Initial Decoding (GID) to gradually determine the values of fi in a more reliable manner instead of fully completing them in step 1. Essentially, GID uses steps 1, 2 and 3 jointly to determine fi values as they become available. First note that determining any fi value requires the corresponding yh_i and b_i (which depends on the sign of the corresponding L_v_Ex(i)) values. Since yh_i is solely dependent on the channel, in order improve fi, we focus on identifying more reliable L_v_Ex(i) values and determine the corresponding fi values of only those reliable L_v_Ex(i) values. This can be done by deciding the value of each b_ii when the sign of the corresponding L_v_Ex(i) value stays the same over a pre-selected number (say lambda) of immediately prior iterations. However, this strategy should be used only after a pre-selected number of iterations (say Na) allowing the decoder to settle on the decoded sequence reasonably well. As soon as a b_i value becomes available, the corresponding fi value can be obtained according to step 2. At that point the received signal can be corrected for that chosen bit as described in step 3 and it can be included in the next iteration. Therefore, in the GID method, chosen bits are gradually included in the decoding of the explicit stream making the decoding of C stronger in a gradual manner as iterations proceed.

### IV. Decoding Strategy

If C is a small code and can be decoded in a maximum likelihood (ML) sense, the initial decoding of C is step 1 and the decoding of C as a full code in step 3 can be performed in a ML sense. However, this doubles the decoding complexity and the decoding delay of the explicit stream.

Decoding Strategy without GID: For a large code, such as an LDPC code and most other codes used in practice, ML decoding is not possible and instead iterative decoding is commonly used. In such situations, the initial decoding in step 1 and the full decoding in step 3 can be done in an efficient manner without increasing the overall decoding complexity or the decoding delay of the explicit stream. Focusing on the iterative decoding of C and implementing step 1 directly without GID, a pre-selected N1 number of iterations in step 1 and a pre-selected N2 number of iterations in step 3 can be chosen. The values of N1 and N2 can be chosen to maintain the total number of iterations N4N1+N2) close to the number of iterations commonly used without ITBF thereby maintaining about the same decoding complexity and the decoding delay.

Decoding Strategy with GID: The Decoding strategy with GID can be implemented using the following steps:
(a)in every iteration beyond a pre-selected number of Na iterations, identify chosen bits with L_v_Ex(i) values that have the same sign over the previous lambda iterations and complete steps 2 and 3 to include those chosen bits for future iterations,
(b) continue step (a) up to Nb (>Na) iterations or until fi values of all chosen bits have completed step 3 and the corresponding chosen bits are included in the iterations However, if all el chosen bits have not completed steps 2 and 3 at the end of Nb iterations, perform steps 2 and 3 for all remaining chosen bits using the L_v_Ex(i) values available after Nb iterations, and
(c) continue decoding of C as a full code considering all chosen bits for an additional Nc number of iterations.

The total number of iterations with GID, which is (Nb+Nc) can be chosen close to that of the commonly used number of iterations without ITBF in order to maintain about the same decoding complexity and decoding delay.

The above gradual initial decoding process employs the strategy to correct each of the el chosen bits as their signs become steady. Even though it is unlikely (especially at higher values of lambda), during iterations the signs of likelihood of bits can change even after they remain the same after staying the same for several previous iterations. If that happens any correction that was previously made need to be removed and that chosen bit needs to be again punctured until its sign of the likelihood value becomes steady again. Therefore, the proposed GID method here is designed to re-puncture and recorrect, when necessary, all previously calculated fi values between Na and Nb iterations. Therefore, in addition to gradually resolving the chosen bits, GID allows re-puncturing and re-correcting when necessary. The values of Na, Nb and lambda can be pre-selected depending on the situation. Note that when lambda=1 and Na=Nb, the initial decoding stops completely after Na iterations making GID equivalent to the case without GID with Na=N1. The ITBF schemes with and without GID are compared in the numerical results presented later in this disclosure to demonstrate the improvement that can be achieved by GID over schemes without GID.

### V. Hybrid ITBF/CPCD (ITCD) Schemes

Combined punctured code decoding (CPCD) has been recently introduced to improve the decoding of a code, such as described in (i) R. A. Hassan, J. P. Fonseka, “Rate and Performance Enhancement of LDPC Codes Using Collection of Punctured Codes Decoding (CPCD),” in International Journal of Sensors, Wireless Communications and Control, DOI: 10.2174/2210327911666210210164711, 2020 (hereinafter “Rate and Performance Enhancement of LDPC Codes Using Collection of Punctured Codes Decoding (CPCD)”) and (ii) R. A. Hassan, J. P. Fonseka, “Improving LDPC and Turbo LDPC Codes Using Collection of Punctured Codes Decoding (CPCD),” Physical Communication, Volume 53, 2022 (hereinafter “Improving LDPC and Turbo LDPC Codes Using Collection of Punctured Codes Decoding (CPCD)”). It has been shown that CPCD can significantly improve the performance of quasi cyclic LDPC (QC-LDPC codes as in “Rate and Performance Enhancement of LDPC Codes Using Collection of Punctured Codes Decoding (CPCD)” and “Improving LDPC and Turbo LDPC Codes Using Collection of Punctured Codes Decoding (CPCD)”. In this section, we explain how ITBF can be combined with CPCD to generate ITCD schemes that can transmit a higher data rate on the implicit stream than using ITBF alone while also improving performance on both explicit and implicit streams.

Review of CPCD: In CPCD, a code C (which is considered here as the mother code) is viewed as a collection of any pre-selected number of D punctured codes, Ci, i=1,2,. . ., D, generated from the mother code C (as seen in (i) “Rate and Performance Enhancement of LDPC Codes Using Collection of Punctured Codes Decoding (CPCD)” and (ii) “Improving LDPC and Turbo LDPC Codes Using Collection of Punctured Codes Decoding (CPCD)”). Considering C in systematic form, all n coded bits are viewed as a collection of the message bits and the set of its parity bits p. In CPCD, each punctured code Ci is constructed from all message bits and a portion of the parity bits pi, i=1,2, . . . , D. In CPCD, pis are formed by dividing all parity bits p into non-overlapping segments so that Upi=p. During decoding, each Ci is separately decoded by using the received signal corresponding to its own coded bits (message portion and its corresponding parity portion pi) and also using the extrinsic information of all bits of Ci provided by the remaining punctured codes, Cj, j=1, 2, . . . , D, i ne j. Note that each punctured code in CPCD, Ci, i=1, , . . . , D, can also be seen as a component code of the mother code C.

ITCD Schemes: It is seen from sections 2 and 3 that ITBF uses a punctured code in the initial decoding (step 1). Therefore, the initial decoding in ITBF (step 1) inherently consists of the following two punctured codes of C: (a) the punctured code used in the initial decoding (say C1), and (b) the punctured code formed by the message bits and the chosen bits that are not used in the initial decoding (say C2). However, C2 becomes available in step 3 after making the corrections of the received signal values of the chosen bits . Upon determining C2, the decoding in ITBF was continued by considering C as a full code. Instead, decoding can be continued as in CPCD by considering C1 and C2 as two punctured codes. An ITBF scheme that switches to CPCD decoding after obtaining the channel values of the chosen bits is considered as a hybrid ITBF/CPCD scheme or simply as an ITCD scheme.

However, the CPCD technique considered in ITCD has differences from the CPCD technique employed in (i) “Rate and Performance Enhancement of LDPC Codes Using Collection of Punctured Codes Decoding (CPCD)” and (ii) “Improving LDPC and Turbo LDPC Codes Using Collection of Punctured Codes Decoding (CPCD)”. In order to elaborate on the differences, let us first recall that all CPCD schemes considered in the numerical results in (i) “Rate and Performance Enhancement of LDPC Codes Using Collection of Punctured Codes Decoding (CPCD)” and (ii) “Improving LDPC and Turbo LDPC Codes Using Collection of Punctured Codes Decoding (CPCD)” have used the same number of parity bits in all of their punctured codes and they all started to decode from the very first CPCD iteration (as seen in (i) “Rate and Performance Enhancement of LDPC Codes Using Collection of Punctured Codes Decoding (CPCD)” and (ii) “Improving LDPC and Turbo LDPC Codes Using Collection of Punctured Codes Decoding (CPCD)”). However, in ITBF, C2 becomes available for decoding only after N1 iterations to complete steps 1 through 3 without GID, or C3 becomes gradually available from Na to Nb iterations when GID is used). Further, the number of parity bits of C2 is generally smaller than that of C1. Therefore, in order to combine CPCD with ITBF, we first introduce three separate special cases of CPCD as follows:
(a) Unbalanced CPCD (U-CPCD) that employs different numbers of parity bits in different punctured codes,
(b) Staggered CPCD (S-CPCD) that starts decoding different punctured at different numbers of CPCD iterations, and
(c) unbalanced-staggered CPCD (US-CPCD) is a hybrid of U-CPCD and S-CPCD that employs different numbers of parity bits in different punctured codes and starts decoding different punctured codes at different numbers of CPCD iterations.

In ITCD, the CPCD employed is the US-CPCD version of CPCD. Therefore, ITCD schemes switch to US-CPCD after determining the channel information of the parity bits of C2.

However, when GID is used, step 3 and the values of fi in C2 become available gradually. In such situations, since the punctured code C2 by itself remains as a punctured code as the iterations progress, ITCD can be implemented to start CPCD iterations upon completing a pre-selected mu(<el) number of fi values in step 3 become available and leaving the remaining (el-mu) number of chosen bits as punctured bits within C2. The values of Na, Nb, lambda and mu in ITCD with GID can be chosen depending on the situation. Note that if lambda=1, Na=Nb and mu=e1, and the initial decoding stops completely after Na=N1 iterations making it equivalent the case without GID.

### VI. CPCD with General LDPC Codes

The CPCD principle, that employs multiple punctured codes during decoding, has been shown to work well with quasi-cyclic LDPC (QC-LDPC) codes. It is described here how to go about applying that CPCD technique to any general LDPC code. As seen in (i) “Rate and Performance Enhancement of LDPC Codes Using Collection of Punctured Codes Decoding (CPCD)” and (ii) “Improving LDPC and Turbo LDPC Codes Using Collection of Punctured Codes Decoding (CPCD)”, in the application of CPCD with two punctured codes in QC-LDPC codes, punctured codes can be easily derived by assigning all odd numbered parity bits to one punctured code (C1) and assigning all even numbered parity bits to the other punctured code (C2). This division of variable nodes into punctured codes can be viewed on the Tanner graph as splitting up variable nodes into different punctured code by ensuring that variable nodes of parity bits that are connected to every check node are assigned to different punctured codes. With that observation, CPCD can be applied to any general LDPC code and construct its punctured codes according to the following policy:
Assign variable nodes corresponding to parity bits that are connected to each check node into different punctured codes.

The above policy ensures that every check node gathers information from multiple punctured codes. Further, the above policy; (a) discourages having check nodes connected to variable nodes of only a single punctured code, and (b) encourages check nodes be connected to a high number of punctured codes, preferably equal to the number of punctured codes D adopted in the CPCD scheme. Even though the selection of punctured codes according to the above policy is not unique, it helps to choose punctured codes in CPCD in manner that is consistent with that with QC-LDPC codes. Further, in situations where the above condition cannot be perfectly satisfied, attempting to closely satisfy the above condition would lead to attractive CPCD schemes.

### VII. Combined ITCD/CICM Technique

In [CICM], it has been shown that the performance of coded transmission can be improved by the use of proper interleaving of coded bits prior to transmission and the use of reverse Gray coding (RGC) on the constellation. It has been shown that CICM can significantly improve the performance of coded transmission using higher-order modulation making them perform similar to the binary transmission of the same coded information, as in (i) Y. Hu and J.P. Fonseka, “Constrained Interleaved Coded Modulation”, IEEE Trans. on Vehicular Technology, Vol. 66, Issue: 4, pp. 3501-3506, April 2017 (hereinafter ““Constrained Interleaved Coded Modulation”) and (ii) Y. Hu and J. P. Fonseka, “Constrained Interleaved Coded Spatial Modulation (CICSM)”, IEEE Wireless Communications Letters, Vol. 6, Issue-5, pp. 638-641, October 2017 (hereinafter “Constrained Interleaved Coded Spatial Modulation (CICSM)”). However, the use of CICM presented in “Constrained Interleaved Coded Modulation” and “Constrained Interleaved Coded Spatial Modulation (CICSM)” is limited only for short codes due to the high number of codewords required by the design of its CICM interleaver.

Specifically, CICM technique uses the following modifications from standard transmission using Gray coding: (a) employs an interleaver (referred to as the CICM interleaver) to interleave coded bits of CICM so that the non-zero positions of all low weight coded sequences are fed into different transmitted symbols, and (b) employs reverse Gray coding (RGC) mapping policy so that all single bit differences have a high Euclidean distance on the constellation. As a result all low weight coded sequences end up achieving a high Euclidean distance from the actual transmitted sequence thereby improving performance at higher SNR values. However, due to the use of RGC, CICM schemes have weaker performance at lower SNR values compared with those with regular Gray coding.

Considering all the above, we propose a novel ITCD/CICM technique that combines ITCD with CICM. Since LDPC codes generally have good BER variations with sharp waterfall regions, it is undesirable to use CICM for the entire code as it will make the BER variations worse than that with standard Gray coding. However, noticing that C2 in ITCD starts its decoding in the middle of the iterative decoding process, the CICM technique can be better applied to ITCD by using it only on the parity bits of C2. By doing so, the code C2 that generally consists of a lower number of parity bits than C1 can be made stronger with the help of the constellation.

Considering the above observations, the proposed novel ITCD/CICM scheme employs:
(a) regular Gray coding without any interleaveing to transmit all message bits and all parity bits of C1, and
(b) employ CICM with an interlaver and RGC to transmit only the parity bits of C2.

By using the above approach, any degradation in performance due to the use of RGC from the beginning is removed. Following the desired features of CICM, the interleaver of the parity bits of C2 has to be designed so that every error in the parity bits of C2 would impact as many other variable nodes as possible. Note that every parity bit of C2 can immediately influence many other variable nodes according to the Tanner graph. The set of variables nodes Si, influenced by a parity bit vi of C2, referred to here as the associated variable nodes (AVN) of vi, can be found by (a) following all paths on the Tanner graph that emerge from that variable node vi to its connected the check nodes, and (b) then considering each of those check nodes back to the set of variable nodes to form Si. The AVNs Si of each parity bit of C2 vi, found using steps (a) and (b), can be used to design the CICM interleaver of ITCD/CICM. The CICM inetrelaver can preferably be designed to construct symbols of a M=2\hat{ }-ary constellation used for transmission, by using m parity bits of C2, v1,v2, . . . , vm, to form every symbol of the parity bits of C2 so that their respective S1, S2, . . . Sm share as small number of variable nodes as possible.

As a result, ITCD/CICM transmits the message bits and parity bits of C1 without any interleaving and using Gray coding. However, the parity bits of C2 are ineterleaved as described before and transmitted using RGC.

### VIII. Numerical Results and Discussion

Bit error rate (BER) Simulations: In this section, we present numerical results to demonstrate that
(a) ITBF can transmit a separate implicit coded stream without sacrificing any significant performance on both the explicit and implicit streams, and
(b) ITCD can transmit a higher data rate on the implicit stream while maintaining the same or better performance on both the explicit and implicit streams compared to traditional decoding of the explicit stream without any implicit stream.

Further, the numerical results demonstrate that the additional implicit stream can be transmitted without any increase in the decoding complexity and decoding delay in ITBF schemes. It is also demonstrated the ITCD schemes presented here do not increase the decoding delay, but doubles the decoding complexity (which is common in all parallel CPCD schemes, such as described in “Rate and Performance Enhancement of LDPC Codes Using Collection of Punctured Codes Decoding (CPCD)”) due to the parallel CPCD technique employed using two punctured codes.

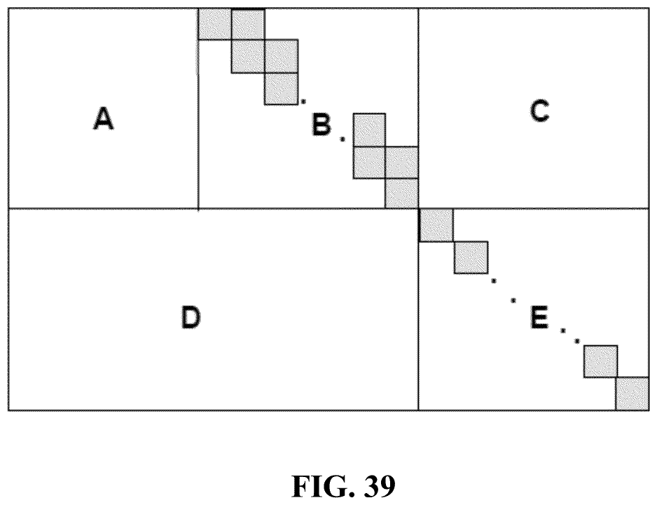

In order to demonstrate (a), we consider the LDPC code employed in the 5G NR standard (i.e., (2018). GPP: TS 38.212 NR; multiplexing and channel coding). In the LDPC code employed in 5G NR, it is easier to identify the chosen bits needed in ITBF due to its structure. Specifically, the parity check matrix H of the LDPC code in 5G NR has a sub-block structure [GPP: TS 38.212 NR; multiplexing and channel coding], shown in FIG. 39. Each sub-block of that H matrix is a z×z matrix, and the value of z is chosen depending on the application. The segment A of H corresponds to the systematic message bits. Segment B corresponds to the first set of parity bits; its first column has weight 3, while its other columns have a dual diagonal structure. Both segments A and B together represent the highest code rate that can be realized in 5G NR LDPC code. Segment C is an all-zero matrix. Segment D is called an extension region and its main purpose is to support Incremental Redundancy Hybrid Automatic Repeat Request (IR-HARQ). Segment E is an identity matrix. In 5G NR, two separate versions of the LDPC code with the same structure shown in FIG. 39 are employed; base graph 1 that employs a 46 by 68 matrix and base graph 2 that employs a 42 by 52 matrix in terms of sub-blocks [GPP: TS 38.212 NR; multiplexing and channel coding]. In 5G NR, the rate adjustment is done by shortening the H matrix by simply removing sub-blocks along columns from the identity portion E (starting from the right most column).

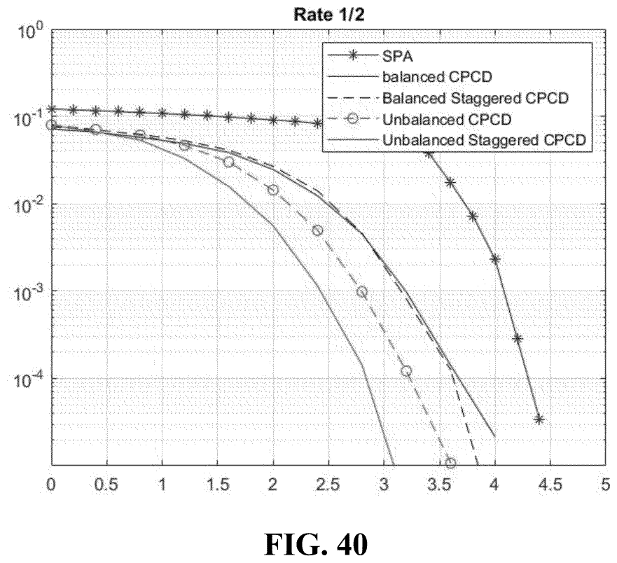

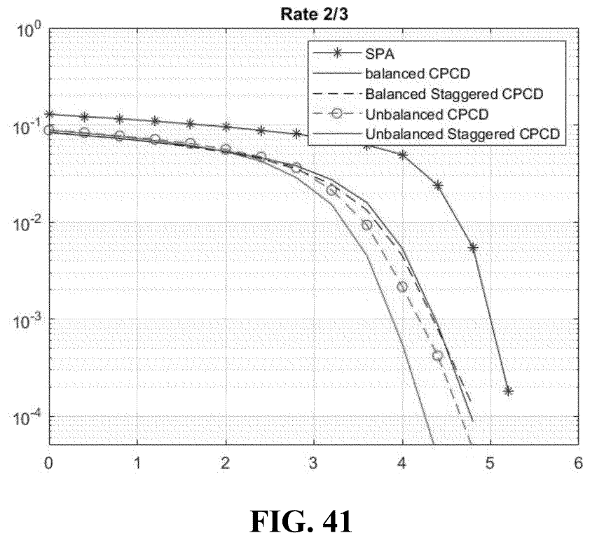

Therefore, puncturing in 5G NR can be easily done by puncturing the desired number of sub-blocks (which determine the chosen bits in ITBF) from the end of the codeword. FIGS. 40-41 show the BER variations of the explicit and the implicit streams of two separately constructed from the 5G LDPC code that uses the base graph 2 and employ 16-QAM for transmission. The ITBF scheme in FIG. 40 uses z=256 and punctures two sub blocks from the right of H to result in a code in 5G with rate 0.2083. The ITBF scheme considered in FIG. 40 that employs that rate 0.2083 code and uses ⅙ fraction of parity bits of the code as chosen bits thereby maintaining about 13.19% rate of transmission on the implicit stream compared with the rate of transmission on the explicit stream.

Similarly, the ITBF scheme in FIG. 41 also uses z=256 and punctures twelve sub blocks from H to result in a code with rate ¼. The ITBF scheme considered in FIG. 41 employs that rate ¼ code and uses 1/14 fraction of parity bits of the code as chosen bits thereby maintaining about 5.36% transmission rate on the implicit stream compared with the transmission rate of the explicit stream. The ITBF schemes in FIG. 40-41 use 8 initial iterations and 24 total iterations in their BER variations. The BER variations of the ITBF schemes are compared with the full code and the punctured code (used in the initial decoding) with the same number of 24 iterations. It is seen from FIG. 40-41 that the explicit stream of the ITBF schemes can perform better than the BER variation of the punctured in isolation (demonstrating that the proposed identification of the flipped positions and the correction of the received signal values are indeed helping the decoder), and further, the BER variation of the explicit stream gets closer the SPA decoding of the full-code. It is also seen that the BER variation of the implicit stream is better than that of the explicit stream and close to that of the BER variation of the full code. Thus, the proposed ITBF technique can transmit a secondary coded stream implicitly without noticeably sacrificing performance or increasing the decoding complexity or the decoding delay.

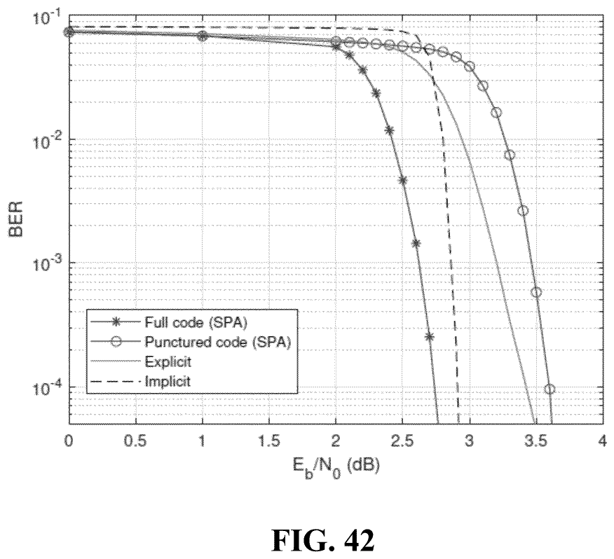

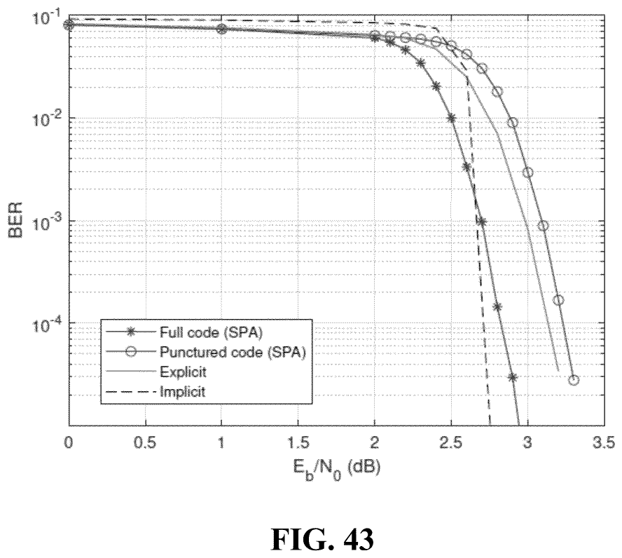

Since ITCD employs CPCD, and since it is known that QC-LDPC codes perform well with CPCD, in order to demonstrate (b), we consider the QC-LDPC code with length 1944 employed in the WiFi standard in all numerical results related to ITCD. Since ITCD employs US -CPCD, we first compare the BER variation of an example known CPCD technique, that employs balanced distribution of parity bits among punctured codes and called here as balanced CPCD (B-CPCD), with those of U-CPCD, S-CPCD and US-CPCD with two punctured codes (D=2). All U-CPCD schemes considered here employ 75% of parity bits in the first punctured code C1 and the remaining 25% of parity bits in the second punctured code C2. In all S-CPCD schemes the first punctured code C1 runs 8 iterations before CPCD decoding begins with a total of 24 iterations. FIG. 42 shows the BER variations of B-CPCD, U-CPCD, S-CPCD, and US-CPCD when the code rate is ½ and 16-QAM is used for transmission. FIG. 43 shows similar results when the code rate is ⅔ and 16-QAM is used for transmission. It is seen from FIG. 39-40 that US-CPCD schemes can actually perform better than all other CPCD counterparts.

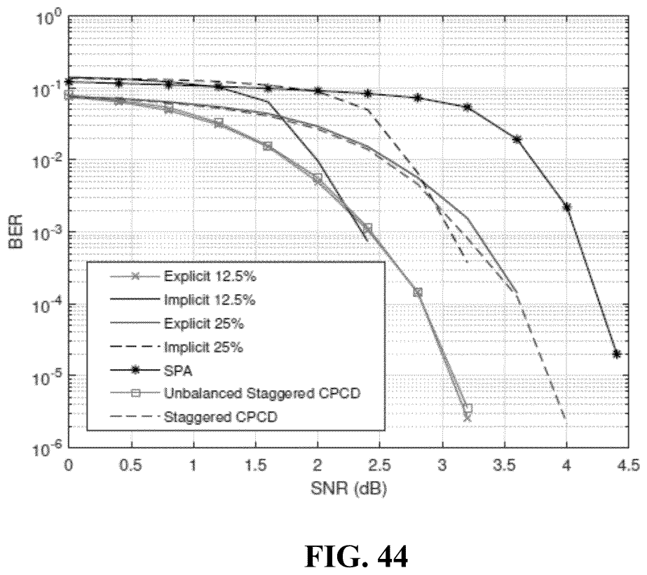

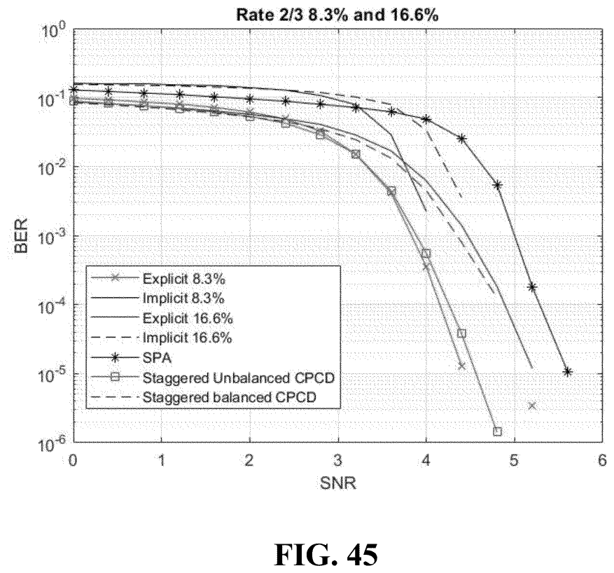

All ITCD schemes considered here employ 8 initial iterations followed by US-CPCD with 2 punctured codes (D=2) that run 4 iterations in each punctured code in every CPCD iteration, and 4 CPCD iterations resulting in altogether 24 SPA runs as with regular SPA decoding. Therefore, all ITCD schemes considered here have the same decoding delay but increases the decoding complexity due to the use of 2 punctured codes during the US-CPCD portion of the decoding. FIG. 44 shows the BER variations of the explicit and implicit streams separately of two ITCD schemes generated from the rate ½ LDPC code employed in WiFi when 16-QAM is used for transmission. Specifically, the two ITCD schemes maintain 12.5% and 25% transmission rate on the implicit stream compared with the transmission rate of the explicit stream. The ITCD scheme that transmits 12.5% rate on the implicit stream employs US-CPCD with 75%, 25% split of parity bits between the two punctured codes C1 and C2. Similarly, the ITCD scheme that transmits 25% rate on the implicit stream employs US-CPCD with 50%, 50% split of parity bits between C1 and C2 (essentially making it similar to S-CPCD). FIG. 45 shows similar BER variations of two ITCD schemes generated from the rate 2/3 code employed in the WiFI standard with 16-QAM transmission. Since the number of parity bits are smaller in the rate ⅔ code, ITCD schemes presented in FIG. 45 respectively transmit a lower rate, specifically 8.3% and 16.6%, on the implicit stream compared with the rate on the explicit stream.

Applications of ITBF and ITCD: ITBF and ITCD can be employed in any communication system to improve the overall transmission rate by transmitting a secondary coded stream implicitly. It is seen from the BER variations in section 5A that ITBF schemes can transmit a secondary coded stream implicitly without noticeably sacrificing performance or increasing the decoding complexity or decoding delay. ITCD achieves the same goal as ITBF. However, ITCD can maintain a higher data rate on the implicit stream while maintaining better or similar performance on both implicit and explicit streams.

Since both explicit and implicit streams operate independently, different types of codes, different code rates, and desired BER values can be independently employed on the two streams, ITBF and ITCD techniques are highly attractive for multimedia applications. In multimedia applications, the explicit stream and the implicit stream can represent two different types of multimedia streams. For example, the explicit stream can transmit a video signal while the implicit stream transmits an audio signal thereby eliminating the need for a separate channel for the transmission of the audio signal.

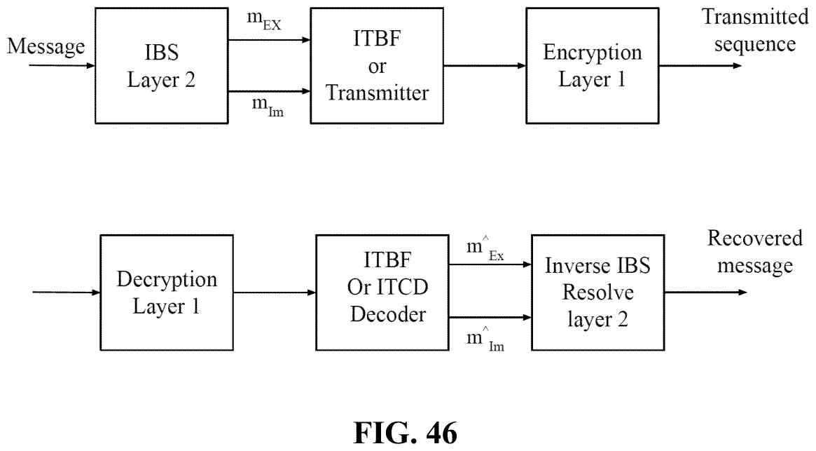

Another important application of ITBF and ITCD is in information security. Different types of encryption methods are used in information security, such as described in Singh, G. (2013). A study of encryption algorithms (rsa, des, 3des and aes) for information security. International Journal of Computer Applications 67 (19). The transmission of an independent implicit stream in ITBF and ITCD allows a secure communication system to add an additional layer of encryption through ITBF or ITCD. FIG. 11 illustrates how an additional layer of security can be embedded while transmitting an encrypted message. This can be achieved by forming the implicit stream by choosing bits from the original message stream according to a confidential implicit bit selection (IBS) process as illustrated in FIG. 46. The traditional form encryption can be employed on the explicit stream which is referred to here as the first layer of encryption. The second layer of encryption is added from the confidential IBS process. Note that, even if an intruder somehow penetrates the first layer of encryption and recovers the explicit information stream, the intruder is still unable to recover the original message stream without the knowledge of the IBS process. Therefore, the second layer of encryption introduced by the IBS process in the selection of the implicit message stream can significantly enhance the security of an information transmission scheme.

The proposed ITBF and ITCD techniques as described before can transmit el (or generally el′) implicit coded bits during the transmission of a explicit codeword of length n, thereby maintaining a transmission rate of el/n on the implicit stream compared with the rate of the explicit stream. As a result, depending on the code employed on the implicit stream, if the effect of implicit coded bits of an implicit codeword are spread in time among several codewords of the explicit codewords, the implicit stream may have to wait for the completion of the decoding of several codewords of the explicit stream to complete gathering channel information of all coded bits of the corresponding implicit codeword thereby introducing a delay in decoding of the implicit coded bits. However, this delay can be avoided by splitting the segments of el coded bits of the implicit stream preferably over different tones in an OFDM system. By doing so, at the end of the decoding of each explicit codeword on different tones (which are decoded simultaneously), the artificially created channel information of all coded bits of the corresponding implicit codeword would be available and that implicit codeword therefore would be ready for decoding, thereby eliminating the decoding delay. For example, if both the explicit and the implicit streams employ the same code, and if el/n=0.25, an implicit codeword will be ready for decoding when the four tones that carry the information of their respective segments of el coded bits complete decoding of their corresponding explicit codewords. As a result, an OFDM system that employs M tones can transmit M_ad=floor(M*el/n) additional codewords implicitly while decoding M explicit codewords transmitted using M tones by using the proposed ITBF or ITCD schemes, where floor(x) is the standard floor function. In essence, an OFDM scheme that employs M tones effectively employ an additional M_ad tones, and these additional tones are referred to here as image tones. Importantly, these image tones do not occupy any bandwidth or demand any transmitted power.

### IX. Summary and Conclusions

A novel implicit transmission with bit flipping (ITBF) technique has been introduced to transmit a secondary coded stream implicitly while transmitting a primary coded stream explicitly over a channel. The ITBF technique can employ any coding technique on the primary and secondary channels independently. ITBF flips a set of chosen parity bits of the explicit stream according to the implicit stream. Using an initial decoding method that excludes the chosen bits, receiver determines (a) whether or not each of the chosen bit has been flipped, (b) correct the portion of the chosen bits of the explicit received stream (as if no bits were flipped before transmission) to continue decoding of the explicit stream, and (c) extracts an artificial channel information for the corresponding implicit bits. Numerical results presented for the LDPC code employed in 5G demonstrate that the implicit stream that employs the same code employed on the explicit stream can transmit at 13% of the rate on the explicit stream without significantly sacrificing performance, or increasing the decoding complexity or decoding delay.

The ITBF method has been further improved by combining it with CPCD to form ITCD schemes. ITCD schemes moves to CPCD upon correcting the flipped bits. Specifically, CPCD decoding in ITCD considers the following two punctured codes: (a) the message and the parity bits excluding the chosen bits, and (b) message and the corrected chosen bits. Since CPCD performs better than traditional decoding, ITCD can transmit a higher data rate on the implicit stream while maintaining better or the same performance as traditional decoding without increasing the decoding complexity or the decoding delay. Numerical results presented for the LDPC code in the WiFi standard show that ITCD can transmit a secondary stream implicitly at 25% rate of the explicit stream without sacrificing performance, or increasing the decoding complexity or decoding delay.

Example embodiments of the disclosed innovations have been described above. Those skilled in the art will understand, however, that changes and modifications may be made to the embodiments described without departing from the true scope and sprit of the present invention, which will be defined by claims.

What is claimed is:

1. A transmitter apparatus comprising:
a first message stream, m_Ex, which is referred to here as the explicit message stream;
an explicit encoder, C_Ex, which can be any type of a code, such as a block code, turbo code, LDPC code, polar code, etc., that encodes the message sequence m_Ex according to the encoding policy adopted by the code C_Ex;
a second message stream, m_Im, which is referred to as the implicit message stream;
an implicit encoder, C_Im, that can be any independent code, such as a block code, turbo code, LDPC code, polar code, etc., that encodes the message sequence m_Im according to the encoding policy adopted by the code C_Im;
a set of bit positions of each codeword of the explicit stream, which are referred to here as the chosen bits, that are chosen according to any preferable policy;
an alteration policy that alters the chosen el bits of each codeword of the explicit stream according to el′ (<=el) coded bits of the implicit stream to form an altered codewords of the explicit stream;
a modulator that modulates the altered coded bits of the explicit stream according to any chosen linear or non-linear modulation scheme, such as QPSK, 16-QAM, 64-QAM, M-ary CPM, FSK, etc.; and
a transmitting antenna that transmits the modulated signal.

2. The transmitter apparatus of claim 1, with el'=el, where the alteration of the el chosen bits of the explicit stream is done by flipping each chosen bit according to a coded bit of the implicit stream; specifically flip any ith chosen bit if the corresponding ith implicit bit is a ‘1’ (or a ‘0’) and not flip ith chosen bit if the corresponding ith coded implicit bit is a ‘0’ (or a ‘1’).

3. A receiver apparatus that decodes the received signal of claim 1, the receiver apparatus comprising:
an initial decoder that decodes every codeword of the explicit coded stream by treating C_Ex as a punctured code formed by excluding all el chosen bits;
a comparator that compares the decoded chosen bits from the initial decoding and the hard decisions of the received signal to determine whether each chosen bit is more likely or not to have been flipped prior to transmission;
a received signal correction unit that changes the signs of the received signal values of the chosen bits that have been identified as flipped by the comparator;
a final decoder of C_Ex that decodes each codeword of the explicit code C_Ex as a full code by using all coded bits of the codeword including the corrected received signal values of the chosen bits obtained from the received signal correction unit;
an artificial channel information creation unit that compares chosen bits of each decoded explicit codeword with the hard decisions of the corresponding received bit and generates channel information of each el′ implicit coded bits used to determine the alterations made in the corresponding el chosen bits of the each explicit codeword; and
an implicit decoder to decode each codeword of the implicit stream according to the decoder of C_Im once artificial channel information of all coded bits of each codeword of the implicit stream is obtained.

4. The receiver apparatus of claim 3, where the initial decoding is performed gradually using a gradual initial decoding method.

5. A receiver apparatus that decodes the received signal of claim 1, the receiver apparatus comprising:
an initial decoder that decodes every codeword of the explicit coded stream by treating C_Ex as a punctured code formed by excluding all el chosen bits;
a comparator that compares the decoded chosen bits from the initial decoding and the hard decisions of the received signal to determine whether each chosen bit is more likely or not to have been flipped prior to transmission;
a received signal correction unit that changes the signs of the received signal values of the chosen bits that have been identified as flipped by the comparator;
a final decoder of C_Ex that decodes each codeword of the explicit code C_Ex by considering two component codes of C_Ex: (a) a first component code being the punctured code used in the initial decoding, and (b) a second component code that comprises the message bits and the corrected chosen bits of C_Ex, and exchanging information between those two component codes;
an artificial channel information creation unit that compares chosen bits of each decoded explicit codeword with the hard decisions of the corresponding received bit and generates channel information of each el′ implicit coded bits used to determine the alterations made in the corresponding el chosen bits of the each explicit codeword; and
an implicit decoder to decode each codeword of the implicit stream according to the decoder of C_Im once artificial channel information of all coded bits of each codeword of the implicit stream is obtained.

6. The receiver apparatus of claim 5, where the initial decoding is performed gradually using a gradual initial decoding method.
